(19) United States
(12) Patent Application Publication
(10) Pub. No.: US 2010/0224248 A1
(43) Pub. Date: Sep. 9, 2010

(54) Solar Modules Including Spectral Concentrators and Related Manufacturing Methods

(76) Inventors: John Kenney, Palo Alto, CA (US); Jian Jim Wang, Orefield, PA (US); William Matthew Pfenninger, Fremont, CA (US); Nemanja Vockic, San Jose, CA (US); John Midgley, San Carlos, CA (US)

Correspondence Address: COOLEY LLP;ATTN: Patent Group, Suite 1100, 777 - 6th Street, NW, WASHINGTON, DC, 20001, US

(21) Appl. No.: 12/708,502

(22) Filed: Feb. 18, 2010

Related U.S. Application Data
(60) Provisional application No. 61/154,256, filed on Feb. 20, 2009.
(60) Provisional application No. 61/160,148, filed on Mar. 13, 2009.

(51) Int. Cl. H01L 31/00

(52) U.S. Cl. 136/259

(57) ABSTRACT

Described herein are solar modules and related manufacturing methods. In one embodiment, a solar module includes: (1) a photovoltaic cell; and (2) a resonant cavity waveguide optically coupled to the photovoltaic cell, the resonant cavity waveguide including: (a) a top reflector; (b) a bottom reflector; and (c) an emission layer disposed between the top reflector and the bottom reflector with respect to an anti-node position within the resonant cavity waveguide, the emission layer configured to absorb incident solar radiation and emit radiation that is guided towards the photovoltaic cell, the emitted radiation including an energy band having a spectral width no greater than 80 nm at Full Width at Half Maximum.

### CROSS-REFERENCE TO RELATED APPLICATIONS

This application claims the benefit of U.S. Provisional Application Ser. No. 61/154,256, filed on Feb. 20, 2009, and the benefit of U.S. Provisional Application Ser. No. 61/160,148, filed on Mar. 13, 2009, the disclosures of which are incorporated herein by reference in their entireties.

### FIELD OF THE INVENTION

The invention relates generally to solar modules. More particularly, the invention relates to solar modules including spectral concentrators.

### BACKGROUND

A solar module operates to convert energy from solar radiation into electricity, which is delivered to an external load to perform useful work. A solar module typically includes a set of photovoltaic (“PV”) cells, which can be connected in parallel, in series, or a combination thereof. The most common type of PV cell is a p-n junction device based on crystalline silicon. Other types of PV cells can be based on amorphous silicon, polycrystalline silicon, germanium, organic materials, and Group III-V semiconductor materials, such as gallium arsenide.

During operation of an existing solar module, incident solar radiation penetrates below a surface of the PV cell and is absorbed within the PV cell. A depth at which the solar radiation penetrates below the surface can depend upon an absorption coefficient of the PV cell. In the case of a PV cell based on silicon, an absorption coefficient of silicon varies with wavelength of solar radiation. For example, for solar radiation at 900 nm, silicon has an absorption coefficient of about 100 cm⁻¹, and the solar radiation can penetrate to a depth of about 100 μm. In contrast, for solar radiation at 450 nm, the absorption coefficient is greater at about 10⁴ cm⁻¹, and the solar radiation can penetrate to a depth of about 1 μm. At a particular depth within the PV cell, absorption of solar radiation produces charge carriers in the form of electron-hole pairs. Electrons exit the PV cell through one electrode, while holes exit the PV cell through another electrode. The net effect is a flow of an electric current through the PV cell driven by incident solar radiation. The inability to convert the total incident solar radiation to useful electrical energy represents a loss or inefficiency of the solar module.

Current solar modules typically suffer a number of technical limitations on the ability to efficiently convert incident solar radiation to useful electrical energy. One significant loss mechanism typically derives from a mismatch between an incident solar spectrum and an absorption spectrum of PV cells. In the case of a PV cell based on silicon, photons with energy greater than a bandgap energy of silicon can lead to the production of photo-excited electron-hole pairs with excess energy. Such excess energy is typically not converted into electrical energy but is rather typically lost as heat through hot charge carrier relaxation or thermalization. This heat can raise the temperature of the PV cell and, as result, can reduce the efficiency of the PV cell in terms of its ability to produce electron-hole pairs. In some instances, the efficiency of the PV cell can decrease by about 0.5 percent for every 1° C. rise in temperature. In conjunction with these thermalization losses, photons with energy less than the bandgap energy of silicon are typically not absorbed and, thus, typically do not contribute to the conversion into electrical energy. As a result, a small range of the incident solar spectrum near the bandgap energy of silicon can be efficiently converted into useful electrical energy.

Also, in accordance with a junction design of a PV cell, charge separation of electron-hole pairs is typically confined to a depletion region, which can be limited to a thickness of about 1 μm. Electron-hole pairs that are produced further than a diffusion or drift length from the depletion region typically do not charge separate and, thus, typically do not contribute to the conversion into electrical energy. The depletion region is typically positioned within the PV cell at a particular depth below a surface of the PV cell. The variation of the absorption coefficient of silicon across an incident solar spectrum can impose a compromise with respect to the depth and other characteristics of the depletion region that reduces the efficiency of the PV cell. For example, while a particular depth of the depletion region can be desirable for solar radiation at one wavelength, the same depth can be undesirable for solar radiation at a shorter wavelength. In particular, since the shorter wavelength solar radiation can penetrate below the surface to a lesser degree, electron-hole pairs that are produced can be too far from the depletion region to contribute to an electric current.

It is against this background that a need arose to develop the solar modules and related manufacturing methods described herein.

### SUMMARY

Embodiments of the invention relate to solar modules and related manufacturing methods. In one embodiment, a solar module includes: (1) a photovoltaic cell; and (2) a resonant cavity waveguide optically coupled to the photovoltaic cell, the resonant cavity waveguide including: (a) a top reflector; (b) a bottom reflector; and (c) an emission layer disposed between the top reflector and the bottom reflector with respect to an anti-node position within the resonant cavity waveguide, the emission layer configured to absorb incident solar radiation and emit radiation that is guided towards the photovoltaic cell, the emitted radiation including an energy band having a spectral width no greater than 80 nm at Full Width at Half Maximum.

In another embodiment, a solar module includes: (1) a photovoltaic cell; and (2) a spectral concentrator optically coupled to the photovoltaic cell and including a luminescent stack, the luminescent stack including: (a) a first reflector; (b) a second reflector; and (c) an emission layer disposed between the first reflector and the second reflector, the emission layer including a luminescent material having the formula: [AₐB_{b}Xₓ], A is selected from potassium, rubidium, and cesium; B is selected from germanium, tin, and lead; X is selected from chlorine, bromine, and iodine; a is in the range of 1 to 9; b is in the range of 1 to 5; and x is equal to a+2b.

In yet another embodiment, a solar module includes: (1) a photovoltaic cell; and (2) a luminescent stack defining a groove and including: (a) a first reflector; (b) a second reflector; (c) a first emission layer disposed between the first reflector and the second reflector; (d) a second emission layer disposed between the first emission layer and the second reflector; and (e) a bonding layer disposed between the first emission layer and the second emission layer, wherein the groove extends through at least a portion of the first emission layer and the second emission layer, and the photovoltaic cell is disposed with respect to the groove so as to be optically coupled to the first emission layer and the second emission layer.

Other aspects and embodiments of the invention are also contemplated. The foregoing summary and the following detailed description are not meant to restrict the invention to any particular embodiment but are merely meant to describe some embodiments of the invention.

### BRIEF DESCRIPTION OF THE DRAWINGS

For a better understanding of the nature and objects of some embodiments of the invention, reference should be made to the following detailed description taken in conjunction with the accompanying drawings. In the drawings, like reference numbers denote like elements, unless the context clearly dictates otherwise.

FIG. 1 illustrates a combined representation of an incident solar spectrum and measured absorption and emission spectra of UD930 in accordance with an embodiment of the invention.

FIG. 2 illustrates a solar module implemented in accordance with an embodiment of the invention.

FIG. 3 and FIG. 4 illustrate a spectral concentrator implemented in accordance with an embodiment of the invention.

FIG. 5 illustrates a combined representation of an incident solar spectrum, an emission spectrum of an emission layer, and a reflectivity spectrum of a reflector in accordance with an embodiment of the invention.

FIG. 6 through FIG. 19 illustrate luminescent stacks implemented as resonant cavity waveguides in accordance with various embodiments of the invention.

FIG. 20 through FIG. 25 illustrate solar modules implemented in accordance with various embodiments of the invention.

FIG. 26 and FIG. 27 illustrate manufacturing of a solar module according to an embodiment of the invention.

FIG. 28 illustrates manufacturing of a solar module according to another embodiment of the invention.

FIG. 29 illustrates a sample of a spectral concentrator formed in accordance with a bonding approach, according to an embodiment of the invention.

FIG. 30 illustrates a plot of transmittance of a reflector as a function of wavelength of light, according to an embodiment of the invention.

FIG. 31 illustrates a sample of a spectral concentrator formed in accordance with an integrated cavity approach, according to an embodiment of the invention.

FIG. 32 illustrates superimposed plots of edge emission spectra as a function of excitation power, according to an embodiment of the invention.

FIG. 33 illustrates superimposed plots of edge emission spectra for various excitation powers and superimposed plots of edge emission intensities as a function of time, according to an embodiment of the invention.

FIG. 34 illustrates superimposed plots of an edge emission spectrum for UD930 when incorporated within an integrated cavity sample and a typical emission spectrum for UD930 in the absence of resonant cavity effects, according to an embodiment of the invention.

FIG. 35 illustrates an edge emission spectrum for UD930 when incorporated within an integrated cavity sample and when excited with a white light source, according to an embodiment of the invention.

FIG. 36 illustrates superimposed plots of edge emission spectra, according to an embodiment of the invention.

FIG. 37 illustrates an edge emission spectrum for UD930 when incorporated within another integrated cavity sample and when excited with a white light source, according to an embodiment of the invention.

FIG. 38 illustrates an experimental set-up for performing photoluminescence measurements, according to an embodiment of the invention.

FIG. 39A through FIG. 39C illustrate plots of edge emission spectra in accordance with the experimental set-up of FIG. 38, according to an embodiment of the invention.

### DETAILED DESCRIPTION

### Overview

Embodiments of the invention relate to solar modules and related manufacturing methods. For some embodiments, a solar module includes a spectral concentrator and a set of PV cells that are optically coupled to the spectral concentrator. The spectral concentrator can perform a number of operations, including: (1) collecting incident solar radiation; (2) converting the incident solar radiation to substantially monochromatic radiation near a bandgap energy of the PV cells; and (3) conveying the converted radiation to the PV cells, where the converted radiation can be converted to useful electrical energy. By converting a wide range of energies of the incident solar radiation to a narrow band of energies matched to the bandgap energy of the PV cells, significant improvements in efficiency can be achieved. In addition, the design of the PV cells can be optimized or otherwise tailored based on this narrow band of energies. As described herein, further improvements in efficiency can be achieved by incorporating a suitable set of luminescent materials within the spectral concentrator and by exploiting resonant cavity effects in the design of the spectral concentrator.

### DEFINITIONS

The following definitions apply to some of the elements described with regard to some embodiments of the invention. These definitions may likewise be expanded upon herein.

As used herein, the singular terms “a,” “an,” and “the” include plural referents unless the context clearly dictates otherwise. Thus, for example, reference to a luminescent material can include multiple luminescent materials unless the context clearly dictates otherwise.

As used herein, the term “set” refers to a collection of one or more elements. Thus, for example, a set of layers can include a single layer or multiple layers. Elements of a set can also be referred to as members of the set. Elements of a set can be the same or different. In some instances, elements of a set can share one or more common characteristics.

As used herein, the term “adjacent” refers to being near or adjoining. Adjacent elements can be spaced apart from one another or can be in actual or direct contact with one another. In some instances, adjacent elements can be connected to one another or can be formed integrally with one another.

As used herein, the terms “connect,” “connected,” and “connection” refer to an operational coupling or linking. Connected elements can be directly coupled to one another or can be indirectly coupled to one another, such as via another set of elements.

As used herein, the terms “substantially” and “substantial” refer to a considerable degree or extent. When used in conjunction with an event or circumstance, the terms can refer to instances in which the event or circumstance occurs precisely as well as instances in which the event or circumstance occurs to a close approximation, such as accounting for typical tolerance levels of the manufacturing operations described herein.

As used herein, the terms “optional” and “optionally” mean that the subsequently described event or circumstance may or may not occur and that the description includes instances where the event or circumstance occurs and instances in which it does not.

As used herein, relative terms, such as “outer,” “inner,” “top,” “bottom,” “middle,” “side,” “exterior,” “external,” “interior,” and “internal,” refer to an orientation of a set of elements with respect to one another, such as in accordance with the drawings, but do not require a particular orientation of those elements during manufacturing or use.

As used herein, the term “ultraviolet range” refers to a range of wavelengths from about 5 nm to about 400 nm.

As used herein, the term “visible range” refers to a range of wavelengths from about 400 nm to about 700 nm.

As used herein, the term “infrared range” refers to a range of wavelengths from about 700 nm to about 2 mm. The infrared range includes the “near infrared range,” which refers to a range of wavelengths from about 700 nm to about 5 μm, the “middle infrared range,” which refers to a range of wavelengths from about 5 μm to about 30 μm, and the “far infrared range,” which refers to a range of wavelengths from about 30 μm to about 2 mm.

As used herein, the terms “reflection,” “reflect,” and “reflective” refer to a bending or a deflection of light, and the term “reflector” refers to an element that causes, induces, or is otherwise involved in such bending or deflection. A bending or a deflection of light can be substantially in a single direction, such as in the case of specular reflection, or can be in multiple directions, such as in the case of diffuse reflection or scattering. In general, light incident upon a material and light reflected from the material can have wavelengths that are the same or different.

As used herein, the terms “luminescence,” “luminesce,” and “luminescent” refer to an emission of light in response to an energy excitation. Luminescence can occur based on relaxation from excited electronic states of atoms or molecules and can include, for example, chemiluminescence, electroluminescence, photoluminescence, thermoluminescence, triboluminescence, and combinations thereof. Luminescence can also occur based on relaxation from excited states of quasi-particles, such as excitons, bi-excitons, and exciton-polaritons. For example, in the case of photoluminescence, which can include fluorescence and phosphorescence, an excited state can be produced based on a light excitation, such as absorption of light. In general, light incident upon a material and light emitted by the material can have wavelengths that are the same or different.

As used herein with respect to photoluminescence, the term “quantum efficiency” refers to a ratio of the number of output photons to the number of input photons. Quantum efficiency of a photoluminescent material can be characterized with respect to its “internal quantum efficiency,” which refers to a ratio of the number of photons emitted by the photoluminescent material to the number of photons absorbed by the photoluminescent material. In some instances, a photoluminescent material can be included within a structure that is exposed to solar radiation, and the structure can direct, guide, or propagate emitted light towards a PV cell. In such instances, another characterization of quantum efficiency can be an “external quantum efficiency” of the structure, which refers to a ratio of the number of photons that reach the PV cell to the number of solar photons that are absorbed by the photoluminescent material within the structure. Alternatively, quantum efficiency of the structure can be characterized with respect to its “overall external quantum efficiency,” which refers to a ratio of the number of photons that reach the PV cell to the number of solar photons that are incident upon the structure. As can be appreciated, an overall external quantum efficiency of a structure can account for potential losses, such as reflection, that reduce the fraction of incident solar photons that can reach a photoluminescent material. A further characterization of quantum efficiency can be an “energy quantum efficiency,” in which the various ratios discussed above can be expressed in terms of ratios of energies, rather than ratios of numbers of photons. An energy-based quantum efficiency can be less than its corresponding photon number-based quantum efficiency in the event of down-conversion, namely if a higher energy photon is absorbed and converted to a lower energy emitted photon.

As used herein, the term “absorption spectrum” refers to a representation of absorption of light over a range of wavelengths. In some instances, an absorption spectrum can refer to a plot of absorbance (or transmittance) of a material as a function of wavelength of light incident upon the material.

As used herein, the term “emission spectrum” refers to a representation of emission of light over a range of wavelengths. In some instances, an emission spectrum can refer to a plot of intensity of light emitted by a material as a function of wavelength of the emitted light.

As used herein, the term “excitation spectrum” refers to another representation of emission of light over a range of wavelengths. In some instances, an excitation spectrum can refer to a plot of intensity of light emitted by a material as a function of wavelength of light incident upon the material.

As used herein, the term “Full Width at Half Maximum” or “FWHM” refers to a measure of spectral width. In some instances, a FWHM can refer to a width of a spectrum at half of a peak intensity value.

As used herein with respect to an absorption spectrum or an excitation spectrum, the term “substantially flat” refers to being substantially invariant with respect to a change in wavelength. In some instances, a spectrum can be referred to as being substantially flat over a range of wavelengths if absorbance or intensity values within that range of wavelengths exhibit a standard deviation of less than about 20 percent with respect to an average intensity value, such as less than about 10 percent or less than about 5 percent.

As used herein with respect to an emission spectrum, the term “substantially monochromatic” refers to emission of light over a narrow range of wavelengths. In some instances, an emission spectrum can be referred to as being substantially monochromatic if a spectral width is no greater than about 120 nm at FWHM, such as no greater than about 100 nm at FWHM, no greater than about 80 nm at FWHM, or no greater than about 50 nm at FWHM.

As used herein, the term “nanometer range” or “nm range” refers to a range of dimensions from about 1 nm to about 1 μm. The nm range includes the “lower nm range,” which refers to a range of dimensions from about 1 nm to about 10 nm, the “middle nm range,” which refers to a range of dimensions from about 10 nm to about 100 nm, and the “upper nm range,” which refers to a range of dimensions from about 100 nm to about 1 μm.

As used herein, the term “micrometer range” or “μm range” refers to a range of dimensions from about 1 μm to about 1 mm. The μm range includes the “lower μm range,” which refers to a range of dimensions from about 1 μm to about 10 μm, the “middle μm range,” which refers to a range of dimensions from about 10 μm to about 100 μm, and the “upper μm range,” which refers to a range of dimensions from about 100 μm to about 1 mm.

As used herein, the term “size” refers to a characteristic dimension of an object. In the case of an object that is spherical, a size of the object can refer to a diameter of the object. In the case of an object that is non-spherical, a size of the object can refer to an average of various orthogonal dimensions of the object. Thus, for example, a size of an object that is spheroidal can refer to an average of a major axis and a minor axis of the object. When referring to a set of objects as having a particular size, it is contemplated that the objects can have a distribution of sizes around that size. Thus, as used herein, a size of a set of objects can refer to a typical size of a distribution of sizes, such as an average size, a median size, or a peak size.

As used herein, the term “nanoparticle” refers to a particle that has a size in the nm range. A nanoparticle can have any of a variety of shapes, such as box-shaped, cube-shaped, cylindrical, disk-shaped, spherical, spheroidal, tetrahedral, tripodal, tube-shaped, pyramid-shaped, or any other regular or irregular shape, and can be formed from any of a variety of materials. In some instances, a nanoparticle can include a core formed from a first material, which core can be optionally surrounded by a coating or a shell formed from a second material. The first material and the second material can be the same or different. Depending on the configuration of a nanoparticle, the nanoparticle can exhibit size dependent characteristics associated with quantum confinement. However, it is also contemplated that a nanoparticle can substantially lack size dependent characteristics associated with quantum confinement or can exhibit such size dependent characteristics to a low degree.

As used herein, the term “microparticle” refers to a particle that has a size in the μm range. A microparticle can have any of a variety of shapes, such as box-shaped, cube-shaped, cylindrical, disk-shaped, spherical, spheroidal, tetrahedral, tripodal, tube-shaped, pyramid-shaped, or any other regular or irregular shape, and can be formed from any of a variety of materials. In some instances, a microparticle can include a core formed from a first material, which core can be optionally surrounded by a coating or a shell formed from a second material. The first material and the second material can be the same or different.

As used herein, the term “dopant” refers to a chemical entity that is present in a material as an additive or an impurity. In some instances, the presence of a dopant in a material can alter a set of characteristics of the material, such as its chemical, magnetic, electronic, or optical characteristics.

### Luminescent Materials

A variety of luminescent materials can be used to form the solar modules described herein. Examples include organic fluorophors, inorganic fluorophors and phosphors, nanoparticles, and semiconductor materials.

Inorganic fluorophors having optical transitions in the range of about 900 nm to about 980 nm can be suitable for use with PV cells based on silicon. An inorganic fluorophor having a suitable emission wavelength can be selected based on an atomic moiety involved. For example, inorganic fluorophors with luminescence derived from transition or rare earth atoms can be used. Other examples of inorganic fluorophors include oxides or chalcoginides with luminescence derived from a defect state in a crystal. Inorganic phosphors can also be suitable for use with PV cells based on silicon.

Nanoparticles, such as nanoparticles formed from silicon or germanium, can be useful for spectral concentration. The nanoparticles can be formed as self-assembled nanoparticles, such as by vacuum deposition, or as discrete nanoparticles, such as in a colloidal solution. The nanoparticles can be formed with a high internal quantum efficiency for photoluminescence by reducing defect density, typically to less than one defect per nanoparticle. In addition, surfaces of the nanoparticles can be properly terminated to enhance the photoluminescence. Emission wavelength of the nanoparticles can be dependent upon, or controlled by, their sizes. A narrow distribution of sizes can be desirable, so that a resulting spectral width is narrow, and there is reduced self-absorption of emitted light from smaller-sized nanoparticles by larger-sized nanoparticles.

Semiconductor materials, such as indium phosphide or InP, with a bandgap energy that is near and slightly above the bandgap energy of PV cells can also be used. In particular, semiconductor materials with a bandgap energy in the range of about 1.1 eV to about 1.5 eV, such as from about 1.2 eV to about 1.4 eV, at 300K can be suitable in spectral concentrators for PV cells based on silicon.

For example, indium phosphide has a direct, allowed bandgap energy of about 1.35 eV and an absorption coefficient of about 10⁵ cm⁻¹. Indium phosphide, or another semiconductor material, can be deposited as a film in a single layer or in multiple layers interspersed with other layers. The other layers can be included for optical and efficiency purposes and for chemical and environmental protection, such as silica and alumina as hermetic sealants. The absorption coefficient of indium phosphide, or another semiconductor material, in the optical wavelengths of the solar spectrum can be in the range of about 10⁴ cm⁻¹ or greater at energies larger than the bandgap edge. A film thickness in the micrometer range, such as a few micrometers or less, can have an optical density of 2 or more to allow at least about 99 percent of incident solar radiation to be absorbed. Indium phosphide, or another semiconductor material, can also be deposited into porous matrices or deposited as nanoparticles. For example, indium phosphide can be formed as nanoparticles and dispersed in a matrix such as an optically stable polymer or an inorganic glass. The total amount of absorbing semiconductor material can be equivalent to an optical density of 2 or more to allow at least about 99 percent of incident solar radiation to be absorbed. Use of a resonant cavity waveguide allows the efficient use of semiconductor materials in the form of thin films. Furthermore, the resonant cavity waveguide, by modification of a radiation matrix, allows the use of semiconductor materials with forbidden optical transitions and indirect optical transitions in the desired wavelength range for spectral concentration. Lower bandgap energy materials can also be made to luminesce by quantum confinement, either in thin films or by formation of nanoparticles.

A new class of luminescent materials is disclosed in U.S. patent application Ser. No. 11/689,381, (now U.S. Pat. No. 7,641,815), entitled “Luminescent Materials that Emit Light in the Visible Range or the Near Infrared Range” and filed on Mar. 21, 2007, the disclosure of which is incorporated herein by reference in its entirety. This class of luminescent materials includes semiconductor materials that can be represented with reference to the formula:

[AₐB_{b}Xₓ][dopants] (I)

In formula (I), A is selected from elements of Group IA, such as sodium (e.g., as Na(I) or Na¹⁺), potassium (e.g., as K(I) or K¹⁺), rubidium (e.g., as Rb(I) or Rb¹⁺), and cesium (e.g., as Cs(I) or Cs¹⁺); B is selected from elements of Group VA, such as vanadium (e.g., as V(III) or V⁺³), elements of Group IB, such as copper (e.g., as Cu(I) or Cu⁺¹), silver (e.g., as Ag(I) or Ag⁺¹), and gold (e.g., as Au(I) or Au⁺¹), elements of Group IIB, such as zinc (e.g., as Zn(II) or Zn⁺²), cadmium (e.g., as Cd(II) or Cd⁺²), and mercury (e.g., as Hg(II) or Hg⁺²), elements of Group IIIB, such as gallium (e.g., as Ga(I) or Ga⁺¹), indium (e.g., as In(I) or In⁺¹), and thallium (e.g., as Tl(I) or Tl⁺¹), elements of Group IVB, such as germanium (e.g., as Ge(II) or Ge⁺² or as Ge(IV) or Ge⁺⁴), tin (e.g., as Sn(II) or Sn⁺² or as Sn(IV) or Sn⁺⁴), and lead (e.g., as Pb(II) or Pb⁺² or as Pb(IV) or Pb⁺⁴), and elements of Group VB, such as bismuth (e.g., as Bi(III) or Bi⁺³); and X is selected from elements of Group VIIB, such as fluorine (e.g., as F⁻¹), chlorine (e.g., as Cl⁻¹), bromine (e.g., as Br⁻¹), and iodine (e.g., as I⁻¹). Still referring to formula (I), a is an integer that can be in the range of 1 to 12, such as from 1 to 9 or from 1 to 5; b is an integer that can be in the range of 1 to 8, such as from 1 to 5 or from 1 to 3; and x is an integer that can be in the range of 1 to 12, such as from 1 to 9 or from 1 to 5. In some instances, a can be equal to 1, and x can be equal to 1+2b. It is also contemplated that one or more of a, b, and x can have fractional values within their respective ranges. It is further contemplated that Xₓ in formula (I) can be more generally represented as XₓX′_{X′}X″_{x″}, where X, X′, and X″ can be independently selected from elements of Group VIIB, and the sum of x, x′, and x″ can be in the range of 1 to 12, such as from 1 to 9 or from 1 to 5. With reference to the generalized version of formula (I), a can be equal to 1, and the sum of x, x′, and x″ can be equal to 1+2b. Dopants optionally included in a luminescent material represented by formula (I) can be present in amounts that are less than about 5 percent, such as less than about 1 percent, in terms of elemental composition, and can derive from reactants that are used to form the luminescent material. In particular, the dopants can include cations and anions, which form electron acceptor/electron donor pairs that are dispersed within a microstructure of the luminescent material.

Luminescent materials represented by formula (I) can be formed via reaction of a set of reactants at high yields and at moderate temperatures and pressures. The reaction can be represented with reference to the formula:

Source(B)+Source(A, X)→Luminescent Material (II)

In formula (II), source(B) serves as a source of B, and, in some instances, source(B) can also serve as a source of dopants. In the case that B is tin, for example, source(B) can include one or more types of tin-containing compounds selected from tin(II) compounds of the form BY, BY₂, B₃Y₂, and B₂Y and tin(IV) compounds of the form BY₄, where Y can be selected from elements of Group VIB, such as oxygen (e.g., as O⁻²); elements of Group VIIB, such as fluorine (e.g., as F⁻¹), chlorine (e.g., as Cl⁻¹), bromine (e.g., as Br⁻¹), and iodine (e.g., as I⁻¹); and poly-elemental chemical entities, such as nitrate (i.e., NO₃⁻¹), thiocyanate (i.e., SCN⁻¹), hypochlorite (i.e., OCl⁻¹), sulfate (i.e., SO₄⁻²), orthophosphate (i.e., PO₄⁻³), metaphosphate (i.e., PO₃⁻¹), oxalate (i.e., C₂O₄⁻²), methanesulfonate (i.e., CH₃SO₃⁻¹), trifluoromethanesulfonate (i.e., CF₃SO₃⁻¹), and pyrophosphate (i.e., P₂O₇⁻⁴). Examples of tin(II) compounds include tin(II) fluoride (i.e., SnF₂), tin(II) chloride (i.e., SnCl₂), tin(II) chloride dihydrate (i.e., SnCl₂.2H₂O), tin(II) bromide (i.e., SnBr₂), tin(II) iodide (i.e., SnI₂), tin(II) oxide (i.e., SnO), tin(II) sulfate (i.e., SnSO₄), tin(II) orthophosphate (i.e., Sn₃(PO₄)₂), tin(II) metaphosphate (i.e., Sn(PO₃)₂), tin(II) oxalate (i.e., Sn(C₂O₄)), tin(II) methanesulfonate (i.e., Sn(CH₃SO₃)₂), tin(II) pyrophosphate (i.e., Sn₂P₂O₇), and tin(II) trifluoromethanesulfonate (i.e., Sn(CF₃SO₃)₂). Examples of tin(IV) compounds include tin(IV) chloride (i.e., SnCl₄), tin(IV) iodide (i.e., SnI₄), and tin(IV) chloride pentahydrate (i.e., SnCl₄.5H₂O). Still referring to formula (II), source(A, X) serves as a source of A and X, and, in some instances, source(A, X) can also serve as a source of dopants. Examples of source(A, X) include alkali halides of the form AX. In the case that A is cesium, for example, source(A, X) can include one or more types of cesium(I) halides, such as cesium(I) fluoride (i.e., CsF), cesium(I) chloride (i.e., CsCl), cesium(I) bromide (i.e., CsBr), and cesium(I) iodide (i.e., CsI). It is contemplated that different types of source(A, X) can be used (e.g., as source(A, X), source(A, X′), and source(A, X″) with X, X′, and X′ independently selected from elements of Group VIIB) to form a resulting luminescent material having mixed halides.

Several luminescent materials represented by formulas (I) and (II) have characteristics that are desirable for spectral concentration. In particular, the luminescent materials can exhibit photoluminescence with a high internal quantum efficiency that is greater than about 6 percent, such as at least about 10 percent, at least about 20 percent, at least about 30 percent, at least about 40 percent, or at least about 50 percent, and can be up to about 90 percent or more. Also, the luminescent materials can exhibit photoluminescence with a narrow spectral width that is no greater than about 120 nm at FWHM, such as no greater than about 100 nm, no greater than about 80 nm, or no greater than about 50 nm at FWHM. Thus, for example, the spectral width can be in the range of about 20 nm to about 120 nm at FWHM, such as from about 50 nm to about 120 nm, from about 50 nm to about 100 nm, from about 20 nm to about 80 nm, from about 50 nm to about 80 nm, or from about 20 nm to about 50 nm at FWHM. Incorporation of the luminescent materials within a resonant cavity waveguide can further narrow the spectral width, such as in the range of about 1 nm to about 20 nm or in the range of about 1 nm to about 10 nm at FWHM.

In addition, the luminescent materials can have bandgap energies that are tunable to desirable levels by adjusting reactants and processing conditions that are used. For example, a bandgap energy can correlate with A, with the order of increasing bandgap energy corresponding to, for example, cesium, rubidium, potassium, and sodium. As another example, the bandgap energy can correlate with X, with the order of increasing bandgap energy corresponding to, for example, iodine, bromine, chlorine, and fluorine. This order of increasing bandgap energy can translate into an order of decreasing peak emission wavelength. Thus, for example, a luminescent material including iodine can sometimes exhibit a peak emission wavelength in the range of about 900 nm to about 1 μm, while a luminescent material including bromine or chlorine can sometimes exhibit a peak emission wavelength in the range of about 700 nm to about 800 nm. By tuning bandgap energies, the resulting photoluminescence can have a peak emission wavelength located within a desirable range of wavelengths, such as the visible range or the infrared range. In some instances, the peak emission wavelength can be located in the near infrared range, such as from about 900 nm to about 1 μm, from about 910 nm to about 1 μm, from about 910 nm to about 980 nm, or from about 930 nm to about 980 nm. Incorporation of the luminescent materials within a resonant cavity waveguide can shift or otherwise modify the peak emission wavelength and, in some instances, can yield multiple optical modes each associated with a respective peak emission wavelength and with a respective spectral width.

Moreover, the photoluminescence characteristics described above can be relatively insensitive over a wide range of excitation wavelengths. Indeed, this unusual characteristic can be appreciated with reference to excitation spectra of the luminescent materials, which excitation spectra can be substantially flat over a range of excitation wavelengths encompassing portions of the ultraviolet range, the visible range, and the infrared range. In some instances, the excitation spectra can be substantially flat over a range of excitation wavelengths from about 200 nm to about 1 μm, such as from about 200 nm to about 980 nm or from about 200 nm to about 950 nm. Similarly, absorption spectra of the luminescent materials can be substantially flat over a range of excitation wavelengths encompassing portions of the ultraviolet range, the visible range, and the infrared range. In some instances, the absorption spectra can be substantially flat over a range of excitation wavelengths from about 200 nm to about 1 μm, such as from about 200 nm to about 980 nm or from about 200 nm to about 950 nm.

Certain luminescent materials represented by formulas (I) and (II) can also be represented with reference to the formula:

[AₐSn_{b}Xₓ][dopants] (III)

In formula (III), A is selected from sodium, potassium, rubidium, and cesium; and X is selected from chlorine, bromine, and iodine. Still referring to formula (III), x is equal to a+2b. In some instances, a can be equal to 1, and x can be equal to 1+2b. Several luminescent materials with desirable characteristics can be represented as CsSnX₃ and include materials designated as UD700 and UD930. In the case of UD700, X is bromine, and, in the case of UD930, X is iodine. UD700 exhibits a peak emission wavelength at about 700 nm, while UD930 exhibits a peak emission wavelength in the range of about 940 nm to about 950 nm. The spectral width of UD700 and UD930 is narrow (e.g., about 50 meV or less at FWHM), and the absorption spectrum is substantially flat from the absorption edge into the far ultraviolet. Photoluminescent emission of UD700 and UD930 is stimulated by a wide range of wavelengths of solar radiation up to the absorption edge of these materials at about 700 nm for UD700 and about 950 nm for UD930. The chloride analog, namely CsSnCl₃, exhibits a peak emission wavelength at about 450 nm, and can be desirable for certain implementations. Other luminescent materials with desirable characteristics include RbSnX₃, such as RbSnI₃ that exhibits a peak emission wavelength in the range of about 715 nm to about 720 nm. Each of these luminescent materials can be deposited as a film in a single layer or in multiple layers interspersed with other layers formed from the same luminescent material or different luminescent materials.

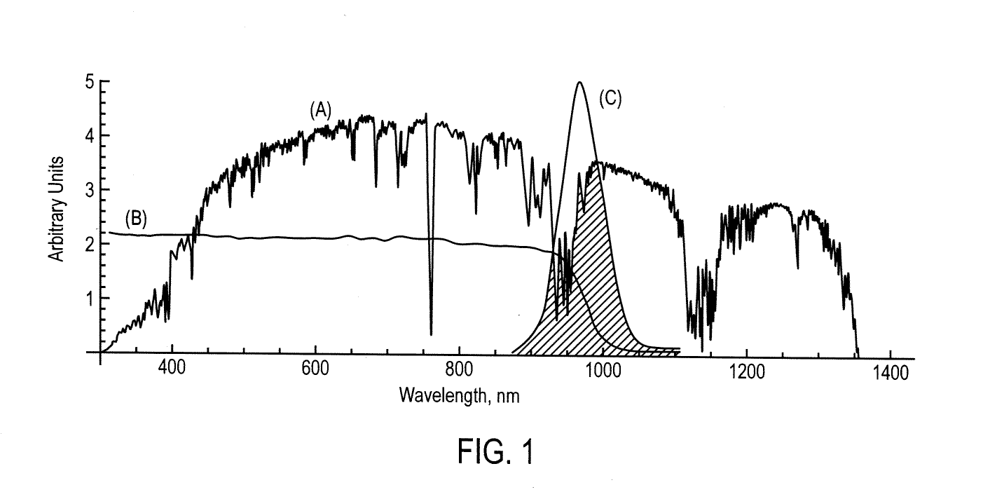

Desirable characteristics of UD930 can be further appreciated with reference to FIG. 1, which illustrates a combined representation of a solar spectrum and measured absorption and emission spectra of UD930 in accordance with an embodiment of the invention. In particular, FIG. 1 illustrates the AM1.5G solar spectrum (referenced as (A)), which is a standard solar spectrum representing incident solar radiation on the surface of the earth. The AM1.5G solar spectrum has a gap in the region of 930 nm due to atmospheric absorption. In view of the AM1.5G solar spectrum and characteristics of PV cells based on silicon, the absorption spectrum (referenced as (B)) and emission spectrum (referenced as (C)) of UD930 render this material particularly effective for spectral concentration when incorporated within an emission layer. In particular, photoluminescence of UD930 is substantially located in the gap of the AM1.5G solar spectrum, with the peak emission wavelength of about 950 nm falling within the gap. This, in turn, allows the use of reflectors (e.g., above and below the emission layer) that are tuned to reflect emitted radiation back towards the emission layer, without significant reduction of incident solar radiation that can pass through the reflectors and reach the emission layer. Also, the absorption spectrum of UD930 is substantially flat and extends from the absorption edge at about 950 nm through substantially the full AM1.5G solar spectrum into the ultraviolet. In addition, the peak emission wavelength of about 950 nm (or about 1.3 eV) is matched to the absorption edge of PV cells based on silicon, and the spectral width is about 50 meV or less at FWHM (or about 37 nm or less at FWHM). The absorption coefficient of silicon is about 10² cm⁻¹ in this range of emission wavelengths, and junctions within the PV cells can be designed to efficiently absorb the emitted radiation and convert the radiation into electron-hole pairs. As a result, UD930 can broadly absorb a wide range of wavelengths from incident solar radiation, while emitting a narrow range of wavelengths that are matched to silicon to allow a high conversion efficiency of incident solar radiation into electricity. Furthermore, the absorption spectrum and the emission spectrum of UD930 overlap to a low degree, thereby reducing instances of self-absorption that would otherwise lead to reduced conversion efficiency.

Other luminescent materials that are suitable in spectral concentrators include Zn₃P₂, Cu₂O, CuO, CuInGaS, CuInGaSe, CuₓS, CuInSe, InSₓ, ZnS, SrS, CaS, PbS, InSeₓ, CdSe, and so forth. Additional suitable luminescent materials include CuInSe₂ (E_{g} of about 1.0), CuInTe₂ (E_{g} of about 1.0-1.1), CuInS₂ (E_{g} of about 1.53), CuAlTe₂ (E_{g} of about 1.3-2.2), CuGaTe₂ (E_{g} of about 1.23), CuGaSe₂ (E_{g} of about 1.7), AgInSe₂ (E_{g} of about 1.2), AgGaSe₂ (E_{g} of about 1.8), AgAlSe₂ (E_{g} of about 1.66), AgInS₂ (E_{g} of about 1.8), AgGaTe₂ (E_{g} of about 1.1), AgAlTe₂ (E_{g} of about 0.56), and so forth.

Table I below lists a variety of semiconductor materials that can be used for the solar modules described herein.

TABLE I
Examples of Spectral Concentrator Materials

| material | E_{g} (eV, 300K) | type | material | E_{g} (eV, 300K) | type |
|---|---|---|---|---|---|
| Ge QD | 0.8 to 1.5 | | BaSnO₃ | 1.4 | |
| Si QD | 1.2 to 1.5 | | CrCa₂GeO₄ | 1.1 | |
| InP | 1.34 | direct | LaMnO₃ | 1.3 | |
| GaₓIn₁₋ₓAs_{y}P_{1-y} | 1.2 to 1.4 | | Ba₁₋ₓSrₓSi₂ | 1.2 | |
| CdTe | 1.475 | direct | BaSi₂ | 1.3 | direct |
| Ga₂Te₃ | 1.2 | direct | ZnGeAs₂ | 1.12 | direct |
| In₂Se₃ | 1.3 | direct | CdSnP₂ | 1.17 | direct |
| InSe | 1.2 | indirect | Cu₃AsS₄ | 1.24 | |
| In₂Te₃ | 1.1 | direct | CdIn₂Te₄ | 1.25 | direct |
| InTe | 1.16 | direct | Na₃Sb | 1.1 | |
| CuGaTe₂ | 1.2 | | K₃Sb | 1.1 | |
| CuInS₂ | 1.5 | | CuO | 1.4 | indirect |
| Cu₃In₅Se₉ | 1.1 | | Cu₂O | 1.4 | forbidden, direct |
| CuInS₂₋ₓSeₓ | 1.1 to 1.4 | direct | Cu₂S | 1.3 | direct |
| Ag₃In₅Se₉ | 1.22 | | Cu₂Se | 1.2 | direct |
| AgGaTe₂ | 1.3 | direct | Cd₄Sb₃ | 1.4 | |
| AgInSe₂ | 1.2 | direct | TlS | 1.36 | direct |
| CuTlS₂ | 1.4 | | BiS₃ | 1.3 | |
| Cr₂S₃ | 1.1 | | BiI₃ | 1.35 | |
| FeP₂ | 0.4 | | NiP₂ | 0.7 | |
| FeSi₂ | 0.8 | | SnS | 1.1 | |
| Mg₂Si | 0.8 | | SnSe | 0.9 | |
| MoS₂ inte. | <1.4 | | Ti₁₊ₓS₂ | 0.7 | |
| MoSe₂ inte. | <1.2 | | TiS₃₋ₓ | 0.9 | |
| WS₂ inte. | 1.1 | | Zn₃N₂ | 1.2 | |
| Sr₂CuO₂Cl | 1.3 | direct | Ag₈GeS₆ | 1.39 | |
| ZnGeP₂ | 1.3 | direct | Ag₈SnS₆ | 1.28 | |
| Zn₃P₂ | 1.35 | indirect | CdInSe₂ | 1.4 | |
| Zn₃P₂ | 1.4 | direct | HgTlS₂ | 1.25 | |
| β ZnP₂ | 1.3 | direct | BiSeI | 1.3 | |
| KTaO₃ | 1.5 | | MgGa₂S₄ | 1.2 | |

Absorption and emission characteristics are typically several orders of magnitude lower for semiconductor materials having indirect optical transitions or forbidden optical transitions compared to those materials having direct optical transitions. However, by modification of a radiation matrix, resonant cavity effects can enhance absorption and emission characteristics and allow the use of semiconductor materials having indirect or forbidden optical transitions. Referring to Table I, CuO is an indirect bandgap semiconductor material having a bandgap energy of about 1.4 eV, and Cu₂O has a direct but spin forbidden bandgap energy of about 1.4 eV. By incorporating within a resonant cavity waveguide, either, or both, CuO and Cu₂O can be used for spectral concentration. Still referring to Table I, Zn₃P₂ has an indirect optical transition of about 50 meV below a direct optical transition of about 1.4 eV. Resonant cavity effects can allow coupling of the indirect optical transition to the higher energy direct optical transition, thereby providing enhanced absorption and emission for use as spectral concentrators.

In addition to the characteristics noted above, the semiconductor materials listed in Table I typically have an index of refraction greater than about 3. For example, InP has an index of refraction of about 3.2. Because of internal reflection, less than about 18 percent of light within a luminescent stack can exit to air. In some instances, light normal to a surface of the luminescent stack can have a Fresnel reflection loss of about 25 percent to air. Anti-reflection coatings can be used to enhance optical coupling of the light from the luminescent stack to a PV cell.

To reduce self-absorption of emitted light within a luminescent stack, luminescence can occur via exciton emission. An exciton corresponds to an electron-hole pair, which can be formed as a result of light absorption. A bound or free exciton can have a Stokes shift equal to an exciton binding energy. Most semiconductor materials have exciton binding energies of less than about 20 meV or less than about 15 meV. Room temperature is about 25 meV, so excitons are typically not present at room temperature for these materials. For solar applications, a binding energy in the range of about 20 meV to about 100 meV or in the range of about 15 meV to about 100 meV can be desirable, such as from about 25 meV to about 100 meV, from about 15 meV to about 25 meV, from about 25 meV to about 50 meV, from about 25 meV to about 35 meV, or from about 35 meV to about 50 meV. An even larger binding energy can sometimes lead to a Stokes shift in the photoluminescence from the absorption edge that results in an absorption gap, which can sometimes lead to lower solar energy conversion efficiencies. Semiconductor materials with large exciton binding energies can be incorporated in a resonant cavity waveguide to yield suppression of emission in a vertical direction and stimulated emission along a plane of the cavity waveguide. The larger a Stokes shift, or exciton binding energy, the more tolerant the cavity waveguide can be with respect to imperfections. Thus, the cavity waveguide can be readily formed in an inexpensive manner, without resorting to techniques such as Molecular Beam Epitaxy (“MBE”). Thermal quenching, namely the reduction of luminescence intensity with an increase in temperature, can also be reduced or eliminated by generating an exciton with a binding energy greater than the Boltzmann temperature, which is about 25 meV at room temperature. Several semiconductor materials represented by formula (III) have large exciton binding energies. For example, UD930 has an exciton binding energy in the range of about 10 meV to about 50 meV, such as about 30 meV or about 20 meV. Some semiconductor materials, such as CdTe and HgTe, have excitons with large binding energies and are present at room temperature. However, some of these semiconductor materials may be toxic or relatively expensive. Other semiconductor materials have intrinsic excitons at room temperature, such as bismuth triiodide or BiI₃, and can be desirable for the solar modules described herein.

Certain layered semiconductor materials, such as tin and lead halides, can have bandgap and exciton energies tuned by separation of inorganic layers with organic components, such as amines or diamines as organic spacers. These hydrid materials can have large binding energies up to several hundred meV's. The large binding energies can allow a strong effect in a resonant cavity waveguide that is tolerant to defects, roughness, scattering centers, and other imperfections. These hybrid materials can be relatively straightforward to form and be readily coated from solution or in a vacuum, such as using Molecular Layer Deposition (“MLD”). Examples include organic-inorganic quantum well materials, conducting layered organic-inorganic halides containing 110-oriented perovskite sheets, hybrid tin iodide perovskite semiconductor materials, and lead halide-based perovskite-type crystals. Certain aspects of these semiconductor materials are described in Ema et al., “Huge Exchange Energy and Fine Structure of Excitons in an Organic-Inorganic Quantum Well,” Physical Review B, Vol. 73, pp. 241310-1 to 241310-4 (2006); Mitzi et al., “Conducting Layered Organic-inorganic Halides Containing 110-Oriented Perovskite Sheets,” Science, Vol. 267, pp. 1473-1476 (1995); Kagan et al., “Organic-Inorganic Hybrid Materials as Semiconducting Channels in Thin-Film Field-Effect Transistors,” Science, Vol. 286, pp. 945-947 (1999); Mitzi, “Solution-processed Inorganic Semiconductors,” J. Mater. Chem., Vol. 14, pp. 2355-2365 (2004); Symonds et al., “Emission of Hybrid Organic-inorganic Exciton Plasmon Mixed States,” Applied Physics Letters, Vol. 90, 091107 (2007); Zoubi et al., “Polarization Mixing in Hybrid Organic-Inorganic Microcavities,” Organic Electronics, Vol. 8, pp. 127-135 (2007); Knutson et al., “Tuning the Bandgap in Hybrid Tin Iodide Perovskite Semiconductors Using Structural Templating,” Inorg. Chem., Vol. 44, pp. 4699-4705 (2005); and Tanaka et al., “Comparative Study on the Excitons in Lead-halide-based Perovskite-type crystals CH₃NH₃PbBr₃ CH₃NH₃PbI₃,” Solid State Communications, Vol. 127, pp. 619-623 (2003), the disclosures of which are incorporated herein by reference in their entireties.

Also, other layered materials, such as tin sulfide, tin selenide, titanium sulfide, and others listed in Table I, can be tuned by intercalating other materials between the layered materials. A suitable deposition technique can be used to make layered materials with tuned bandgap energies and tuned exciton binding energies. Tuning an exciton to higher energy can reduce self-absorption and enhance the probability of lasing. Such material-process combination can be used to develop a low self-absorption luminescent material by tuned exciton luminescent emission. This can be further combined with a resonant cavity waveguide, in either a weak or strong coupling regime, to produce a low loss, high quantum efficiency structure.

Several semiconductor materials represented by formula (III) can have layered microstructures. For example and without wishing to be bound by a particular theory, UD930 can be polycrystalline with a layered microstructure relative to natural axes of the material. When incorporated within a resonant cavity waveguide, UD930 can exhibit an exciton emission that forms exciton-polaritons in the cavity waveguide. The cavity waveguide can be highly efficient, even though the cavity waveguide can be formed with relatively low precision and without control at nanometer tolerances. In some instances, the resulting emission can be indicative of a polariton laser operating in a strong coupling regime.

Another way to reduce self-absorption is via the use of orientated birefringence. In particular, one way to reduce self-absorption in a specific direction within a single crystal or film is to orient a birefringent material. Birefringence refers to a different refractive index along two or more different directions of a material. A birefringent material, such as a semiconductor material, has two or more different bandgap energies along different crystal axes. If a crystal anisotropy has a bandgap in the visible region of an optical spectrum, the material can be referred to as being dichoric rather than birefringent. Various birefringent semiconductor materials can be used in spectral concentrators, such as CuInSe₂₋ₓSₓ, Zn₃N₂, and perovskites such as CsSn₁₊ₓI₃₊₂ₓ. Since there are two or more absorption edges or bandgap energies for a birefringent material, a resulting film can be deposited in an oriented state with the higher bandgap energy (i.e., shorter wavelength absorption edge) along a direction facing towards PV cells. In this case, emitted light in the direction facing towards the PV cells can have a lower absorbance because the emission wavelength is longer than the higher bandgap energy. The use of resonant cavity effects and reflectors can suppress emission in other, more highly self-absorbed directions.

Thermal quenching and self-absorption can also be reduced by modifying material characteristics. For semiconductor materials, an absorption edge can become tilted with increasing temperature and certain types of doping. This absorption edge tilt can sometimes lead to increased self-absorption, and can be described by the Elliott equation. Proper doping and interface or surface modification can be used to control this absorption edge tilt to reduce instances of thermal quenching and self-absorption. In the case of nanoparticles formed of a semiconductor material, coatings formed on the nanoparticles can alter emission characteristics of the semiconductor material by the “Bragg Onion” technique.

The solar spectrum on the surface of the earth ranges from the ultraviolet into the infrared. Photons absorbed from the ultraviolet to about 1.3 eV are about 49.7 percent of the total number of photons and about 46.04 percent of the total energy. Of the absorbed photons at 100 percent internal quantum efficiency, a luminescent material with emission at about 1.3 eV can yield a solar energy conversion efficiency of about 46 percent (for one photon to one photon mechanism). Multiple photon generation can yield higher solar energy conversion efficiencies, and, in general, can involve a conversion of nᵢ photons to nⱼ photons, where nᵢ and nⱼ are integers, and nⱼ>nᵢ. Multiple photon generation materials can be included in the solar modules described herein, and the use of resonant cavity effects can enhance emission and efficiency of multiple photon generation processes. Silicon nanoparticles, such as silicon quantum dots, that emit multiple photons can be used in spectral concentrators described herein to provide higher conversion efficiencies. Certain aspects of silicon nanoparticles are described in Beard et al., “Multiple Exciton Generation in Colloidal Silicon Nanocrystals,” Nano Letters, Vol. 7, No. 8, pp. 2506-2512 (2007), the disclosure of which is incorporated herein by reference in its entirety.

Also, a quantum cutting material can exhibit down-conversion by absorbing one shorter wavelength photon and emitting two or more longer wavelength photons, while a down-shifting material can exhibit down-conversion by absorbing one shorter wavelength photon and emitting one longer wavelength photon. Quantum cutting, in general, can involve a conversion of nᵢ photons to nⱼ photons, where nᵢ and nⱼ are integers, and nⱼ>nᵢ. Quantum cutting materials and down-shifting materials can be included in the solar modules described herein, such as in the form of oxides or chalcogenides with luminescence derived from a set of rare earth atoms or transition metal atoms via doping or co-doping, and the use of resonant cavity effects can enhance emission and efficiency of quantum cutting and down-shifting processes. For example, certain transition metals, such as chromium (e.g., as Cr(III)), titanium (e.g., as Ti(II)), copper (e.g., as Cu(I) or Cu(II)), and iron (e.g., as Fe(III)), can be used for down-shifting, and certain lanthanides, such as terbium and ytterbium, can be used for quantum cutting when incorporated within a suitable matrix or as a component film. Ytterbium can also be incorporated within CsSnCl₃, or another suitable material, and undergo quantum cutting by energy transfer from CsSnCl₃ to ytterbium with emission at about 980 nm. A similar energy transfer to ytterbium can occur when both terbium and ytterbium are doped into UD930. Other examples of desirable materials include zinc oxide (i.e., ZnO) doped with aluminum having a suitable oxidation state, zinc sulfide (i.e., ZnS) doped with manganese or magnesium having a suitable oxidation state, aluminum oxide or alumina (i.e., Al₂0₃) doped with erbium, chromium, or titanium having a suitable oxidation state, zirconium oxide (i.e., ZrO₂) doped with yttrium having a suitable oxidation state, strontium sulfide (i.e., SrS) doped with cerium having a suitable oxidation state, titanium oxide (i.e., TiO₂) doped with a suitable rare earth atom, and silicon dioxide (i.e., SiO₂) doped with a suitable rare earth atom.

Since about one half of incident solar radiation is at lower energy, or longer wavelength, than 1.3 eV (or 950 nm), conversion efficiency can be increased by up-conversion. Up-conversion can involve a process where two photons are absorbed and one photon is emitted at a higher energy. Rare earth atoms can be relatively efficient at undergoing up-conversion, and other processes, such as Second Harmonic Generation (“SHG”) at relatively high intensities, can be used to enhance solar energy conversion efficiencies. Up-conversion materials can be included in the solar modules described herein, such in the form of oxides or chalcoginides with luminescence derived from a set of rare earth atoms via doping or co-doping. The use of resonant cavity effects can enhance emission and efficiency of up-conversion and non-linear processes such as SHG. Certain aspects of up-conversion are described in Sark et al., “Enhancing Solar Cell Efficiency by Using Spectral Converters,” Solar Energy Materials & Solar Cells, Vol. 87, pp. 395-409 (2005); and Shalav et al., “Luminescent Layers for Enhanced Silicon Solar Cell Performance: Up-conversion,” Solar Energy Materials & Solar Cells, Vol. 91, pp. 829-842 (2007), the disclosures of which are incorporated herein by reference in their entireties.

### Solar Modules

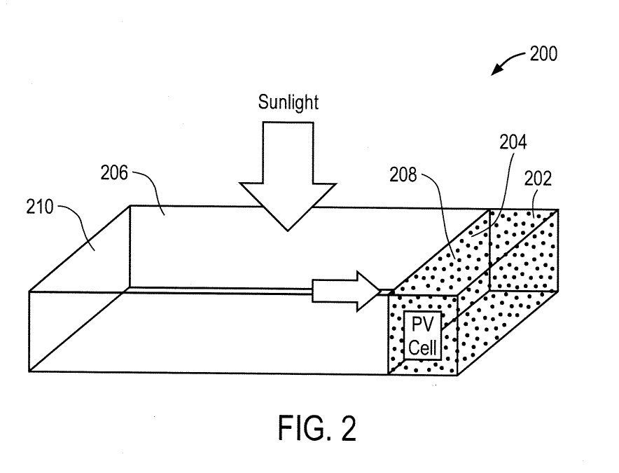

FIG. 2 illustrates a solar module 200 implemented in accordance with an embodiment of the invention. The solar module 200 includes a PV cell 202, which is a p-n junction device formed from crystalline silicon. However, the PV cell 202 can also be formed from another suitable photoactive material. As illustrated in FIG. 2, the PV cell 202 is implemented as a thin slice or strip of crystalline silicon. The use of thin slices of silicon allows a reduction in silicon consumption, which, in turn, allows a reduction in manufacturing costs. Micromachining operations can be performed on a silicon wafer to form numerous silicon slices, and each of the silicon slices can be further processed to form PV cells, such as the PV cell 202. The PV cell 202 can have dimensions of about 300 μm by about 300 μm by a few centimeters in length, or dimensions of about 250 μm by about 250 μm by about 3 inches in length. As illustrated in FIG. 2, the PV cell 202 is configured to accept and absorb radiation incident upon a side surface 204 of the PV cell 202, although other surfaces of the PV cell 202 can also be involved.

In the illustrated embodiment, the solar module 200 also includes a spectral concentrator 206, which is formed as a slab having a side surface 208 that is adjacent to the side surface 204 of the PV cell 202. The spectral concentrator 206 includes a set of luminescent materials that convert a relatively wide range of energies of solar radiation into a set of relatively narrow, substantially monochromatic energy bands that are matched to an absorption spectrum of the PV cell 202. During operation of the solar module 200, incident solar radiation strikes a top surface 210 of the spectral concentrator 206, and a certain fraction of this incident solar radiation penetrates below the top surface 210 and is absorbed and converted into substantially monochromatic, emitted radiation. This emitted radiation is guided laterally within the spectral concentrator 206, and a certain fraction of this emitted radiation reaches the side surface 204 of the PV cell 202, which absorbs and converts this emitted radiation into electricity.

In effect, the spectral concentrator 206 performs a set of operations, including: (1) collecting incident solar radiation; (2) converting the incident solar radiation into substantially monochromatic, emitted radiation near a bandgap energy of the PV cell 202; and (3) conveying the emitted radiation to the PV cell 202, where the emitted radiation can be converted to useful electrical energy. The spectral concentrator 206 can include distinct structures that are optimized or otherwise tailored towards respective ones of the collection, conversion, and conveyance operations. Alternatively, certain of these operations can be implemented within a common structure. These operations that are performed by the spectral concentrator 206 are further described below.

Collection refers to capturing or intercepting incident solar radiation in preparation for conversion to emitted radiation. Collection efficiency of the spectral concentrator 206 can depend upon the amount and distribution of a luminescent material within the spectral concentrator 206. In some instances, the luminescent material can be viewed as a set of luminescent centers that can intercept incident solar radiation, and a greater number of luminescent centers typically increases the collection efficiency. Depending upon the distribution of the luminescent centers, collection of incident solar radiation can occur in a distributed fashion throughout the spectral concentrator 206, or can occur within one or more regions of the spectral concentrator 206. The collection efficiency can also depend upon other aspects of the spectral concentrator 206, including the ability of incident solar radiation to reach the luminescent material. In particular, the collection efficiency is typically improved by suitable optical coupling of incident solar radiation to the luminescent material, such as via an anti-reflection coating to reduce reflection of incident solar radiation.

Conversion refers to emitting radiation in response to incident solar radiation, and the efficiency of such conversion refers to the probability that an absorbed solar photon is converted into an emitted photon. Conversion efficiency of the spectral concentrator 206 can depend upon photoluminescence characteristics of a luminescent material, including its internal quantum efficiency, but can also depend upon interaction of luminescent centers with their local optical environment, including via resonant cavity effects. Depending upon the distribution of the luminescent centers, conversion of incident solar radiation can occur in a distributed fashion throughout the spectral concentrator 206, or can occur within one or more regions of the spectral concentrator 206. Also, depending upon the particular luminescent material used, the conversion efficiency can depend upon wavelengths of incident solar radiation that are absorbed by the luminescent material.

Conveyance refers to guiding or propagation of emitted radiation towards the PV cell 202, and the efficiency of such conveyance refers to the probability that an emitted photon reaches the PV cell 202. Conveyance efficiency of the spectral concentrator 206 can depend upon photoluminescence characteristics of a luminescent material, including a degree of overlap between emission and absorption spectra, but can also depend upon interaction of luminescent centers with their local optical environment, including via resonant cavity effects.

By performing these operations, the spectral concentrator 206 provides a number of benefits. In particular, by performing the collection operation in place of the PV cell 202, the spectral concentrator 206 allows a significant reduction in silicon consumption, which, in turn, allows a significant reduction in manufacturing costs. In some instances, the amount of silicon consumption can be reduced by a factor of about 10 to about 1,000. Also, the spectral concentrator 206 enhances solar energy conversion efficiency based on at least two effects: (1) concentration effect; and (2) monochromatic effect.

In terms of the concentration effect, the spectral concentrator 206 performs spectral concentration by converting a relatively wide range of energies of incident solar radiation into a set of narrow bands of energies close to the bandgap energy of the PV cell 202. Incident solar radiation is collected via the top surface 210 of the spectral concentrator 206, and emitted radiation is guided towards the side surface 204 of the PV cell 202. A solar radiation collection area, as represented by, for example, an area of the top surface 210 of the spectral concentrator 206, can be significantly greater than an area of the PV cell 202, as represented by, for example, an area of the side surface 204 of the PV cell 202. A resulting concentration factor onto the PV cell 202 can be in the range of about 10 to about 100 and up to about 1,000 or more. For example, the concentration factor can exceed about 10,000 and can be up to about 60,000 or more. In turn, the concentration factor can increase the open circuit voltage or V_{oc} of the solar module 200, and can yield an increase in solar energy conversion efficiency of about 2 percent (absolute), or 10 percent (relative), for each concentration factor of 10 in emitted radiation reaching the PV cell 202. For example, V_{oc} can be increased from a typical value of about 0.55 V, which is about half the bandgap energy of silicon, to about 1.6 V, which is about 1.5 times the bandgap energy of silicon. A typical solar radiation energy flux or intensity is about 100 mW cm⁻², and, in some instances, a concentration factor of up to 10⁶ (or more) can be achieved by optimizing the spectral concentrator 206 with respect to the collection, conversion, and conveyance operations.

In terms of the monochromatic effect, a narrow band radiation emitted from the spectral concentrator 206 can be efficiently absorbed by the PV cell 202, which can be optimized in terms of its junction design to operate on this narrow band, emitted radiation. In addition, by matching the energy of the emitted radiation with the bandgap energy of the PV cell 202, thermalization can mostly occur within the spectral concentrator 206, rather than within the PV cell 202.

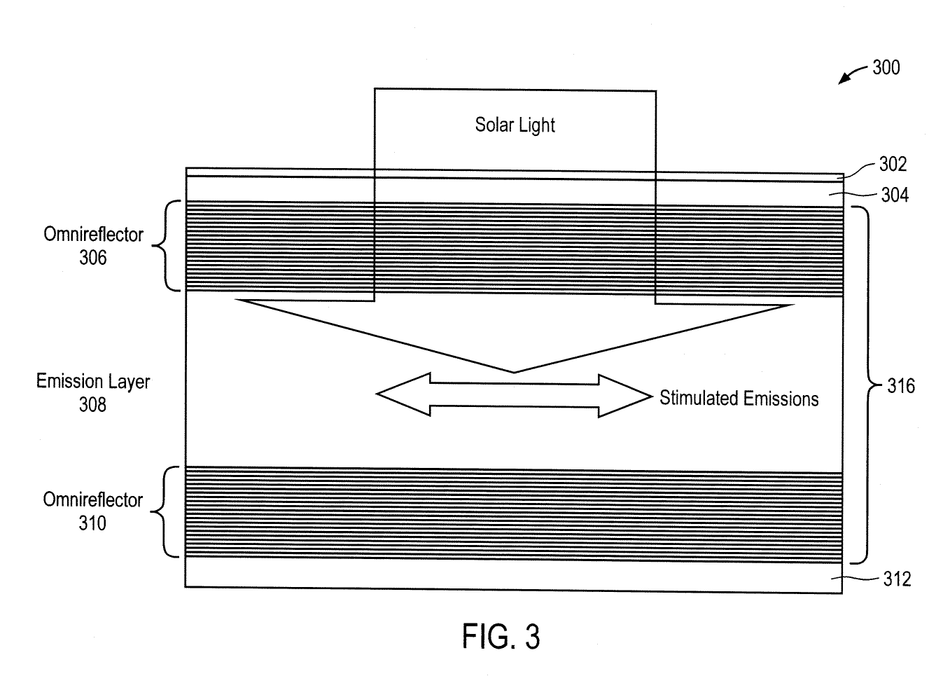

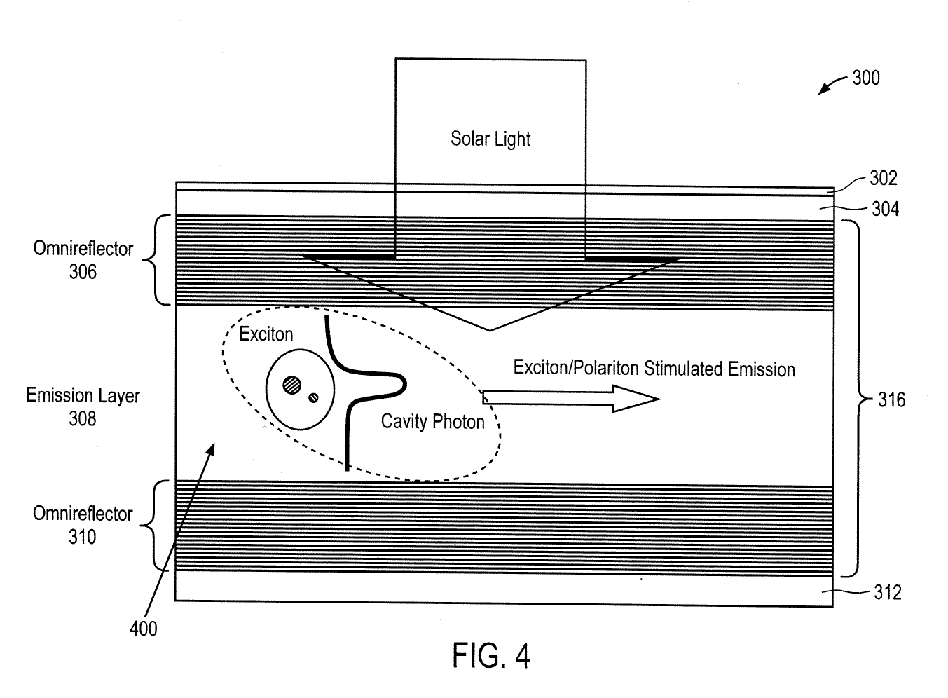

FIG. 3 and FIG. 4 illustrate a spectral concentrator 300 implemented in accordance with an embodiment of the invention. The spectral concentrator 300 includes multiple structures that allow the spectral concentrator 300 to perform collection, conversion, and conveyance operations. In particular, the spectral concentrator 300 includes a top substrate layer 304, which faces incident solar radiation and is formed from a glass, a polymer, or another suitable material that is optically transparent or translucent. An anti-reflection layer 302 is formed adjacent to a top surface of the top substrate layer 304 to reduce reflection of incident solar radiation. As illustrated in FIG. 3, the spectral concentrator 300 also includes a luminescent stack 316, which converts a relatively wide range of energies of incident solar radiation into emitted radiation having a relatively narrow, substantially monochromatic energy band. The luminescent stack 316 is sandwiched by the top substrate layer 304 and a bottom substrate layer 312, which are adjacent to a top surface and a bottom surface of the luminescent stack 316, respectively. The bottom substrate layer 312 serves to protect the luminescent stack 316 from environmental conditions, and is formed from a glass, a metal, a ceramic, a polymer, or another suitable material. While not illustrated in FIG. 3, side edges and surfaces of the spectral concentrator 300, which are not involved in conveyance of radiation, can have a Lambertian or other reflector formed thereon, such as white paint or another suitable reflective material. Also, it is contemplated that either, or both, of the top substrate layer 304 and the bottom substrate layer 312 can be optionally omitted for certain implementations.

As illustrated in FIG. 3, the luminescent stack 316 includes an emission layer 308, which includes a set of luminescent materials that absorb solar radiation and emit radiation in a substantially monochromatic energy band. In particular, the emission layer 308 is configured to perform down-conversion to match the bandgap energy of silicon, or another photoactive material forming a PV cell (not illustrated). Solar radiation with higher energies is absorbed and converted into emitted radiation with lower energies that match the bandgap energy of the PV cell. In this manner, thermalization can mostly occur within the luminescent stack 316, rather than within the PV cell. It is also contemplated that the emission layer 308 can be configured to perform up-conversion, such that solar radiation with lower energies is absorbed and converted into emitted radiation with higher energies that match the bandgap energy of the PV cell. Emitted radiation is guided within the emission layer 308 and is directed towards the PV cell, which absorbs and converts this emitted radiation into electricity. By selecting a set of luminescent materials having a high absorption coefficient for solar radiation, a thickness of the emission layer 308 can be reduced, such as in the range of about 0.01 μm to about 2 μm, in the range of about 0.05 μm to about 1 μm, in the range of about 0.1 μm to about 1 μm, or in the range of about 0.1 μm to about 0.5 μm.

Referring to FIG. 3, the emission layer 308 is sandwiched by a top reflector 306 and a bottom reflector 310, which are adjacent to a top surface and a bottom surface of the emission layer 308, respectively. This pair of reflectors 306 and 310 serve to reduce loss of emitted radiation out of the luminescent stack 316 as the emitted radiation is guided towards the PV cell. The top reflector 306 is omnireflective over emission wavelengths of the emission layer 308, while allowing relevant wavelengths of incident solar radiation to pass through and strike the emission layer 308. Similarly, the bottom reflector 310 is omnireflective over emission wavelengths, thereby reducing loss of emitted radiation through the bottom substrate layer 312. Stated in another way, each of the top reflector 306 and the bottom reflector 310 has narrowband reflectivity with respect to emission wavelengths.

In the illustrated embodiment, each of the top reflector 306 and the bottom reflector 310 is implemented as a dielectric stack, including multiple dielectric layers and with the number of dielectric layers in the range of 2 to 1,000, such as in the range of 2 to 100, in the range of 30 to 90, or in the range of 30 to 80. Each dielectric layer can have a thickness in the range of about 0.001 μm to about 0.2 μm, such as in the range of about 0.01 μm to about 0.15 μm or in the range of about 0.01 μm to about 0.1 μm. Depending on the number of dielectric layers forming the top reflector 306 and the bottom reflector 310, a thickness of each of the top reflector 306 and the bottom reflector 310 can be in the range of about 0.1 μm to about 20 μm, such as in the range of about 1 μm to about 15 μm or in the range of about 1 μm to about 10 μm. For certain implementations, a dielectric stack can include multiple layers formed from different dielectric materials. Layers formed from different materials can be arranged in a periodic fashion, such as in an alternating fashion, or in a non-periodic fashion. Examples of dielectric materials that can be used to form the top reflector 306 and the bottom reflector 310 include oxides, such as silica (i.e., SiO₂ or α-SiO₂), alumina (i.e., Al₂O₃), TiO₂, Ta₂O₅, Nb₂O₅, ZrO₂, HfO₂, SnO₂, ZnO₂, La₂O₃, Y₂O₃, CeO₂, Sc₂O₃, Er₂O₃, V₂O₅, and In₂O₃; nitrides, such as SiOₓN₂₋ₓ; fluorides, such as CaF₂, SrF₂, ZnF₂, MgF₂, LaF₃, and GdF₂; nanolaminates, such as HfO₂/Ta₂O₅, TiO₂/Ta₂O₅, TiO₂/Al₂O₃, ZnS/Al₂O₃, and AlTiO; and other suitable thin-film dielectric materials. Desirably, different materials forming a dielectric stack have different refractive indices so as to form a set of high index layers and a set of low index layers that are interspersed within the dielectric stack. For certain implementations, an index contrast in the range of about 0.3 to about 1 or in the range of about 0.3 to about 2 can be desirable. For example, TiO₂ and SiO₂ can be included in alternating layers of a dielectric stack to provide a relatively large index contrast between the layers. A larger index contrast can yield a larger stop band with respect to emitted radiation, thereby approaching the performance of an ideal omnireflector. In addition, a larger index contrast can yield a greater angular tolerance for reflectivity with respect to incident solar radiation, and can reduce a leakage of emitted radiation at larger angles from a normal direction. Either, or both, of the top reflector 306 and the bottom reflector 310 can be designed for relatively athermal behavior and can be matched to the emission layer 308 in terms of index changes with temperature and in terms of coefficient of thermal expansion.

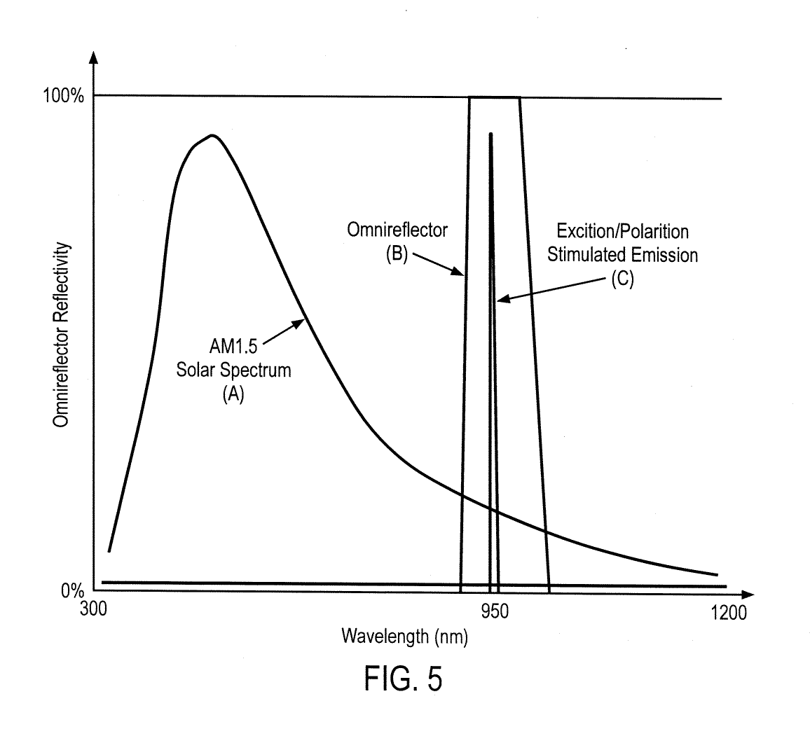

Desirable characteristics of the top reflector 306 and the bottom reflector 310 can be further appreciated with reference to FIG. 5, which illustrates a combined representation of a solar spectrum, an emission spectrum of the emission layer 308, and a reflectivity spectrum of either, or both, of the top reflector 306 and the bottom reflector 310. In particular, FIG. 5 illustrates the AM1.5 solar spectrum (referenced as (A)), which is another standard solar spectrum representing incident solar radiation on the surface of the earth. In view of the AM1.5 solar spectrum and the emission spectrum (referenced as (C)), the reflectivity spectrum (referenced as (B)) is particularly effective for spectral concentration when implemented within either, or both, of the top reflector 306 and the bottom reflector 310. In particular, the reflectivity spectrum has a narrow stop band of relatively low transmittance (or relatively high reflectivity) centered around the peak emission wavelength (about 950 nm in the illustrated embodiment), and a wide transmission band of relatively high transmittance (or relatively low reflectivity) outside of the stop band, with a steep and distinct transition from the stop band to the transmission band. By selecting suitable materials and processing conditions, characteristics of the stop band, the transmission band, and the transition between the stop band and the transmission band can be optimized or otherwise tuned for various implementations. For certain implementations, the stop band has a reflectivity that is at least about 90 percent, such as at least about 97 percent, at least about 98 percent, or at least about 99 percent, and up to about 99.5 percent or 100 percent, with a spectral width or a bandwidth in the range of about 10 nm to about 100 nm at FWHM, such as in the range of about 30 nm to about 100 nm, in the range of about 30 nm to about 50 nm, or in the range of about 50 nm to about 100 nm. Within this bandwidth, the reflectivity can substantially lack angular dependence, and can apply for a wide range of angles relative to a normal direction, such as ±89°, ±70°, ±45°, ±30°, ±20°, or ±10°. Also, the transmission band has a reflectivity that is no greater than about 40 percent, such as no greater than about 30 percent, no greater than about 20 percent, or no greater than about 10 percent, and down to about 5 percent or 1 percent, over a wide range of wavelengths encompassing the visible range and up to the transition between the stop band and the transmission band. Within this range of wavelengths, the reflectivity can substantially lack angular dependence, and can apply for a wide range of angles relative to the normal direction. By implementing in such manner, the top reflector 306 and the bottom reflector 310 can be tuned to reflect emitted radiation back towards the emission layer 308, without significant reduction of incident solar radiation that can pass through the top reflector 306 and reach the emission layer 308.

Referring back to FIG. 3 and FIG. 4, aspects of Cavity Quantum Electrodynamics can be used to implement the luminescent stack 316 as a micro-cavity or a resonant cavity waveguide. The resulting resonant cavity effects can provide a number of benefits. For example, resonant cavity effects can be exploited to control a direction of emitted radiation towards a PV cell and, therefore, enhance the fraction of emitted radiation reaching the PV cell. This directional control can involve suppressing emission for optical modes in non-guided directions, while allowing or enhancing emission for optical modes in guided directions towards the PV cell. In such manner, there can be a significant reduction in loss of emitted radiation via a loss cone. Also, resonant cavity effects can be exploited to modify emission characteristics, such as by enhancing emission of a set of wavelengths that are associated with certain optical modes and suppressing emission of another set of wavelengths that are associated with other optical modes. This modification of emission characteristics can reduce an overlap between an emission spectrum and an absorption spectrum via spectral pulling, and can reduce losses arising from self-absorption. This modification of emission characteristics can also yield a larger exciton binding energy, and can promote luminescence via exciton emission. In addition, resonant cavity effects can enhance absorption and emission characteristics of a set of luminescent materials, and can allow the use of semiconductor materials having indirect optical transitions or forbidden optical transitions. This enhancement of absorption and emission characteristics can involve optical gain as well as amplified spontaneous emission, such as via the Purcell effect. In some instances, the high intensity of emitted radiation within the luminescent stack 316 can lead to stimulated emission and lasing, which can further reduce losses as emitted radiation is guided towards the PV cell.

In the illustrated embodiment, a local density of optical states within the emission layer 308 can include both guided optical modes and radiative optical modes. Guided optical modes can involve propagation of emitted radiation along the emission layer 308, while radiative optical modes can involve propagation of emitted radiation out of the emission layer 308. For a relatively low degree of vertical confinement, the local density of optical states and emission characteristics are modified to a relatively low degree. Increasing vertical confinement, such as by increasing an index contrast between dielectric layers of the top reflector 306 and the bottom reflector 310, can introduce greater distortions in the local density of optical states, yielding modification of emission characteristics including directional control. Also, by adjusting a thickness of the emission layer 308 with respect to vertical resonance, radiative optical modes can be suppressed. This suppression can reduce emission losses out of the emission layer 308, while enhancing probability of lateral emission along the emission layer 308 in a direction towards a PV cell. For certain implementations, the emission layer 308 can be disposed between the pair of reflectors 306 and 310 so as to be substantially centered at an anti-node position of a resonant electromagnetic wave, and the pair of reflectors 306 and 310 can be spaced to yield a cavity length in the range of a fraction of a wavelength to about ten wavelengths or more. Lateral confinement can also be achieved by, for example, forming reflectors adjacent to side edges and surfaces of the spectral concentrator 300, which are not involved in conveyance of radiation.

When implemented as a resonant cavity waveguide, a performance of the luminescent stack 316 can be characterized with reference to its quality or Q value, which can vary from low to high. A relatively low Q value can be sufficient to yield improvements in efficiency, with a greater Q value yielding additional improvements in efficiency. For certain implementations, the luminescent stack 316 can have a Q value that is at least about 5, such as at least about 10 or at least about 100, and up to about 10⁵ or more, such as up to about 10,000 or up to about 1,000. In the case of a high-Q resonant cavity waveguide, the luminescent stack 316 can exhibit an exciton emission in which excitons interact with cavity photons to form coupled exciton-photon quasi-particles referred as exciton-polaritons 400, as illustrated in FIG. 4. The luminescent stack 316 can operate in a weak coupling regime or a strong coupling regime, depending upon an extent of coupling between excitons and cavity photons or among excitons in the case of bi-excitons.

In the strong coupling regime, the luminescent stack 316 can be implemented as a polariton laser, which can lead to highly efficient and intense emissions and extremely low lasing thresholds. A polariton laser can have substantially zero losses and an efficiency up to about 100 percent. A polariton laser is also sometimes referred as a zero threshold laser, in which there is little or no lasing threshold, and lasing derives at least partly from excitons or related quasi-particles, such as bi-excitons or exciton-polaritons. The formation of quasi-particles and a resulting modification of energy levels or states can reduce losses arising from self-absorption. Contrary to conventional lasers, a polariton laser can emit coherent and substantially monochromatic radiation without population inversion. Without wishing to be bound by a particular theory, emission characteristics of a polariton laser can occur when exciton-polaritons undergo Bose-condensation within a resonant cavity waveguide. Lasing can also occur in the weak coupling regime, although a lasing threshold can be higher than for the strong coupling regime. In the weak coupling regime, lasing can derive primarily from excitons, rather than from exciton-polaritons.

By implementing as a high-Q resonant cavity waveguide in the form of a polariton laser, the luminescent stack 316 can exhibit a number of desirable characteristics. In particular, lasing can be achieved with a very low threshold, such as with an excitation intensity that is no greater than about 200 mW cm⁻², no greater than about 100 mW cm⁻², no greater than about 50 mW cm⁻², or no greater than about 10 mW cm⁻², and down to about 1 mW cm⁻² or less, which is several orders of magnitude smaller than for a conventional laser. Because a typical solar radiation intensity is about 100 mW cm⁻², lasing can be achieved with normal sunlight with little or no concentration. Also, lasing can occur with a short radiative lifetime, such as no greater than about 500 psec, no greater than about 200 psec, no greater than about 100 psec, or no greater than about 50 psec, and down to about 1 psec or less, which can avoid or reduce relaxation through non-radiative mechanisms. Furthermore, lasing can involve narrowing of a spectral width of an emission spectrum to form a narrow emission line, such as by a factor of at least about 1.5, at least about 2, or at least about 5, and up to about 10 or more, relative to the case where there is a substantial absence of resonant cavity effects. For example, in the case of UD930, a spectral width can be narrowed from a typical value of about 80 nm at FWHM to a value in the range of about 2 nm to about 10 nm, such as from about 3 nm to about 10 nm, when UD930 is incorporated in a high-Q resonant cavity waveguide. A narrow emission line from lasing can enhance solar conversion efficiencies, as a result of the monochromatic effect.

In such manner, lasing and low loss with distance can allow higher intensities of emissions reaching a PV cell and higher solar conversion efficiencies. There can be little or no measurable loss of emissions that are guided towards the PV cell. With lasing, a photon quantum efficiency from solar radiation to emitted radiation can approach 100 percent, and a solar energy conversion efficiency can be up to about 30 percent or more, such as in the range of about 20 percent to about 30 percent or in the range of about 28 percent to about 30 percent.

During manufacturing, Atomic Layer Deposition (“ALD”) can be used to form various layers of the spectral concentrator 300 in a single deposition run to form a substantially monolithic, integrated cavity waveguide, and processing conditions can be optimized with respect to characteristics of those layers. ALD typically uses a set of reactants to form alternate, saturated, chemical reactions on a surface, resulting in self-limited growth with desirable characteristics such as conformity, high throughput, uniformity, repeatability, and precise control over thickness. For certain implementations, reactants are sequentially introduced to a surface in a gas phase to form successive monolayers. ALD can be used to incorporate a set of dopants in a controlled fashion so as to tune refractive indices or to introduce or modify photoluminescence characteristics for down-conversion or up-conversion. ALD can also be used to apply a set of reflective materials on side edges and surfaces of the spectral concentrator 300, which are not involved in conveyance of radiation. Also, ALD can be used to apply an optical coupling material adjacent to an interface between the spectral concentrator 300 and a PV cell, such as in the form of a dielectric stack. The optical coupling material can be applied to a coupling surface of the spectral concentrator 300, a coupling surface of the PV cell, or to both surfaces. Certain aspects of ALD are described in Nanu et al., “CuInS₂—TiO₂ Heterojunctions Solar Cells Obtained by Atomic Layer Deposition,” Thin Solid Films, Vol. 431-432, pp. 492-496 (2003); Spiering et al., “Stability Behaviour of Cd-free Cu(In,Ga)Se₂ Solar Modules with In₂S₃ Buffer Layer Prepared by Atomic Layer Deposition,” Thin Solid Films, Vol. 480-481, pp. 195-198 (2005); and Klepper et al., “Growth of Thin Films of Co₃O₄ by Atomic Layer Deposition,” Thin Solid Films, Vol. 515, No. 20-21, pp. 7772-7781 (2007); the disclosures of which are incorporated herein by reference in their entireties. It is contemplated that another suitable deposition technique can be used in place of, or in combination with, ALD to form a substantially monolithic, integrated cavity waveguide. Examples of suitable deposition techniques include vacuum deposition (e.g., thermal evaporation or electron-beam evaporation), Physical Vapor Deposition (“PVD”), Chemical Vapor Deposition (“CVD”), plating, spray coating, dip coating, web coating, wet coating, and spin coating.

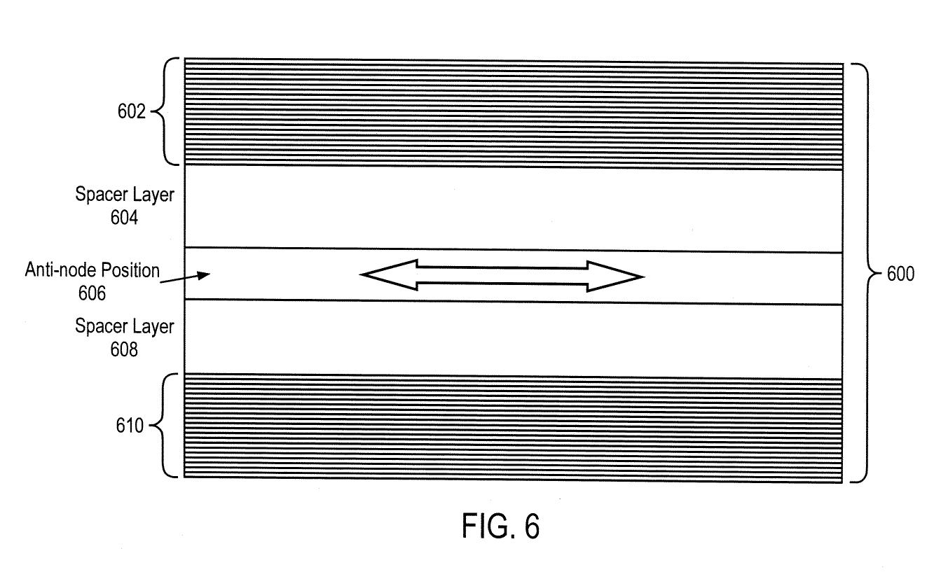

FIG. 6 illustrates a luminescent stack 600 implemented as a resonant cavity waveguide in accordance with another embodiment of the invention. The luminescent stack 600 includes a top reflector 602 and a bottom reflector 610, which are implemented as dielectric stacks including multiple dielectric layers. The pair of reflectors 602 and 610 sandwich an emission layer 606, such that the top reflector 602 is adjacent to a top surface of the emission layer 606, and the bottom reflector 610 is adjacent to a bottom surface of the emission layer 606. The emission layer 606 is disposed between the pair of reflectors 602 and 610 so as to be substantially centered at an anti-node position of a resonant electromagnetic wave. While the single emission layer 606 is illustrated in FIG. 6, it is contemplated that additional emission layers can be included for other implementations. Certain aspects of the luminescent stack 600 can be implemented in a similar manner as described above, and, therefore, are not further described herein.

As illustrated in FIG. 6, a top spacer layer 604 is included between the top reflector 602 and the emission layer 606, and a bottom spacer layer 608 is included between the emission layer 606 and the bottom reflector 610. The pair of spacer layers 604 and 608 provide index matching and serve as a pair of passive in-plane waveguide layers for low loss guiding of emitted radiation within the emission layer 606. The top spacer layer 604 can be foimed from a suitable low index material, such as MgF₂ having a refractive index of about 1.37 or another material having a refractive index that is no greater than about 2 or no greater than about 1.5, or a suitable high index material, such as TiO₂ having a refractive index of about 2.5 or another material having a refractive index greater than about 2.5 or greater than about 3. Similarly, the bottom spacer layer 608 can be formed from a suitable low index material or a suitable high index material. For certain implementations, the top spacer layer 604 and the bottom spacer layer 608 can be formed from similar dielectric materials used to form the top reflector 602 and the bottom reflector 610, such as oxides, nitrides, fluorides, or nanolaminates. ALD can be used to form the top spacer layer 604 and the bottom spacer layer 608, along with the other layers of the luminescent stack 600, in a single deposition run. Alternatively, another suitable deposition technique can be used, such as vacuum deposition, PVD, CVD, plating, spray coating, dip coating, web coating, wet coating, or spin coating. Each of the top spacer layer 604 and the bottom spacer layer 608 can have a thickness in the range of about 1 nm to about 200 nm, such as in the range of about 1 nm to about 100 nm or in the range of about 10 nm to about 100 nm. While two spacer layers 604 and 608 are illustrated in FIG. 6, it is contemplated that more or less spacer layers can be included for other implementations.

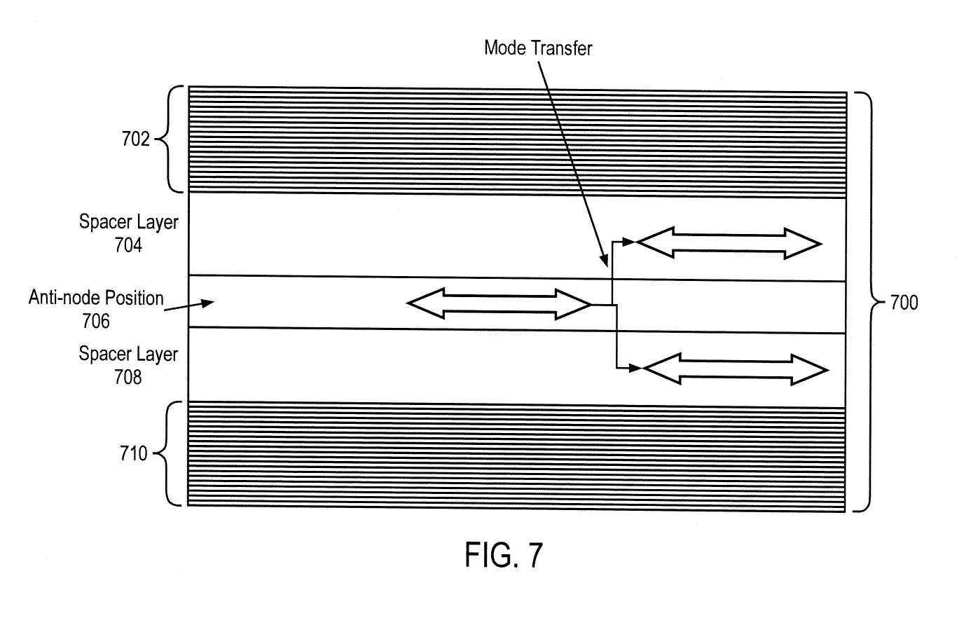

FIG. 7 illustrates a luminescent stack 700 implemented as a resonant cavity waveguide in accordance with another embodiment of the invention. The luminescent stack 700 includes a top reflector 702 and a bottom reflector 710, which are implemented as dielectric stacks including multiple dielectric layers. The pair of reflectors 702 and 710 sandwich an emission layer 706, which is disposed so as to be substantially centered at an anti-node position of a resonant electromagnetic wave. While the single emission layer 706 is illustrated in FIG. 7, it is contemplated that additional emission layers can be included for other implementations. Certain aspects of the luminescent stack 700 can be implemented in a similar manner as described above, and, therefore, are not further described herein.

As illustrated in FIG. 7, a top spacer layer 704 is included between the top reflector 702 and the emission layer 706, and a bottom spacer layer 708 is included between the emission layer 706 and the bottom reflector 710. In the illustrated embodiment, at least one of the pair of spacer layers 704 and 708 is directly involved in conveyance of emitted radiation via optical mode transfer from the emission layer 706. In such manner, propagation of emitted radiation can at least partly occur in the pair of spacer layers 704 and 708, and self-absorption or scattering losses can be reduced relative to the case where substantial propagation of emitted radiation occurs in the emission layer 706. For certain implementations, at least one of the top spacer layer 704 and the bottom spacer layer 708 can be formed from a suitable low index material, such that the luminescent stack 700 serves as an Antiresonant Reflecting Optical Waveguide (“ARROW”). An ARROW is typically based on the Fabry-Perot effect for guiding, rather than total internal reflection, and can provide enhanced photoluminescence and low loss guiding towards a PV cell (not illustrated). The ARROW can allow certain optical modes to be substantially centered on a low index region corresponding to either, or both, of the top spacer layer 704 and the bottom spacer layer 708. In such manner, substantial propagation of emitted radiation can occur outside of the emission layer 706, and self-absorption can be reduced. Certain aspects of ARROW structures are described in Huang et al., “The Modal Characteristics of ARROW structures,” Journal of Lightwave Technology, Vol. 10, No. 8, pp. 1015-1022 (1992); Litchinitser et al., “Application of an ARROW Model for Designing Tunable Photonic Devices,” Optics Express, Vol. 12, No. 8, pp. 1540-1550 (2004); and Liu et al., “Characteristic Equations for Different ARROW Structures,” Optical and Quantum Electronics, Vol. 31, pp. 1267-1276 (1999); the disclosures of which are incorporated herein by reference in their entireties. While two spacer layers 704 and 708 are illustrated in FIG. 7, it is contemplated that more or less spacer layers can be included for other implementations.

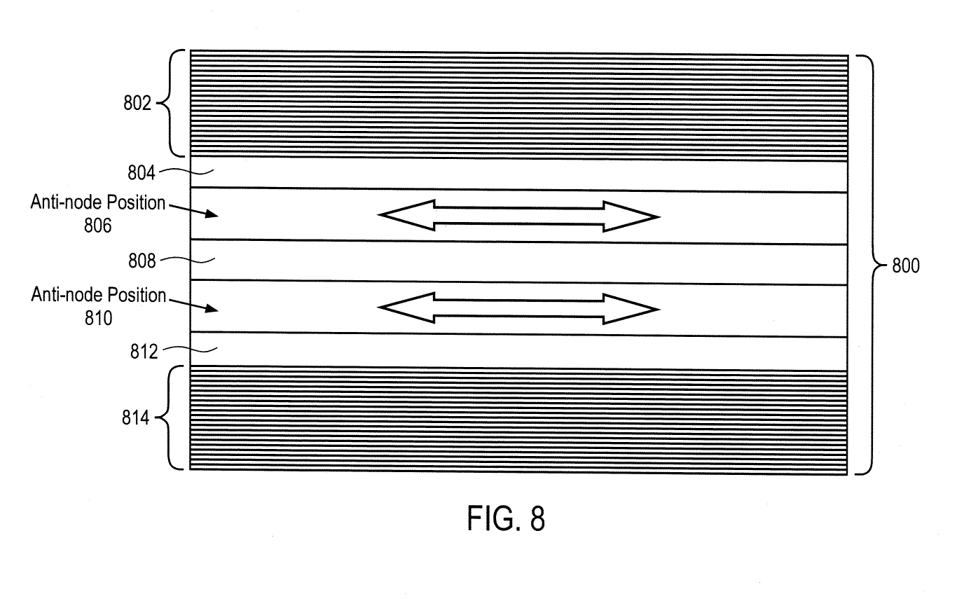

FIG. 8 illustrates a luminescent stack 800 implemented as a resonant cavity waveguide in accordance with another embodiment of the invention. The luminescent stack 800 includes a top reflector 802 and a bottom reflector 814, which are implemented as dielectric stacks including multiple dielectric layers. Certain aspects of the luminescent stack 800 can be implemented in a similar manner as described above, and, therefore, are not further described herein.

In the illustrated embodiment, the pair of reflectors 802 and 814 sandwich a pair of emission layers, namely a top emission layer 806 and a bottom emission layer 810, such that the top reflector 802 is adjacent to a top surface of the top emission layer 806, and the bottom reflector 814 is adjacent to a bottom surface of the bottom emission layer 810. The pair of emission layers 806 and 810 are disposed so as to be substantially centered at respective anti-node positions. While two emission layers 806 and 810 are illustrated in FIG. 8, it is contemplated that more or less emission layers can be included for other implementations. Each of the pair of emission layers 806 and 810 includes a set of luminescent materials that convert a relatively wide range of energies of solar radiation into a relatively narrow, substantially monochromatic energy band. The pair of emission layers 806 and 810 can be formed from the same set of luminescent materials or from different sets of luminescent materials.

For example, the top emission layer 806 can be formed from a luminescent material that performs down-conversion, while the bottom emission layer 810 can be formed from a luminescent material that performs up-conversion. During operation of the luminescent stack 800, incident solar radiation strikes the top emission layer 806, which absorbs a certain fraction of this solar radiation and emits radiation in a substantially monochromatic energy band. In particular, the top emission layer 806 is configured to perform down-conversion to match a bandgap energy of a PV cell (not illustrated). Solar radiation with higher energies is absorbed and converted into emitted radiation with lower energies that match the bandgap energy of the PV cell. Solar radiation with lower energies is not absorbed by the top emission layer 806 and passes through the top emission layer 806. The lower energy radiation strikes the bottom emission layer 810, which absorbs this solar radiation and emits radiation in a substantially monochromatic energy band. In particular, the bottom emission layer 810 is configured to perform up-conversion to match the bandgap energy of the PV cell. By operating in such manner, the luminescent stack 800 provides enhanced utilization of a solar spectrum by allowing different energy bands within the solar spectrum to be collected and converted into electricity.

Still referring to FIG. 8, a top spacer layer 804 is included between the top reflector 802 and the top emission layer 806, a middle spacer layer 808 is included between the top emission layer 806 and the bottom emission layer 810, and a bottom spacer layer 812 is included between the bottom emission layer 810 and the bottom reflector 814. In the illustrated embodiment, the spacer layers 804, 808, and 812 provide index matching and serve as passive in-plane waveguide layers for low loss guiding of emitted radiation within the top emission layer 806 and the bottom emission layer 810. It is also contemplated that at least one of the spacer layers 804, 808, and 812 can be directly involved in conveyance of emitted radiation via optical mode transfer. In such manner, propagation of emitted radiation can at least partly occur in the spacer layers 804, 808, and 812, thereby reducing self-absorption or scattering losses. While three spacer layers 804, 808, and 812 are illustrated in FIG. 8, it is contemplated that more or less spacer layers can be included for other implementations.

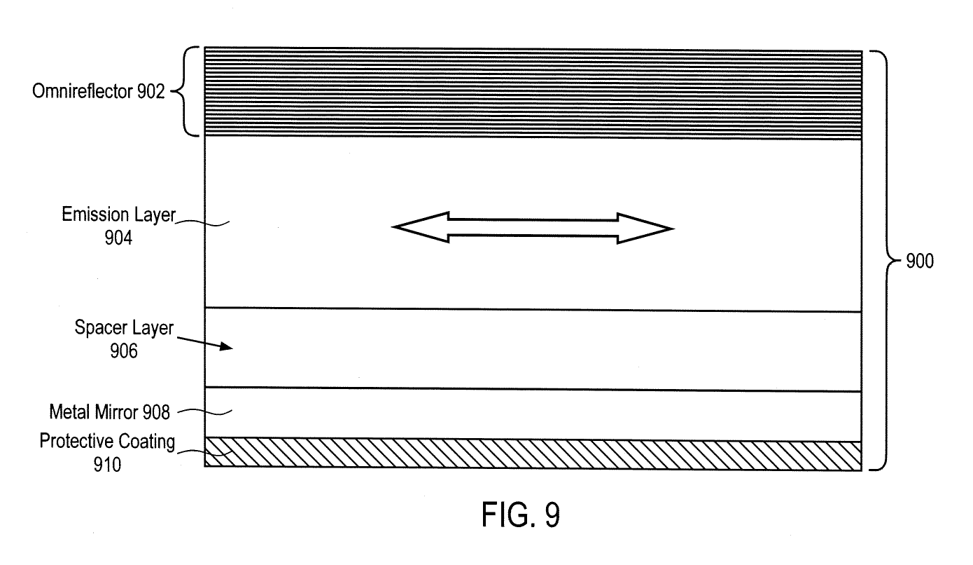

FIG. 9 illustrates a luminescent stack 900 implemented as a resonant cavity waveguide in accordance with another embodiment of the invention. The luminescent stack 900 includes a top reflector 902, which is implemented as a dielectric stack including multiple dielectric layers, and a bottom reflector 908. The pair of reflectors 902 and 908 sandwich an emission layer 904, which is disposed so as to be substantially centered at an anti-node position of a resonant electromagnetic wave. While the single emission layer 904 is illustrated in FIG. 9, it is contemplated that additional emission layers can be included for other implementations. Certain aspects of the luminescent stack 900 can be implemented in a similar manner as described above, and, therefore, are not further described herein.

In the illustrated embodiment, the bottom reflector 908 is omnireflective over a relatively wide range of wavelengths and, thus, allows for two-pass solar irradiation. In particular, any remaining fraction of incident solar radiation, which passes through the emission layer 904, strikes the bottom reflector 908, which reflects this solar radiation. Reflected radiation is directed upwards and strikes the emission layer 904, which can absorb and convert this reflected radiation into emitted radiation. In such manner, the bottom reflector 908 can enhance absorption of solar radiation as well as allow for reduction in a thickness of the emission layer 904, while maintaining a desirable level of absorption. Compared to the top reflector 902, which has narrowband reflectivity over emission wavelengths, the bottom reflector 908 can be relatively more lossy and less reflective with respect to emission wavelengths. However, broadband reflectivity of the bottom reflector 908 and efficiency gains provided by two-pass solar irradiation can provide an overall efficiency gain relative to an implementation using a pair of narrowband reflectors. The bottom reflector 908 can be formed from a metal, such as silver, aluminum, gold, copper, iron, cobalt, nickel, palladium, platinum, ruthenium, titanium, or iridium; a metal alloy; or another suitable material having broadband reflectivity, and can have a thickness in the range of about 1 nm to about 200 nm, such as in the range of about 1 nm to about 100 nm or in the range of about 10 nm to about 100 nm. As illustrated in FIG. 9, a protective layer 910 is formed as a coating adjacent to a bottom surface of the bottom reflector 908. The protective layer 910 serves to protect the bottom reflector 908 from environmental conditions. The protective layer 910 can be formed from a metal, a glass, a polymer, or another suitable material, and can have a thickness in the range of about 1 nm to about 500 nm, such as in the range of about 10 nm to about 300 nm or in the range of about 100 nm to about 300 nm. ALD can be used to form the bottom reflector 908 and the protective layer 910, along with the other layers of the luminescent stack 900, in a single deposition run. Alternatively, another suitable deposition technique can be used. It is contemplated that the protective layer 910 can be optionally omitted for another implementation.

Still referring to FIG. 9, a spacer layer 906 is included between the emission layer 904 and the bottom reflector 908. The spacer layer 906 provides index matching and serves as a passive in-plane waveguide layer for low loss guiding of emitted radiation. It is also contemplated that the spacer layer 906 can be directly involved in conveyance of emitted radiation via optical mode transfer. While the single spacer layer 906 is illustrated in FIG. 9, it is contemplated that more or less spacer layers can be included for other implementations.

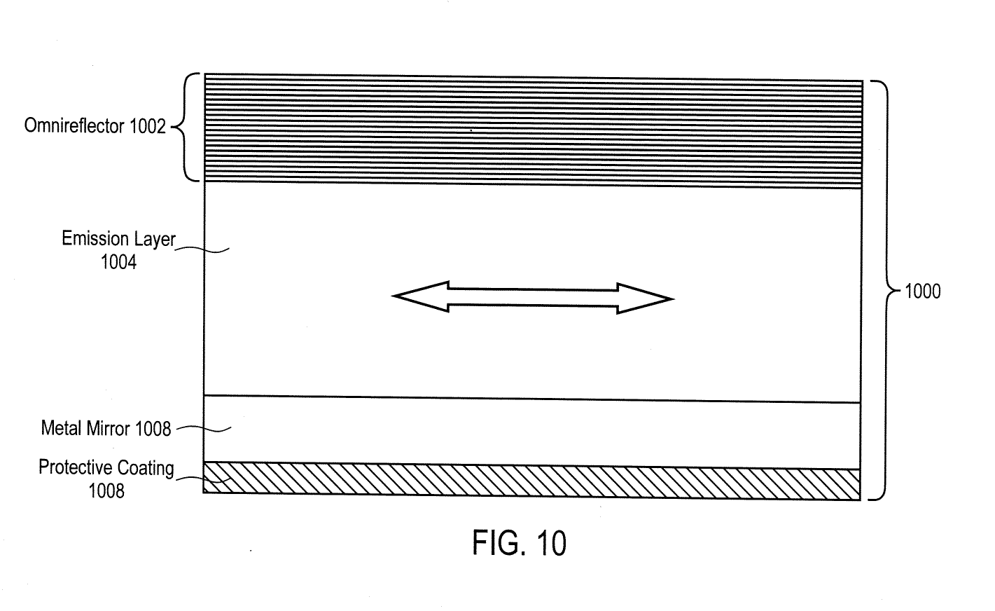

For example, FIG. 10 illustrates a luminescent stack 1000 implemented as a resonant cavity waveguide in accordance with another embodiment of the invention. The luminescent stack 1000 includes a top reflector 1002, which has narrowband reflectivity over emission wavelengths, and a bottom reflector 1006, which has broadband reflectivity. The pair of reflectors 1002 and 1006 sandwich an emission layer 1004, which is disposed so as to be substantially centered at an anti-node position of a resonant electromagnetic wave. While the single emission layer 1004 is illustrated in FIG. 10, it is contemplated that additional emission layers can be included for other implementations. In the illustrated embodiment, a spacer layer between the emission layer 1004 and the bottom reflector 1006 is optionally omitted. A protective layer 1008 is formed adjacent to a bottom surface of the bottom reflector 1006, and serves to protect the bottom reflector 1006 from environmental conditions. It is contemplated that the protective layer 1008 can be optionally omitted for another implementation. Certain aspects of the luminescent stack 1000 can be implemented in a similar manner as described above, and, therefore, are not further described herein.

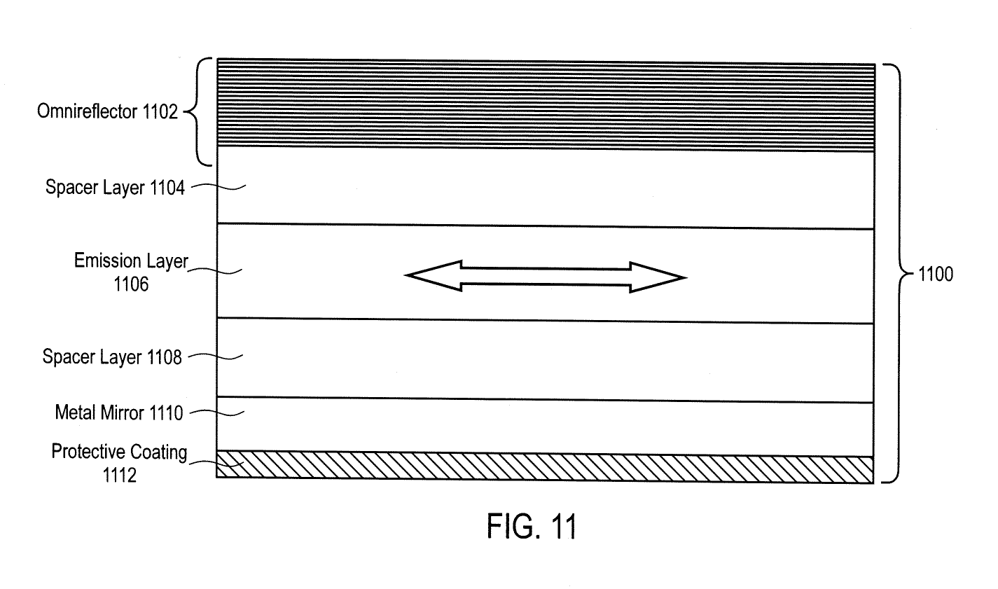

As another example, FIG. 11 illustrates a luminescent stack 1100 implemented as a resonant cavity waveguide in accordance with another embodiment of the invention. The luminescent stack 1100 includes a top reflector 1102, which has narrowband reflectivity over emission wavelengths, and a bottom reflector 1110, which has broadband reflectivity. The pair of reflectors 1102 and 1110 sandwich an emission layer 1106, which is disposed so as to be substantially centered at an anti-node position of a resonant electromagnetic wave. While the single emission layer 1106 is illustrated in FIG. 11, it is contemplated that additional emission layers can be included for other implementations. A protective layer 1112 is formed adjacent to a bottom surface of the bottom reflector 1110, and serves to protect the bottom reflector 1110 from environmental conditions. It is contemplated that the protective layer 1112 can be optionally omitted for another implementation. Certain aspects of the luminescent stack 1100 can be implemented in a similar manner as described above, and, therefore, are not further described herein.

In the illustrated embodiment, a top spacer layer 1104 is included between the top reflector 1102 and the emission layer 1106, and a bottom spacer layer 1108 is included between the emission layer 1106 and the bottom reflector 1110. The pair of spacer layers 1104 and 1108 provide index matching and serve as a pair of passive in-plane waveguide layers for low loss guiding of emitted radiation. It is also contemplated that at least one of the pair of spacer layers 1104 and 1108 can be directly involved in conveyance of emitted radiation via optical mode transfer. A symmetrical arrangement of the pair of spacer layers 1104 and 1108 with respect to the emission layer 1106, as illustrated in FIG. 11, can provide efficiency gains relative to an implementation having an unsymmetrical arrangement or lacking spacer layers.

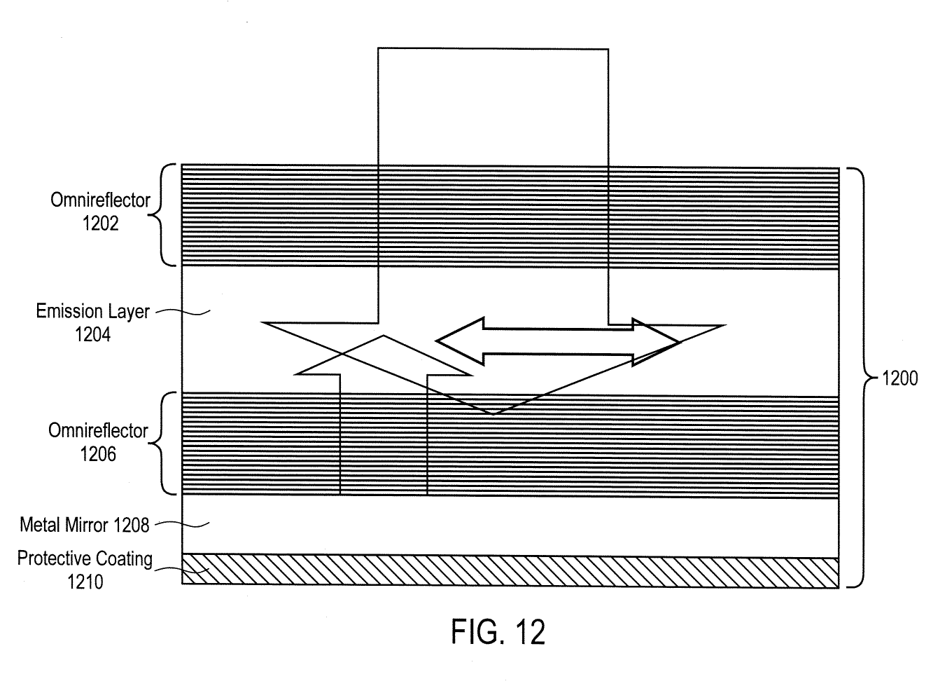

FIG. 12 illustrates a luminescent stack 1200 implemented as a resonant cavity waveguide in accordance with another embodiment of the invention. The luminescent stack 1200 includes a top reflector 1202, which has narrowband reflectivity over emission wavelengths, and a bottom reflector 1208, which has broadband reflectivity. The pair of reflectors 1202 and 1208 sandwich an emission layer 1204, which is disposed so as to be substantially centered at an anti-node position of a resonant electromagnetic wave. While the single emission layer 1204 is illustrated in FIG. 12, it is contemplated that additional emission layers can be included for other implementations. A protective layer 1210 is formed adjacent to a bottom surface of the bottom reflector 1208, and serves to protect the bottom reflector 1208 from environmental conditions. It is contemplated that the protective layer 1210 can be optionally omitted for another implementation. While spacer layers are not illustrated in FIG. 12, it is contemplated that one or more spacer layers can be included for other implementations. Certain aspects of the luminescent stack 1200 can be implemented in a similar manner as described above, and, therefore, are not further described herein.

As illustrated in FIG. 12, another bottom reflector 1206 is included between the emission layer 1204 and the bottom reflector 1208. Similar to the top reflector 1202, the bottom reflector 1206 is implemented as a dielectric stack and has narrowband reflectivity over emission wavelengths. The use of the pair of bottom reflectors 1206 and 1208 in a combination yields enhanced reflectivity over emission wavelengths as well as broadband reflectivity over a wider range of wavelengths, thereby reducing loss of emitted radiation through the pair of bottom reflectors 1206 and 1208 and allowing for two-pass solar irradiation. It is contemplated that the relative positions of the pair of bottom reflectors 1206 and 1208, with respect to the emission layer 1204, can be switched for other implementations.

Additional efficiency gains can be achieved by incorporating a set of luminescent materials that exhibit down-conversion or up-conversion to match an absorption spectrum of an emission layer. The luminescent materials can be incorporated within a separate set of layers of a resonant cavity waveguide or within other layers of the cavity waveguide.

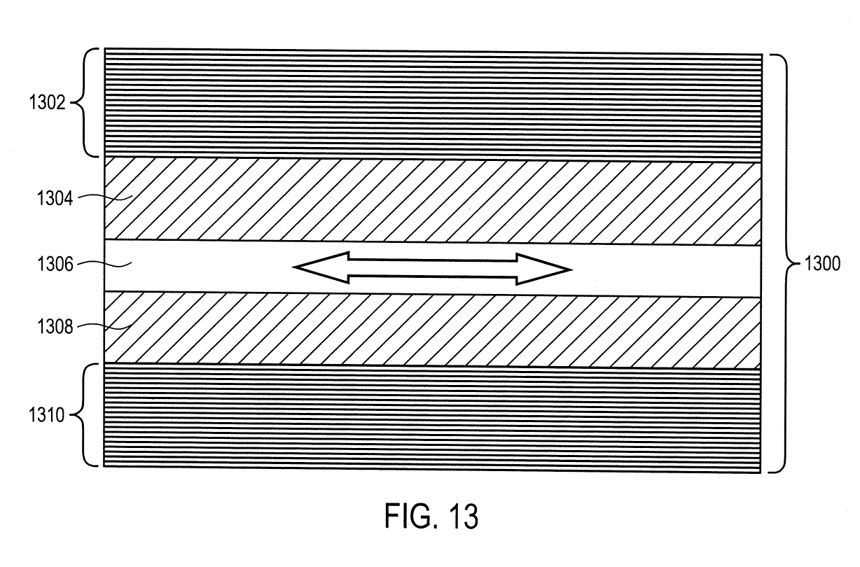

FIG. 13 illustrates a luminescent stack 1300 implemented as a resonant cavity waveguide in accordance with another embodiment of the invention. The luminescent stack 1300 includes a top reflector 1302 and a bottom reflector 1310, which have narrowband reflectivity over emission wavelengths. It is contemplated that the bottom reflector 1310 can also be implemented so as to have broadband reflectivity. The pair of reflectors 1302 and 1310 sandwich an emission layer 1306, which is disposed so as to be substantially centered at an anti-node position of a resonant electromagnetic wave. While the single emission layer 1306 is illustrated in FIG. 13, it is contemplated that additional emission layers can be included for other implementations. Also, while spacer layers are not illustrated in FIG. 13, it is contemplated that one or more spacer layers can be included for other implementations. Certain aspects of the luminescent stack 1300 can be implemented in a similar manner as described above, and, therefore, are not further described herein.

As illustrated in FIG. 13, a top luminescent layer 1304 is included between the top reflector 1302 and the emission layer 1306, and a bottom luminescent layer 1308 is included between the emission layer 1306 and the bottom reflector 1310. Each of the pair of luminescent layers 1304 and 1308 includes a set of luminescent materials that absorb solar radiation and emit radiation in a substantially monochromatic energy band that matches an absorption spectrum of the emission layer 1306. In the illustrated embodiment, the top luminescent layer 1304 is configured to perform down-conversion, such as by including a down-shifting material or a quantum cutting material, while the bottom luminescent layer 1308 is configured to perforin up-conversion, such as by including an up-conversion material. Solar radiation with higher energies is absorbed by the top luminescent layer 1304 and converted into emitted radiation with lower energies that match the absorption spectrum of the emission layer 1306. In turn, the emission layer 1306 absorbs and converts this emitted radiation into stimulated emissions that are guided towards a PV cell (not illustrated). Solar radiation with lower energies, which is not absorbed by the top luminescent layer 1304 or the emission layer 1306, passes through the emission layer 1306 and strikes the bottom luminescent layer 1308, which absorbs and converts this solar radiation into emitted radiation with higher energies that match the absorption spectrum of the emission layer 1306. This emitted radiation is directed upwards and strikes the emission layer 1306, which absorbs and converts this emitted radiation into stimulated emissions that are guided towards the PV cell. By operating in such manner, the luminescent stack 1300 provides enhanced utilization of a solar spectrum by allowing different energy bands within the solar spectrum to be collected and converted into electricity. In addition, thermalization can mostly occur outside of the emission layer 1306, such as within the pair of luminescent layers 1304 and 1308. It is contemplated that the down-conversion and up-conversion roles of the pair of luminescent layers 1304 and 1308 can be switched or modified for other implementations.

ALD can be used to form the top luminescent layer 1304 and the bottom luminescent layer 1308, along with the other layers of the luminescent stack 1300, in a single deposition run. Alternatively, another suitable deposition technique can be used. By selecting a set of luminescent materials having a high absorption coefficient for solar radiation, a thickness of each of the top luminescent layer 1304 and the bottom luminescent layer 1308 can be reduced, such as in the range of about 0.01 μm to about 2 μm, in the range of about 0.05 μm to about 1 μm, in the range of about 0.1 μm to about 1 μm, or in the range of about 0.1 μm to about 0.5 μm. While two luminescent layers 1304 and 1308 are illustrated in FIG. 13, it is contemplated that more or less luminescent layers can be included for other implementations.

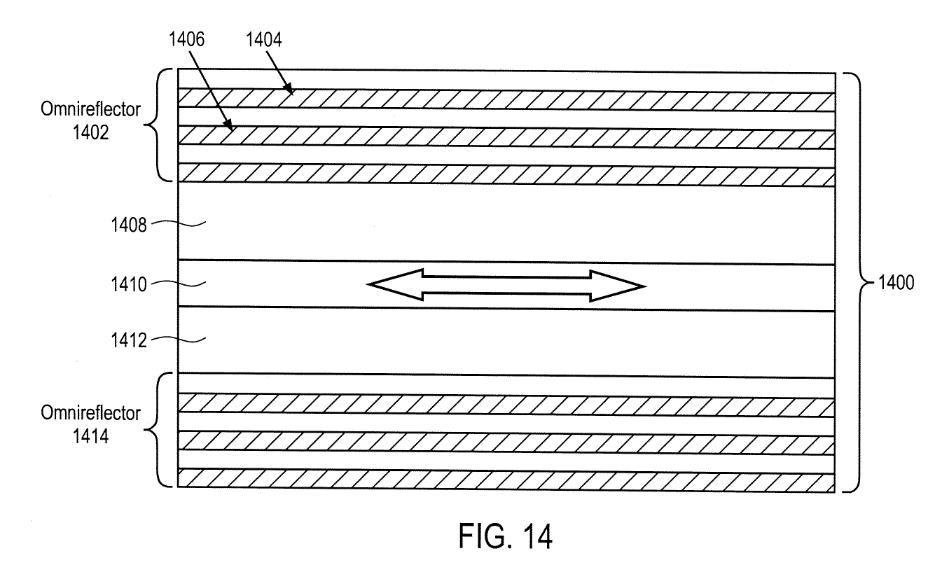

FIG. 14 illustrates a luminescent stack 1400 implemented as a resonant cavity waveguide in accordance with another embodiment of the invention. The luminescent stack 1400 includes a top reflector 1402 and a bottom reflector 1414, which have narrowband reflectivity over emission wavelengths. It is contemplated that the bottom reflector 1414 can also be implemented so as to have broadband reflectivity. The pair of reflectors 1402 and 1414 sandwich an emission layer 1410, which is disposed so as to be substantially centered at an anti-node position of a resonant electromagnetic wave. While the single emission layer 1410 is illustrated in FIG. 14, it is contemplated that additional emission layers can be included for other implementations. A top spacer layer 1408 is included between the top reflector 1402 and the emission layer 1410, and a bottom spacer layer 1412 is included between the emission layer 1410 and the bottom reflector 1414. The pair of spacer layers 1408 and 1412 provide index matching and serve as a pair of passive in-plane waveguide layers for low loss guiding of emitted radiation. It is contemplated that at least one of the pair of spacer layers 1408 and 1412 can be directly involved in conveyance of emitted radiation via optical mode transfer, and that more or less spacer layers can be included for other implementations. Certain aspects of the luminescent stack 1400 can be implemented in a similar manner as described above, and, therefore, are not further described herein.

In the illustrated embodiment, the top reflector 1402 includes a set of luminescent materials that absorb solar radiation and emit radiation in a substantially monochromatic energy band that matches an absorption spectrum of the emission layer 1410. In particular, the top reflector 1402 is implemented as a dielectric stack including multiple dielectric layers. One of these dielectric layers, namely a dielectric layer 1404, is configured to perform down-conversion, such as by including a down-shifting material or a quantum cutting material, while another one of these dielectric layers, namely a dielectric layer 1406, is configured to perform up-conversion, such as by including an up-conversion material. ALD can be used to form the dielectric layers 1404 and 1406, along with the other layers of the luminescent stack 1400, in a single deposition run. Alternatively, another suitable deposition technique can be used. It is contemplated that the down-conversion and up-conversion roles of the pair of dielectric layers 1404 and 1406 can be switched or modified for other implementations. It is also contemplated that more or less dielectric layers included in the top reflector 1402 can be configured to perform down-conversion or up-conversion, and that the bottom reflector 1414 can be similarly configured to perform down-conversion or up-conversion.

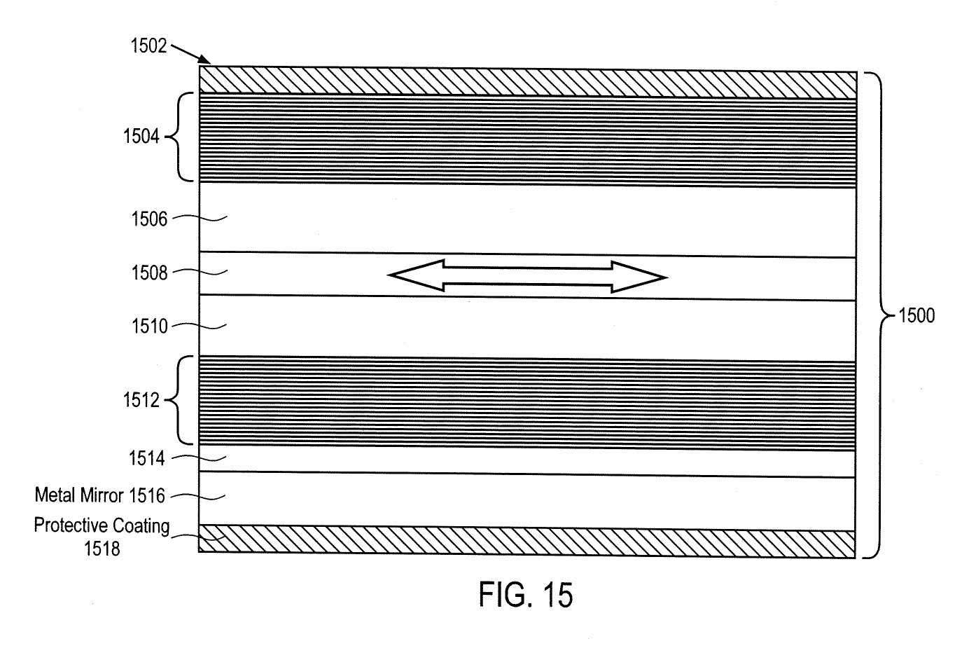

FIG. 15 illustrates a luminescent stack 1500 implemented as a resonant cavity waveguide in accordance with another embodiment of the invention. The luminescent stack 1500 includes a top reflector 1504, which has narrowband reflectivity over emission wavelengths, and a pair of bottom reflectors 1512 and 1516, which are implemented so as to have both narrowband reflectivity over emission wavelengths and broadband reflectivity. The reflectors 1504, 1512, and 1516 sandwich an emission layer 1508, which is disposed so as to be substantially centered at an anti-node position of a resonant electromagnetic wave. While the single emission layer 1508 is illustrated in FIG. 15, it is contemplated that additional emission layers can be included for other implementations. A protective layer 1518 is formed adjacent to a bottom surface of the bottom reflector 1516, and serves to protect the bottom reflector 1516 from environmental conditions. It is contemplated that the protective layer 1518 can be optionally omitted for another implementation. A top spacer layer 1506 is included between the top reflector 1504 and the emission layer 1508, and a bottom spacer layer 1510 is included between the emission layer 1508 and the bottom reflector 1512. The pair of spacer layers 1506 and 1510 provide index matching and serve as a pair of passive in-plane waveguide layers for low loss guiding of emitted radiation. It is contemplated that at least one of the pair of spacer layers 1506 and 1510 can be directly involved in conveyance of emitted radiation via optical mode transfer, and that more or less spacer layers can be included for other implementations. Certain aspects of the luminescent stack 1500 can be implemented in a similar manner as described above, and, therefore, are not further described herein.

As illustrated in FIG. 15, a top luminescent layer 1502 is included adjacent to a top surface of the top reflector 1504, and a bottom luminescent layer 1514 is included between the pair of bottom reflectors 1512 and 1516. Each of the pair of luminescent layers 1502 and 1514 includes a set of luminescent materials that absorb solar radiation and emit radiation in a substantially monochromatic energy band that matches an absorption spectrum of the emission layer 1508. In the illustrated embodiment, the top luminescent layer 1502 is configured to perform down-conversion, such as by including a down-shifting material or a quantum cutting material, while the bottom luminescent layer 1514 is configured to perform up-conversion, such as by including an up-conversion material. ALD can be used to form the pair of luminescent layers 1502 and 1514, along with the other layers of the luminescent stack 1500, in a single deposition run. Alternatively, another suitable deposition technique can be used. It is contemplated that the down-conversion and up-conversion roles of the pair of luminescent layers 1502 and 1514 can be switched or modified for other implementations. It is also contemplated that more or less luminescent layers can be included, and that their relative positions with respect to one another (and with respect to the other layers) can differ from that illustrated in FIG. 15.

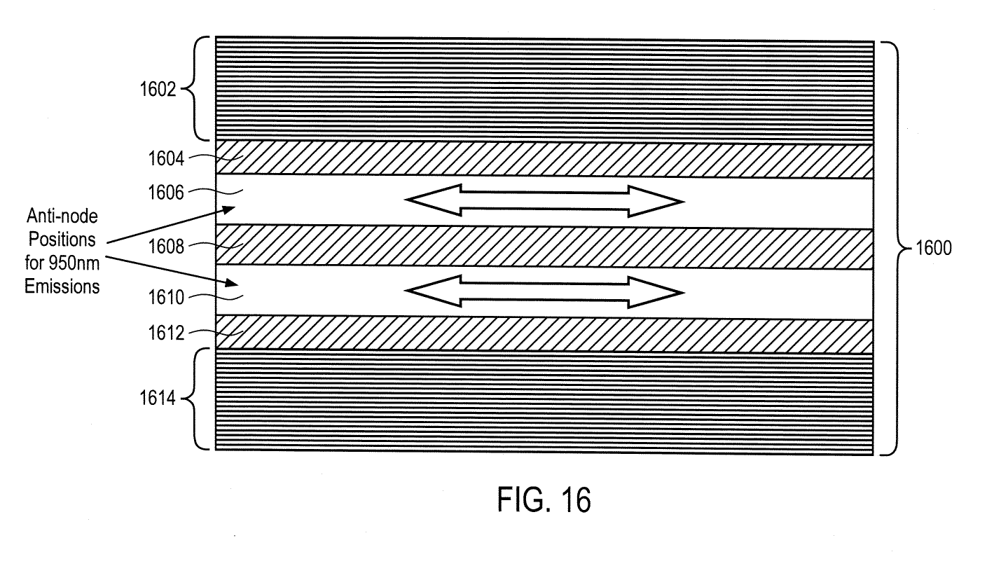

FIG. 16 illustrates a luminescent stack 1600 implemented as a resonant cavity waveguide in accordance with another embodiment of the invention. The luminescent stack 1600 includes a top reflector 1602 and a bottom reflector 1614, which have narrowband reflectivity over emission wavelengths. It is contemplated that the bottom reflector 1614 can also be implemented so as to have broadband reflectivity. The pair of reflectors 1602 and 1614 sandwich a pair of emission layers, namely a top emission layer 1606 and a bottom emission layer 1610, such that the top reflector 1602 is adjacent to a top surface of the top emission layer 1606, and the bottom reflector 1614 is adjacent to a bottom surface of the bottom emission layer 1610. The pair of emission layers 1606 and 1610 are disposed so as to be substantially centered at respective anti-node positions with respect to emission wavelengths, such as with respect to a peak emission wavelength of about 950 nm. While two emission layers 1606 and 1610 are illustrated in FIG. 16, it is contemplated that more or less emission layers can be included for other implementations.

As illustrated in FIG. 16, a top spacer layer 1604 is included between the top reflector 1602 and the top emission layer 1606, a middle spacer layer 1608 is included between the top emission layer 1606 and the bottom emission layer 1610, and a bottom spacer layer 1612 is included between the bottom emission layer 1610 and the bottom reflector 1614. The spacer layers 1604, 1608, and 1612 provide index matching and serve as passive in-plane waveguide layers for low loss guiding of emitted radiation. It is contemplated that at least one of the spacer layers 1604, 1608, and 1612 can be directly involved in conveyance of emitted radiation via optical mode transfer, and that more or less spacer layers can be included for other implementations. Certain aspects of the luminescent stack 1600 can be implemented in a similar manner as described above, and, therefore, are not further described herein.

In the illustrated embodiment, at least one of the spacer layers 1604, 1608, and 1612 includes a set of luminescent materials that absorb solar radiation and emit radiation in a substantially monochromatic energy band that matches an absorption spectrum of either, or both, of the pair of emission layers 1606 and 1610. For example, one of the spacer layers 1604, 1608, and 1612, such as the top spacer layer 1604, can be configured to perform down-conversion, such as by including a down-shifting material or a quantum cutting material, while another one of the spacer layers 1604, 1608, and 1612, such as the bottom spacer layer 1612, can be configured to perform up-conversion, such as by including an up-conversion material. In this example, the top spacer layer 1604 can be substantially centered at an anti-node position with respect to down-converted wavelengths, while the bottom spacer layer 1612 can be substantially centered at an anti-node position with respect to up-converted wavelengths. It is contemplated that the down-conversion and up-conversion roles of the spacer layers 1604 and 1612 can be switched or modified for other implementations. It is also contemplated that more or less of the spacer layers 1604, 1608, and 1612 can be configured to perform down-conversion or up-conversion. ALD can be used to form the spacer layers 1604, 1608, and 1612, along with the other layers of the luminescent stack 1600, in a single deposition run. Alternatively, another suitable deposition technique can be used.

Further efficiency gains can be achieved by incorporating a distributed array or grating structure that can enhance vertical to in-plane optical coupling as well as enhance absorption of solar radiation. The array or grating structure can be incorporated within a separate layer of a resonant cavity waveguide or within another layer of the cavity waveguide.

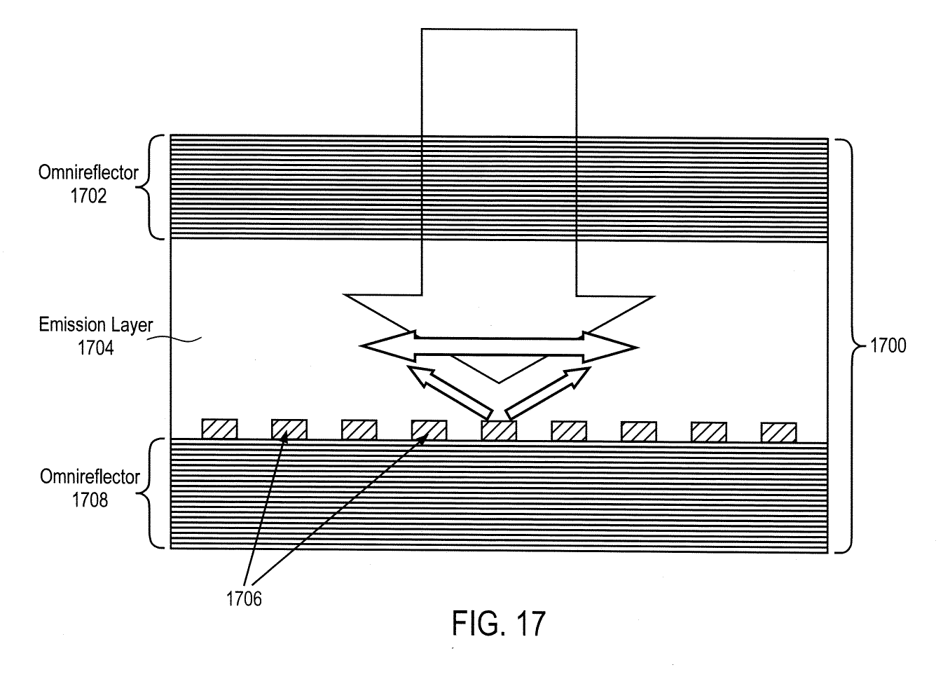

FIG. 17 illustrates a luminescent stack 1700 implemented as a resonant cavity waveguide in accordance with another embodiment of the invention. The luminescent stack 1700 includes a top reflector 1702 and a bottom reflector 1708, which have narrowband reflectivity over emission wavelengths. It is contemplated that the bottom reflector 1708 can also be implemented so as to have broadband reflectivity. The pair of reflectors 1702 and 1708 sandwich an emission layer 1704, which is disposed so as to be substantially centered at an anti-node position of a resonant electromagnetic wave. While the single emission layer 1704 is illustrated in FIG. 17, it is contemplated that additional emission layers can be included for other implementations. Also, while spacer layers are not illustrated in FIG. 17, it is contemplated that one or more spacer layers can be included for other implementations. Certain aspects of the luminescent stack 1700 can be implemented in a similar manner as described above, and, therefore, are not further described herein.

As illustrated in FIG. 17, a grating structure 1706 is included adjacent to an interface between the emission layer 1704 and the bottom reflector 1708. It is contemplated that the grating structure 1706 can be partially or fully embedded within the emission layer 1704 or within another layer, such as a spacer layer (not illustrated) included between the emission layer 1704 and the bottom reflector 1708. The grating structure 1706 serves to reflect solar radiation and preferentially re-distribute or re-direct the solar radiation so as to enhance its coupling to stimulated emissions along an in-plane guiding direction within the emission layer 1704. Also, the grating structure 1706 can reflect radiation emitted by the emission layer 1704 and preferentially re-distribute or re-direct the emitted radiation from an original isotropic distribution to an in-plane guiding direction within the emission layer 1704. The grating structure 1706 can extend in one dimension, two dimensions, or three dimensions, and can be formed in a substantially periodic manner using photolithography, nanoimprint lithography, or another suitable technique. While the single grating structure 1706 is illustrated in FIG. 17, it is contemplated that additional grating structures can be included for other implementations. It is also contemplated that another type of grating structure can be included in place of, or in combination with, the grating structure 1706. For example, a photonic crystal can be implemented as an array of two or more materials with different refractive indices that are arranged in a substantially periodic manner. For light in the visible and near infrared ranges, a spacing within the array can be in the range of a few hundred nanometers to a few micrometers or so.

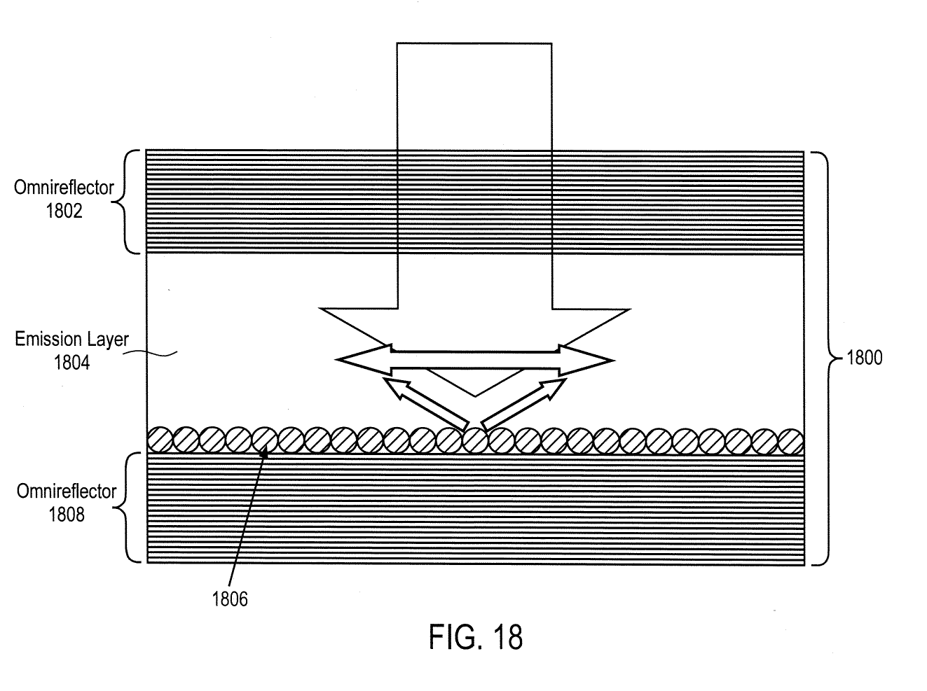

FIG. 18 illustrates a luminescent stack 1800 implemented as a resonant cavity waveguide in accordance with another embodiment of the invention. The luminescent stack 1800 includes a top reflector 1802 and a bottom reflector 1808, which have narrowband reflectivity over emission wavelengths. It is contemplated that the bottom reflector 1808 can also be implemented so as to have broadband reflectivity. The pair of reflectors 1802 and 1808 sandwich an emission layer 1804, which is disposed so as to be substantially centered at an anti-node position of a resonant electromagnetic wave. While the single emission layer 1804 is illustrated in FIG. 18, it is contemplated that additional emission layers can be included for other implementations. Also, while spacer layers are not illustrated in FIG. 18, it is contemplated that one or more spacer layers can be included for other implementations. Certain aspects of the luminescent stack 1800 can be implemented in a similar manner as described above, and, therefore, are not further described herein.

As illustrated in FIG. 18, an array of microparticles 1806 is included adjacent to an interface between the emission layer 1804 and the bottom reflector 1808. It is contemplated that the array of microparticles 1806 can be partially or fully embedded within the emission layer 1804 or within another layer, such as a spacer layer (not illustrated) included between the emission layer 1804 and the bottom reflector 1808. Similar to a grating structure, the array of microparticles 1806 serves to enhance optical coupling to stimulated emissions along an in-plane guiding direction within the emission layer 1804. The array of microparticles 1806 can extend in one dimension, two dimensions, or three dimensions, and can be formed by deposition of pre-formed microparticles, in-situ growth of microparticles, or another suitable technique. It is contemplated that an array of nanoparticles can be used in place of, or in combination with, the array of microparticles 1806.

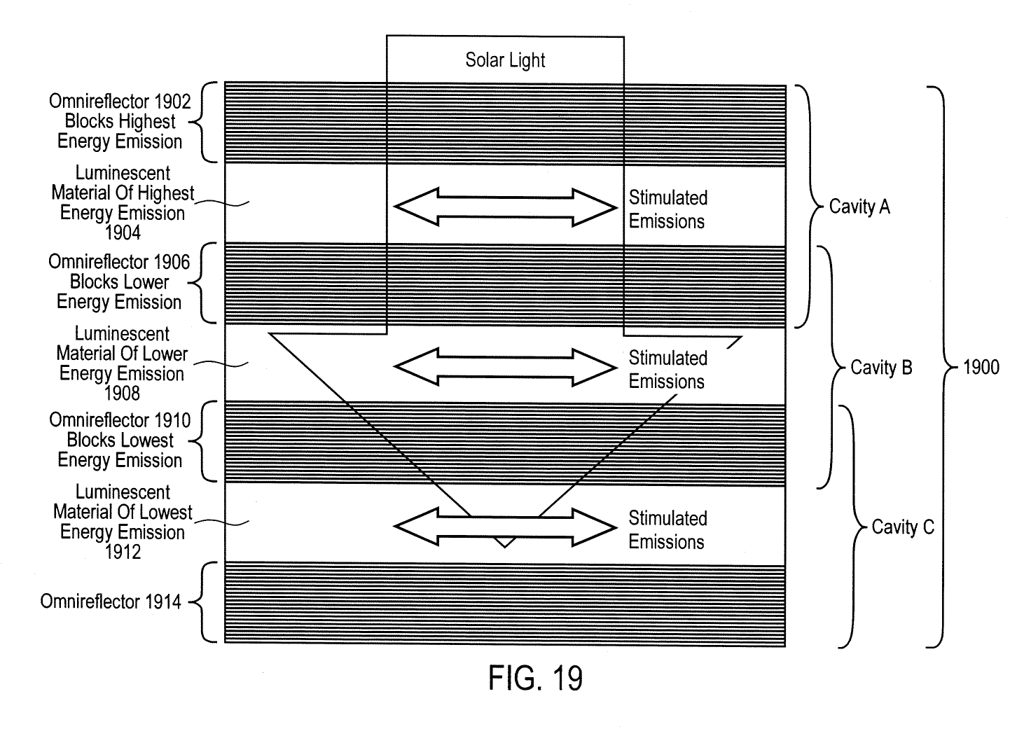

FIG. 19 illustrates a luminescent stack 1900 implemented in accordance with another embodiment of the invention. The luminescent stack 1900 is implemented for a multi-junction device, and includes multiple resonant cavity waveguides that are optically coupled to respective PV cells (not illustrated) having different bandgap energies. For example, the PV cells can be formed from Group III materials, Group IV materials, Group V materials, or combinations thereof, with bandgap energies in the range of about 2.5 eV to about 1.3 eV or in the range of about 2.5 eV to about 0.7 eV. For example, silicon has a bandgap energy of about 1.1 eV, and germanium has a bandgap energy of about 0.7 eV. Certain aspects of the luminescent stack 1900 can be implemented in a similar manner as described above, and, therefore, are not further described herein.

As illustrated in FIG. 19, the luminescent stack 1900 includes multiple emission layers 1904, 1908, and 1912, each of which is configured to absorb solar radiation and emit radiation in a substantially monochromatic energy band that matches a bandgap energy of its respective PV cell. The emission layer 1904 is sandwiched by a top reflector 1902 and a middle reflector 1906, and the pair of reflectors 1902 and 1906, along with the emission layer 1904, correspond to a resonant cavity waveguide A. The emission layer 1908 is sandwiched by the middle reflector 1906 and another middle reflector 1910, and the pair of reflectors 1906 and 1910, along with the emission layer 1908, correspond to a resonant cavity waveguide B. The emission layer 1912 is sandwiched by the middle reflector 1910 and a bottom reflector 1914, and the pair of reflectors 1910 and 1914, along with the emission layer 1912, correspond to a resonant cavity waveguide C. In the illustrated embodiment, the top reflector 1902 has narrowband reflectivity over emission wavelengths of the emission layer 1904, the middle reflector 1906 has narrowband reflectivity over emission wavelengths of the emission layer 1908, and the middle reflector 1910 and the bottom reflector 1914 have narrowband reflectivity over emission wavelengths of the emission layer 1912. It is contemplated that the bottom reflector 1914 can also be implemented so as to have broadband reflectivity. While spacer layers are not illustrated in FIG. 19, it is contemplated that one or more spacer layers can be included for other implementations.

During operation of the luminescent stack 1900, incident solar radiation strikes the emission layer 1904, which is configured to perform down-conversion with respect to a bandgap energy E_{gA}. Solar radiation with energies at or higher than the bandgap energy E_{gA} is absorbed and converted into substantially monochromatic, emitted radiation that is guided towards its respective PV cell, which absorbs and converts this emitted radiation into electricity. Solar radiation with energies lower than the bandgap energy E_{gA} passes through the emission layer 1904 and strikes the emission layer 1908, which is configured to perform down-conversion with respect to a bandgap energy E_{gB}. Solar radiation with energies at or higher than the bandgap energy E_{gB} (and lower than the bandgap energy E_{gA}) is absorbed and converted into substantially monochromatic, emitted radiation that is guided towards its respective PV cell, which absorbs and converts this emitted radiation into electricity. Solar radiation with energies lower than the bandgap energy E_{gB} passes through the emission layer 1908 and strikes the emission layer 1912, which is configured to perform down-conversion with respect to a bandgap energy E_{gC}. Solar radiation with energies at or higher than the bandgap energy E_{gC} (and lower than the bandgap energy E_{gB}) is absorbed and converted into substantially monochromatic, emitted radiation that is guided towards its respective PV cell, which absorbs and converts this emitted radiation into electricity. In the illustrated embodiment, the bandgap energies E_{gA}, E_{gB}, and E_{gC} are related as follows: E_{gA}>E_{gB}>E_{gC}.

By operating in such mariner, the luminescent stack 1900 provides enhanced utilization of a solar spectrum by allowing different energy bands within the solar spectrum to be collected and converted into electricity. While three resonant cavity waveguides A, B, and C are illustrated in FIG. 19, it is contemplated that more or less cavity waveguides can be included for other implementations. In some instances, solar energy conversion efficiency can be increased from a value of about 31 percent when one PV cell is used to a value of about 50 percent when three PV cells are used and towards a value of about 85 percent when a virtually unlimited number of PV cells are used.

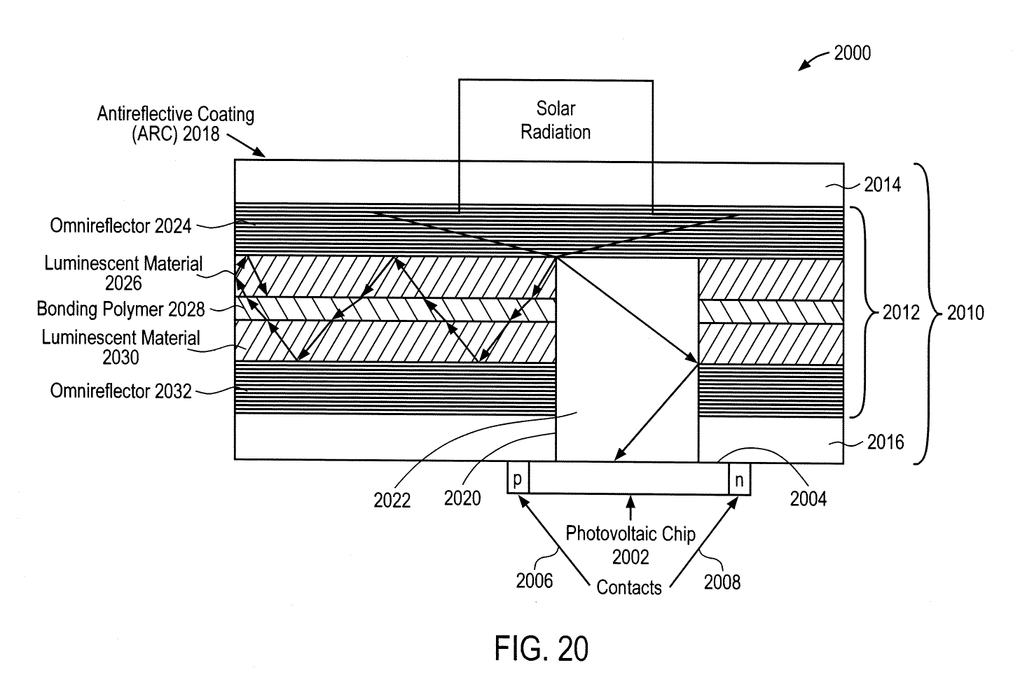

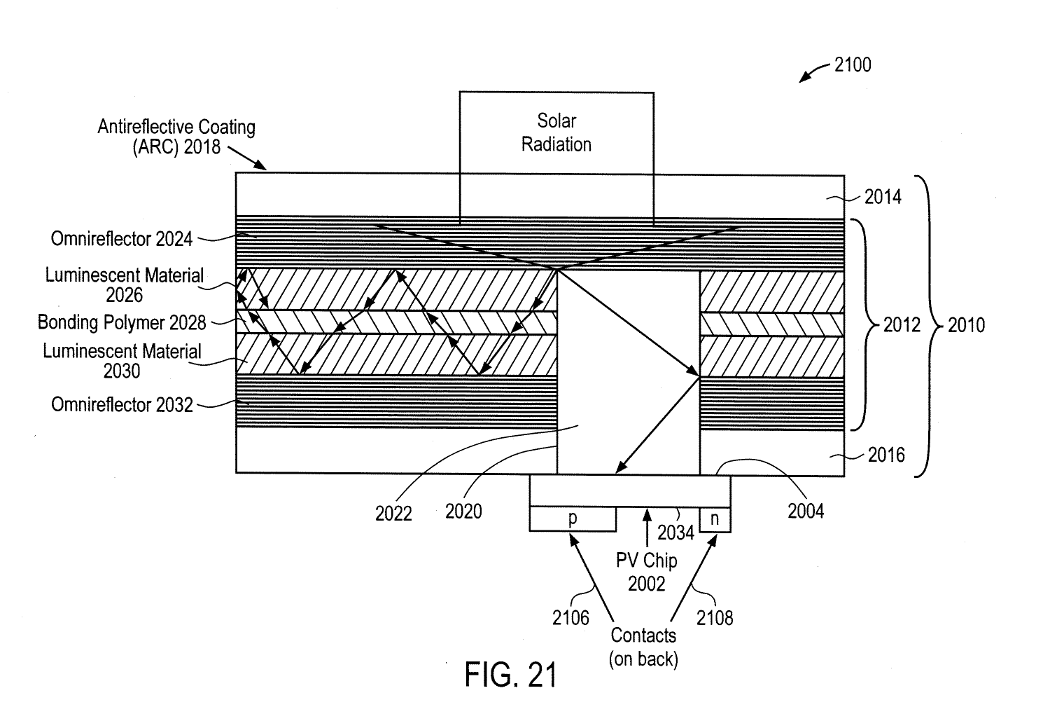

FIG. 20 through FIG. 25 illustrate solar modules 2000, 2100, 2200, 2300, 2400, and 2500 implemented in accordance with various embodiments of the invention. For ease of presentation, the following discussion is primarily with reference to the solar module 2000 of FIG. 20, although the discussion also applies with reference to the solar modules 2100, 2200, 2300, 2400, and 2500 of FIG. 21 through FIG. 25. Also, certain aspects of the solar modules 2000, 2100, 2200, 2300, 2400, and 2500 can be implemented in a similar manner as described above, and, therefore, are not further described herein.

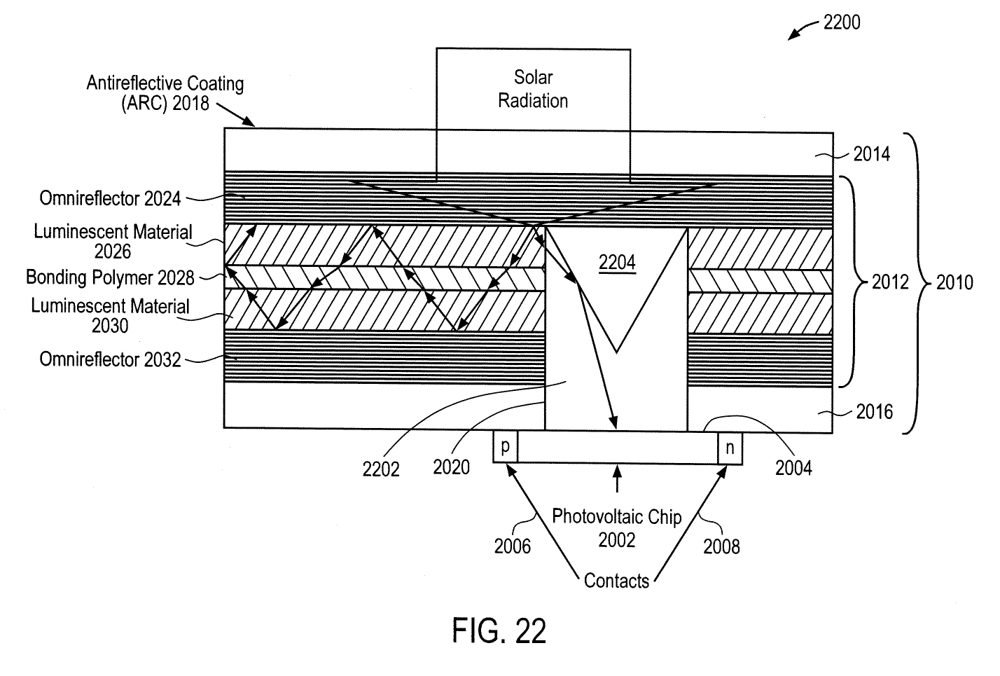

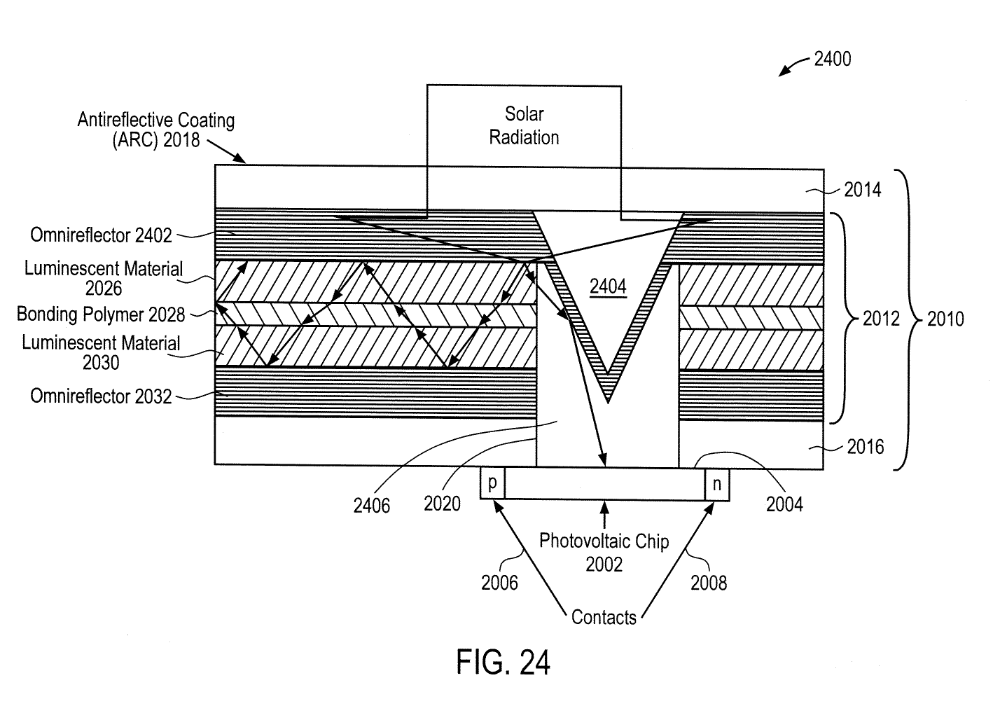

Referring to FIG. 20, the solar module 2000 includes a PV cell 2002, which is a p-n junction device formed from crystalline silicon. However, the PV cell 2002 can also be formed from another suitable photoactive material. As illustrated in FIG. 20, the PV cell 2002 is configured to accept and absorb radiation incident upon a top surface 2004 of the PV cell 2002, although other surfaces of the PV cell 2002 can also be involved. The orientation of the PV cell 2002 is such that its depletion region is substantially aligned with respect to emitted radiation that is guided towards the PV cell 2002. The alignment of the depletion region with respect to emitted radiation can enhance uniformity of optical excitation across the depletion region and enhance solar energy conversion efficiencies. A pair of electrical contacts 2006 and 2008 are connected to respective sides of the depletion region to extract charge carriers produced by the PV cell 2002. FIG. 22 and FIG. 24 illustrate the solar modules 2200 and 2400 implemented in accordance with other embodiments of the invention, in which the electrical contacts 2006 and 2008 are similarly positioned with respect to the PV cell 2002.

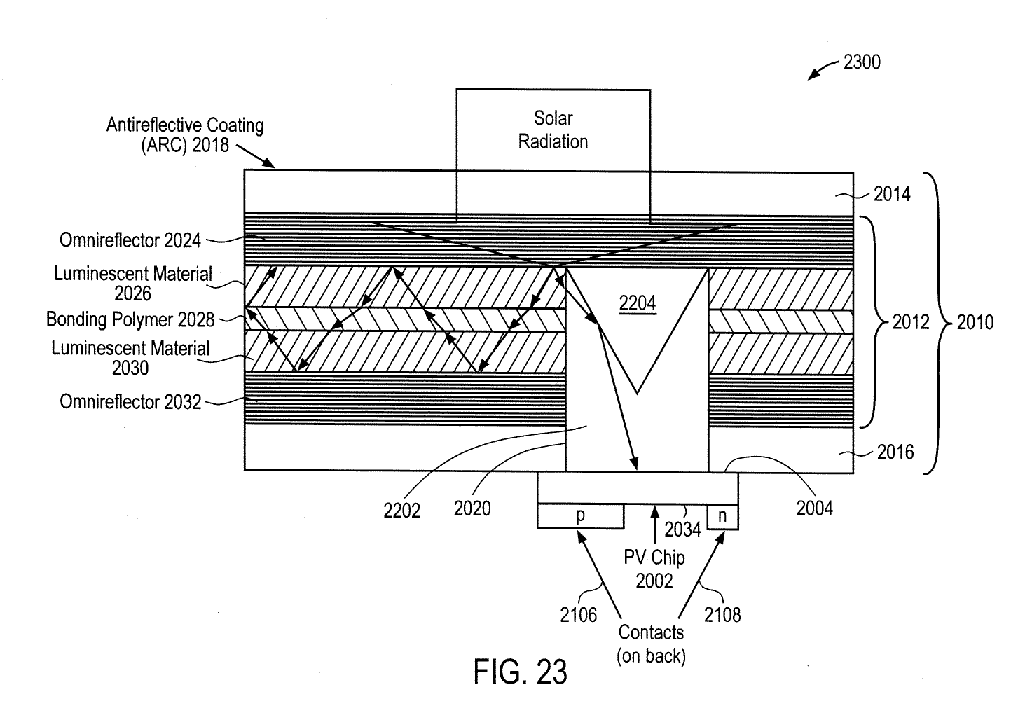

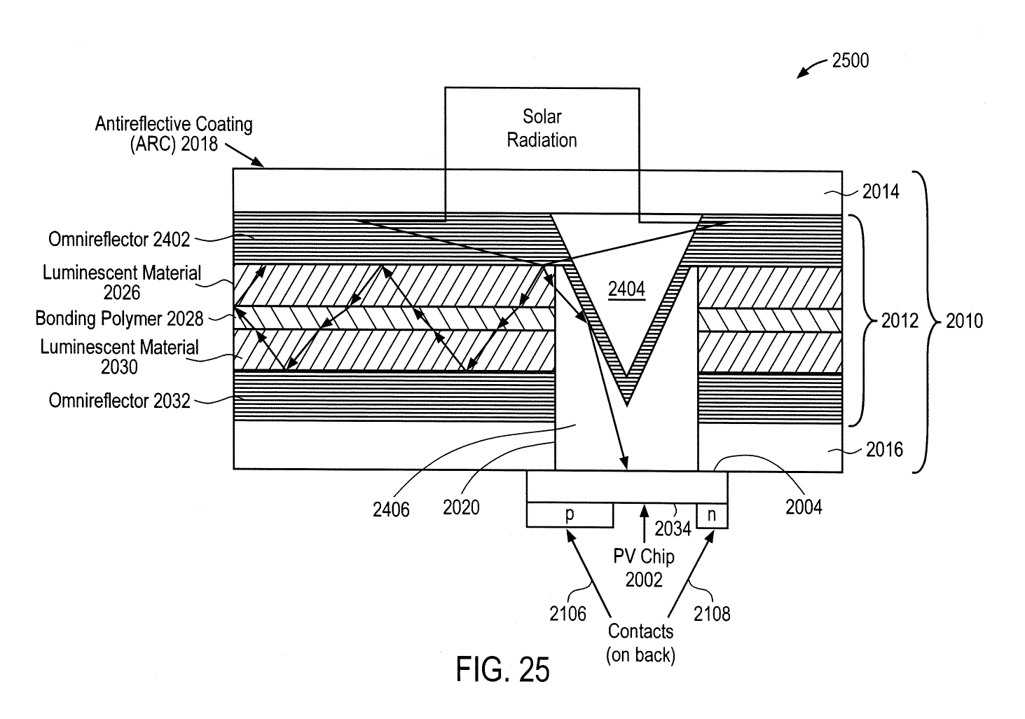

Positioning of electrical contacts can vary for other implementations. For example, FIG. 21, FIG. 23, and FIG. 25 illustrate the solar modules 2100, 2300, and 2500 implemented in accordance with other embodiments of the invention, in which a pair of electrical contacts 2106 and 2108 are both disposed adjacent to a bottom surface 2034 of the PV cell 2002. The positioning of the electrical contacts 2106 and 2108 can allow at least one of the electrical contacts 2106 and 2108 to be spaced further apart from other components of the solar module 2100, 2300, or 2500 and to have a larger cross-sectional area for improved heat dissipation as well as low-loss conduction to external circuitry.

Turning back to FIG. 20, the solar module 2000 includes a spectral concentrator 2010 that is optically coupled to the PV cell 2002. The spectral concentrator 2010 includes a luminescent stack 2012, which converts a relatively wide range of energies of incident solar radiation into stimulated emissions including a relatively narrow, substantially monochromatic energy band. The luminescent stack 2012 is sandwiched by a top substrate layer 2014 and a bottom substrate layer 2016, which are adjacent to a top surface and a bottom surface of the luminescent stack 2012, respectively. An anti-reflection layer 2018 is formed as a coating adjacent to a top surface of the top substrate layer 2014 to reduce reflection of incident solar radiation. While not illustrated in FIG. 20, side edges and surfaces of the spectral concentrator 2010, which are not involved in conveyance of radiation, can have a reflector formed thereon, such as white paint or another suitable reflective material.

In the illustrated embodiment, the luminescent stack 2012 includes a top reflector 2024 and a bottom reflector 2032, which are implemented as dielectric stacks including multiple dielectric layers and having narrowband reflectivity over emission wavelengths. It is contemplated that the bottom reflector 2032 can also be implemented so as to have broadband reflectivity. The pair of reflectors 2024 and 2032 sandwich a pair of emission layers, namely a top emission layer 2026 and a bottom emission layer 2030, such that the top reflector 2024 is adjacent to a top surface of the top emission layer 2026, and the bottom reflector 2032 is adjacent to a bottom surface of the bottom emission layer 2030. Each of the pair of emission layers 2026 and 2030 includes a set of luminescent materials that convert a relatively wide range of energies of solar radiation into a relatively narrow, substantially monochromatic energy band. The pair of emission layers 2026 and 2030 can be formed from the same set of luminescent materials or from different sets of luminescent materials. While two emission layers 2026 and 2030 are illustrated in FIG. 20, it is contemplated that more or less emission layers can be included for other implementations. Also, while spacer layers are not illustrated in FIG. 20, it is contemplated that one or more spacer layers can be included for other implementations.

Referring to FIG. 20, a bonding layer 2028 is included between the emission layers 2026 and 2030, and serves to connect the emission layers 2026 and 2030 via adhesion, hydrogen bonding, or inter-diffusion. The bonding layer 2028 can have a thickness in the range of about 1 nm to about 50 μm, such as in the range of about 500 nm to about 30 μm, in the range of about 1 nm to about 500 nm, in the range of about 1 μm to about 100 nm, or in the range of about 10 nm to about 100 nm. Examples of materials that can be used to form the bonding layer 2028 include a glass, such as a spin-on glass or a sealing glass; a polymer, such as a perfluoropolymer or an epoxy-based polymer; or another suitable adhesive or bonding material that is optically transparent or translucent. For certain implementations, the bonding layer 2028 can provide index matching to enhance optical coupling between the emission layers 2026 and 2030 and to enhance an efficiency at which emitted radiation is guided towards the PV cell 2002. It is also contemplated that the bonding layer 2028 can be formed from a suitable low index material, such that the luminescent stack 2012 serves as an ARROW. While the single bonding layer 2028 is illustrated in FIG. 20, it is contemplated that additional bonding layers can be included for other implementations.

During manufacturing of the spectral concentrator 2010, the top reflector 2024 and the top emission layer 2026 can be formed adjacent to the top substrate layer 2014 using ALD or another suitable deposition technique, and the bottom reflector 2032 and the bottom emission layer 2030 can be formed adjacent to the bottom substrate layer 2016 using ALD or another suitable deposition technique. Next, the bonding layer 2028 can be formed by depositing a suitable adhesive or bonding material adjacent to exposed surfaces of either, or both, of the emission layers 2026 and 2030. The assembly of layers can then be subjected to bonding, such as by applying heat and pressure, so as to form a substantially monolithic, bonded structure. Certain aspects regarding manufacturing of solar modules via a bonding approach are described in U.S. Patent Application Ser. No. 61/146,595, entitled “Solar Modules Including Spectral Concentrators and Related Manufacturing Methods” and filed on Jan. 22, 2009, the disclosure of which is incorporated herein by reference in its entirety.

Referring to FIG. 20, the spectral concentrator 2010 includes a groove 2020 to facilitate guiding of emitted radiation towards the PV cell 2002. During manufacturing of the spectral concentrator 2010, various layers can be formed, and certain portions of these layers can be removed to form the groove 2020. Alternatively, a selective deposition technique can be implemented to form the groove 2020. Disposed within the groove 2020 is a waveguide structure 2022, which serves to re-distribute or re-direct emitted radiation so as to enhance its coupling to the PV cell 2002. The waveguide structure 2022 can be formed from a low index polymer or another suitable low index material that is optically transparent or translucent, which can be deposited within the groove 2020 using any suitable deposition technique.

Additional enhancements in optical coupling can be achieved by incorporating a reflective structure within the groove 2020. Referring to FIG. 22 and FIG. 23, a wedge 2204 is disposed within the groove 2020, such that a base of the wedge 2204 is adjacent to a bottom surface of the top reflector 2024, while a tip of the wedge 2204 faces towards the PV cell 2002. The wedge 2204 can be formed from, or coated with, a metal or another suitable reflective material, and is partially embedded within a waveguide structure 2202, which can be formed from a low index polymer or another suitable low index material that is optically transparent or translucent.

Referring next to FIG. 24 and FIG. 25, a wedge 2404 is disposed within the groove 2020, such that a base of the wedge 2404 is adjacent to a bottom surface of the top substrate layer 2014, while a tip of the wedge 2404 faces towards the PV cell 2002. In the illustrated embodiments, a top reflector 2402 is formed so as to extend along and cover exposed surfaces of the wedge 2404. The wedge 2404 can be formed from a suitable reflective material or a suitable non-reflective material, and is partially embedded within a waveguide structure 2406, which can be foamed from a low index polymer or another suitable low index material that is optically transparent or translucent.

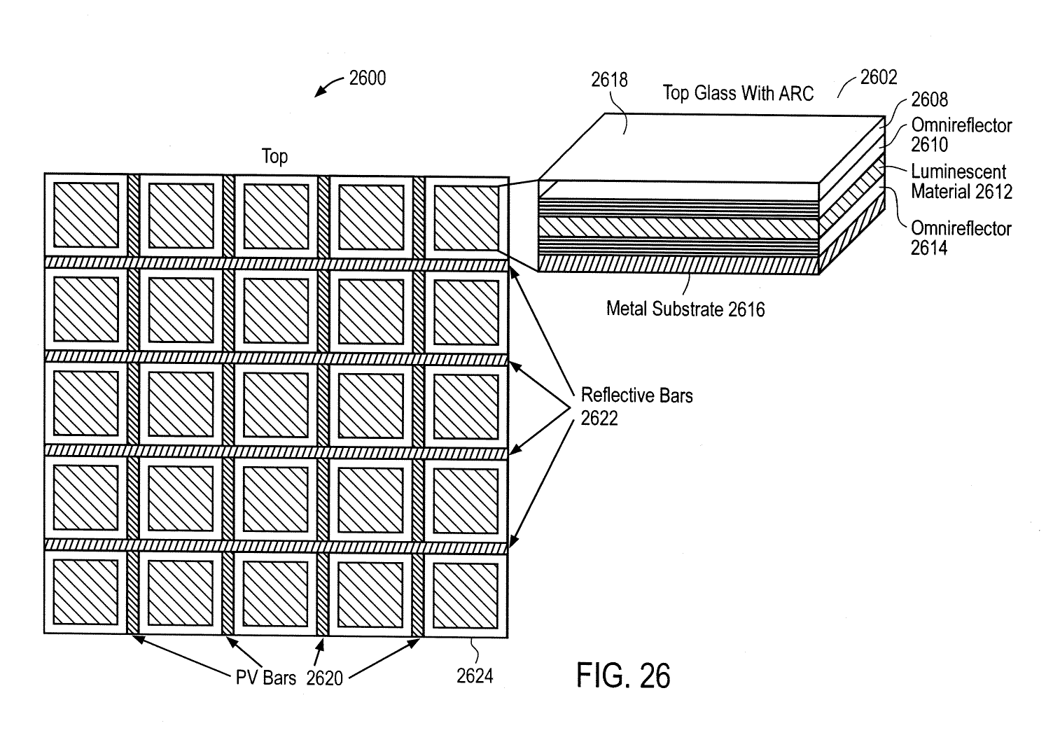

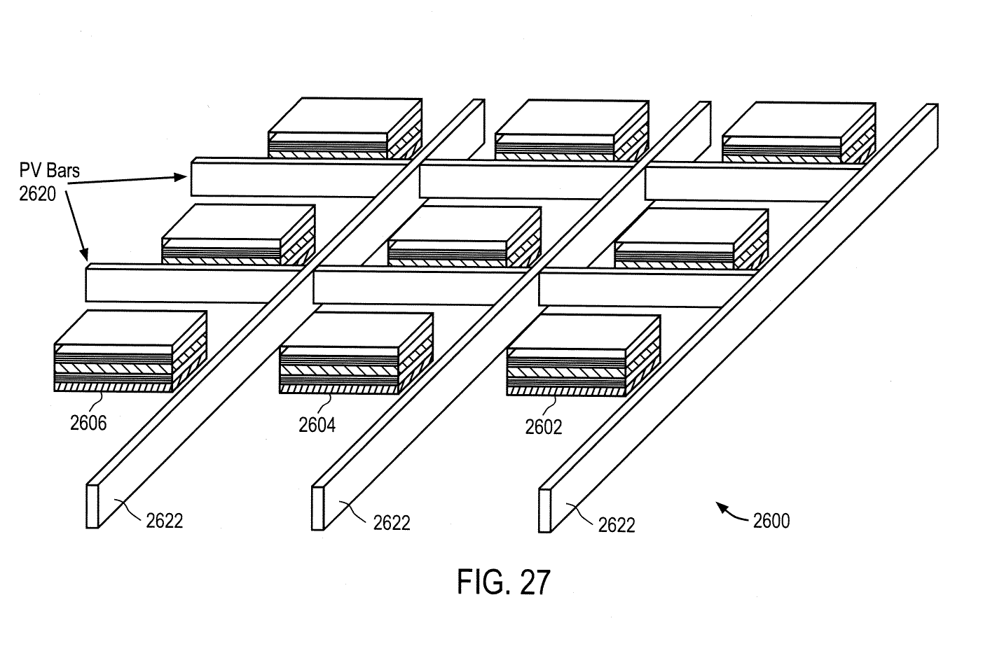

Attention next turns to FIG. 26 and FIG. 27, which illustrate manufacturing of a solar module 2600 according to an embodiment of the invention. The solar module 2600 includes an array of spectral concentrators, including spectral concentrators 2602, 2604, and 2606. Each of the spectral concentrators, such as the spectral concentrator 2602, includes a top substrate layer 2608 and a bottom substrate layer 2616, which sandwich a luminescent stack including a top reflector 2610, an emission layer 2612, and a bottom reflector 2614. The top substrate layer 2608 faces incident solar radiation, and an anti-reflection layer 2618 is formed as a coating adjacent to a top surface of the top substrate layer 2608. In the illustrated embodiment, the bottom substrate layer 2616 is formed from a metal to provide broadband reflectivity as well as improved heat dissipation.

Once formed, the spectral concentrators are readily combined with other pre-formed components, including a set of PV bars 2620 and a set of reflective bars 2622, and bonded to a superstrate 2624, such that at least one of the PV bars 2620 is disposed between adjacent columns or rows of spectral concentrators, and at least one of the reflective bars 2622 is disposed between adjacent rows or columns of spectral concentrators. As illustrated in FIG. 26 and FIG. 27, each of the PV bars 2620 is bifacial and, therefore, is able to accept and absorb radiation incident upon two side surfaces, and the reflective bars 2622 are formed from, or coated with, a metal, a set of dielectric layers, white paint, or another suitable reflective material. Because the spectral concentrators can be implemented for low loss guiding of emitted radiation, the PV bars 2620 can be spaced further apart, such as by up to a few meters. This greater spacing, in turn, can translate into a reduced number of the PV bars 2620 and a reduction in manufacturing costs. This greater spacing can also allow more massive bus bars to handle a higher current output. A bound on this spacing can relate to a photo-generated current for the PV bars 2620, such as a threshold current density for a p-n junction device formed from crystalline silicon. It is contemplated that the reflective bars 2622 can be optionally omitted and replaced with a set of additional PV bars. In the illustrated embodiment, the superstrate 2624 faces incident solar radiation and provides rigidity and protection from environmental conditions. The superstrate 2624 can be formed from a glass, a polymer, or another suitable material that is optically transparent or translucent. It is contemplated that an anti-reflection layer can be formed adjacent to a top surface of the superstrate 2624, and that either, or both, of the anti-reflection layer 2618 and the top substrate layer 2608 can be optionally omitted from each of the spectral concentrators.

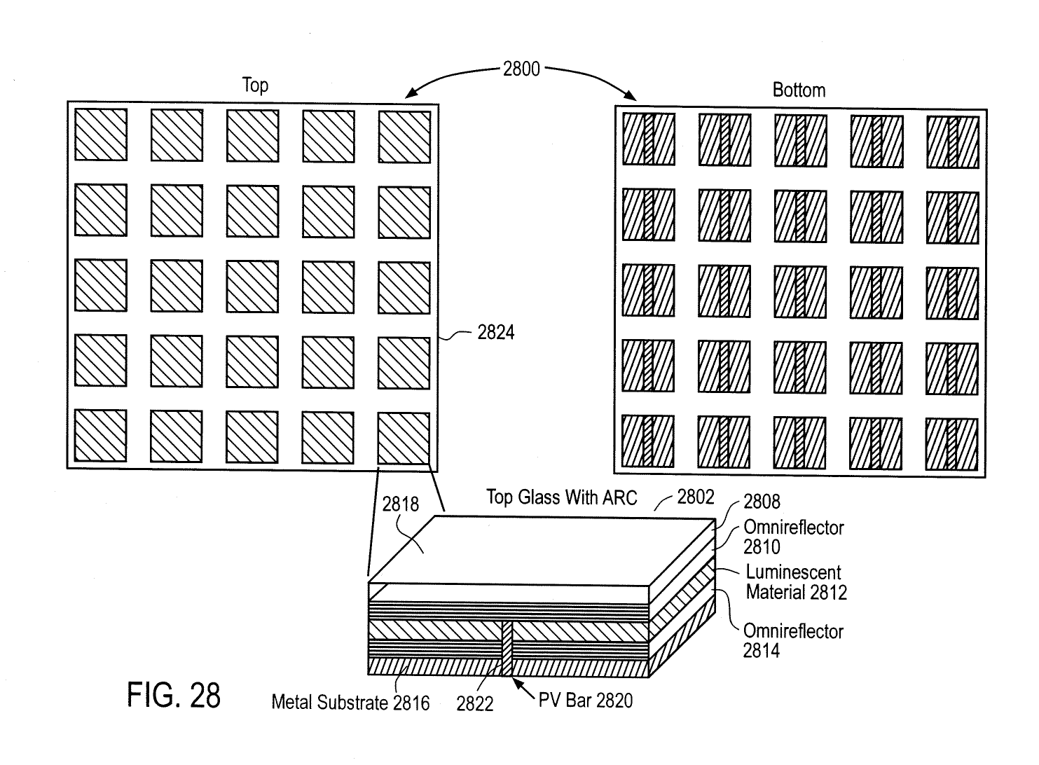

FIG. 28 illustrates manufacturing of a solar module 2800 according to another embodiment of the invention. The solar module 2800 includes an array of spectral concentrators, including a spectral concentrator 2802. Each of the spectral concentrators, such as the spectral concentrator 2802, includes a top substrate layer 2808 and a bottom substrate layer 2816, which sandwich a luminescent stack including a top reflector 2810, an emission layer 2812, and a bottom reflector 2814. The top substrate layer 2808 faces incident solar radiation, and an anti-reflection layer 2818 is formed as a coating adjacent to a top surface of the top substrate layer 2808. In the illustrated embodiment, the bottom substrate layer 2816 is formed from a metal to provide broadband reflectivity as well as improved heat dissipation. Each of the spectral concentrators includes a groove 2822 to accommodate a respective PV bar 2820. As illustrated in FIG. 28, the PV bar 2820 is bifacial and, therefore, is able to accept and absorb radiation incident upon two side surfaces. While not illustrated in FIG. 28, side edges and surfaces of each of the spectral concentrators, which are not involved in conveyance of radiation, can have a reflector formed thereon, such as white paint or another suitable reflective material.

Once formed, the spectral concentrators are readily combined and bonded to a superstrate 2824 for rigidity and environmental protection. In the illustrated embodiment, the superstrate 2824 faces incident solar radiation, and can be formed from a suitable material that is optically transparent or translucent. It is contemplated that an anti-reflection layer can be formed adjacent to a top surface of the superstrate 2824, and that either, or both, of the anti-reflection layer 2818 and the top substrate layer 2808 can be optionally omitted from each of the spectral concentrators.

### EXAMPLES

The following examples describe specific aspects of some embodiments of the invention to illustrate and provide a description for those of ordinary skill in the art. The examples should not be construed as limiting the invention, as the examples merely provide specific methodology useful in understanding and practicing some embodiments of the invention.

### Example 1

### Formation of Luminescent Material—UD930

Samples of UD930 were formed in a reproducible manner by vacuum deposition in accordance with two main approaches. In accordance with one approach, tin chloride and cesium iodide were evaporated in sequential layers, from two layers to 16 layers total, and the ratio of tin chloride to cesium iodide was from about 2:1 to about 1:3. It is contemplated that the number of layers and the ratio of reactants can vary for other implementations. A resulting sample was annealed on a hot plate in air or nitrogen for about 20 seconds to about 120 seconds at a temperature in the range of about 150° C. to about 280° C. Higher temperatures were observed to yield higher photoluminescence intensity, but a resulting surface can be rougher. A temperature of about 180° C. was observed to yield adequate photoluminescence and a relatively smooth surface.

In accordance with another approach, tin iodide and cesium iodide were evaporated in sequential layers, from two layers to six layers total, and the ratio of tin iodide to cesium iodide was from about 1:1 to about 1:2. It is contemplated that the number of layers and the ratio of reactants can vary for other implementations. A resulting sample was annealed on a hot plate in air or nitrogen for about 20 seconds to about 120 seconds at a temperature in the range of about 250° C. to about 380° C. Air-annealed photoluminescence was observed to be sometimes unstable and decayed in a few hours, while nitrogen-annealed photoluminescence was observed to last for at least a few days.

For either approach, stability of photoluminescence was enhanced if samples of UD930 were encapsulated. One manner of encapsulation was by bonding using a layer of a polymer or another suitable adhesive material. Coating or deposition of a layer of silver or another non-reactive metal was also used to provide encapsulation. In both cases, namely bonding and metal deposition, photoluminescence was observed to be stable for at least several months.

Samples of UD930 were observed to exhibit substrate effects with respect to resulting photoluminescence characteristics. Substrates formed from silicon (with oxide), different types of glass, alumina-based ceramic, and porous alumina filter were observed to yield differences of up to ten times in photoluminescence intensity. For example, enhancements of about three times in photoluminescence intensity were observed for alumina-based ceramic substrates, in which alumina is doped with chromium ions and sometimes also titanium ions. Without wishing to be bound by a particular theory, it is believed that such enhancements can at least partly derive from a R1 R2 emission process. In accordance with the R1 R2 emission process, dopants within an alumina-based ceramic substrate down-convert radiation at wavelengths shorter than about 600 nm and emit radiation at about 695 nm, which then excites UD930 to emit radiation at about 950 nm. It is believed that such enhancements can also derive from surface roughness and high reflectivity at 950 nm of the alumina-based ceramic substrate, which promote reflection of radiation back towards UD930.

### Example 2

### Formation of Spectral Concentrator—Bonded Samples

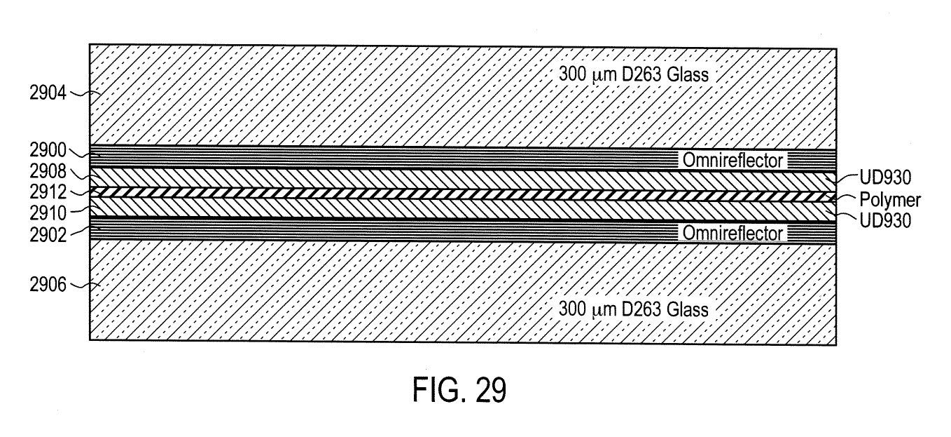

Samples of spectral concentrators were formed in accordance with a bonding approach, as illustrated in FIG. 29. A top reflector 2900 and a bottom reflector 2902 were formed adjacent to a top substrate layer 2904 (D263 glass substrate; 300 μm thickness) and a bottom substrate layer 2906 (D263 glass substrate; 300 μm thickness), respectively. ALD was used to form the reflectors 2900 and 2902, each of which included alternating layers of SiO₂ and TiO₂ for a total of 86 layers. Next, UD930 layers 2908 and 2910 were formed adjacent to the top reflector 2900 and the bottom reflector 2902, respectively, by coating or depositing a set of reactants that are precursors of UD930. In particular, tin chloride and cesium iodide were evaporated in sequential layers, for a total of 4 layers and a total thickness of about 750 nm adjacent to each of the top reflector 2900 and the bottom reflector 2902. The coatings of the reactants were next subjected to annealing at about 185° C. on a hot plate in air. A bonding layer 2912 was formed adjacent to one of the resulting UD930 layers 2908 and 2910 by spin-coating a polymer for a thickness in the range of about 0.5 μm to about 30 μm. The assembly of layers was then subjected to bonding with heat and pressure so as to form a substantially monolithic, bonded structure.

### Example 3

### Characterization of Spectral Concentrator—Bonded Samples

Photoluminescence measurements were performed on bonded samples in accordance with an experimental set-up described as follows. Each bonded sample was placed in a sample holder, and a top surface of the bonded sample was excited with a laser source (10 mW), which directed an excitation spot with an area of about 1 mm² along a direction substantially normal to the top surface and having a wavelength of about 532 nm. Edge emissions were measured using a spectrometer.

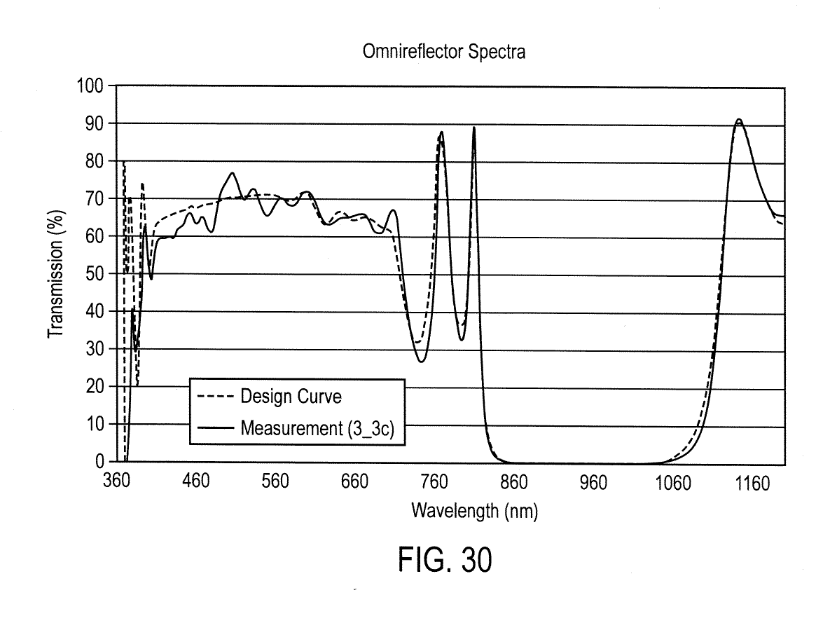

FIG. 30 illustrates a plot of transmittance of a reflector as a function of wavelength of light. As can be appreciated, the reflector has a stop band of relatively low transmittance (or relatively high reflectivity) centered around the peak emission wavelength of 950 nm, and a transmission band of relatively high transmittance (or relatively low reflectivity) outside of the stop band. Surface emissions were measured with respect to a top surface of the reflector, and no detectable surface emissions were observed at directions within a range of ±60° relative to a normal direction.

### Example 4

### Formation of Spectral Concentrator—Integrated Cavity Samples

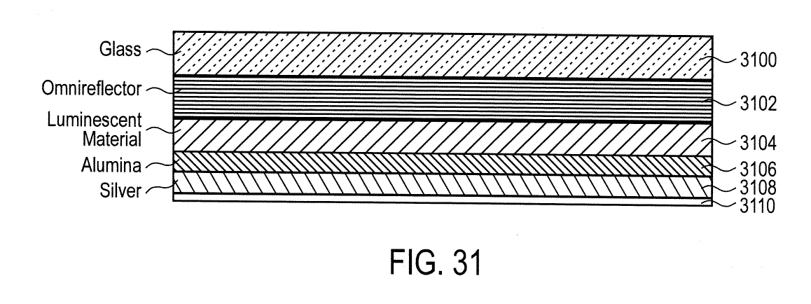

Samples of spectral concentrators were formed in accordance with an integrated cavity approach, as illustrated in FIG. 31. In particular, various layers of an assembly of layers were sequentially formed adjacent to a glass substrate layer 3100. In the case of one sample, for example, ALD was used to form a reflector 3102 adjacent to the glass substrate layer 3100, and a UD930 layer 3104 was formed adjacent to the reflector 3102 by coating or depositing a set of reactants that are precursors of UD930. In particular, tin chloride and cesium iodide were evaporated in sequential layers, for a total of 6 layers and with a thickness of tin chloride of about 60 nm by thermal evaporation and a thickness of cesium iodide of about 150 nm by electron-beam evaporation. An alumina layer 3106 with a thickness of about 100 nm was formed adjacent to the UD930 layer 3104 by electron-beam evaporation, and then a silver metal layer 3108 with a thickness of about 100 nm was formed adjacent to the alumina layer 3106 by electron-beam evaporation. Next, the silver metal layer 3108 was protected from oxidation by forming an aluminum layer 3110 with a thickness of about 250 nm by electron-beam evaporation. The assembly of layers was then subjected to annealing so as to form a substantially monolithic, integrated cavity waveguide.

Integrated cavity samples were generally thinner than counterpart bonded samples as previously described in Examples 2 and 3. Three different types of reflectors were used in the integrated cavity samples, and are designated as B-type, O-type, and J-type. These reflectors each has a stop band centered around 950 nm, but differed somewhat in spectral width of their stop bands and characteristics of their side lobes. Integrated cavity samples using these reflectors were observed to exhibit differences with respect to resulting photoluminescence characteristics.

### Example 5

### Characterization of Spectral Concentrator—Integrated Cavity Samples with B-type Reflectors

Photoluminescence measurements were performed on integrated cavity samples with B-type reflectors in accordance with an experimental set-up similar to that of Example 3.

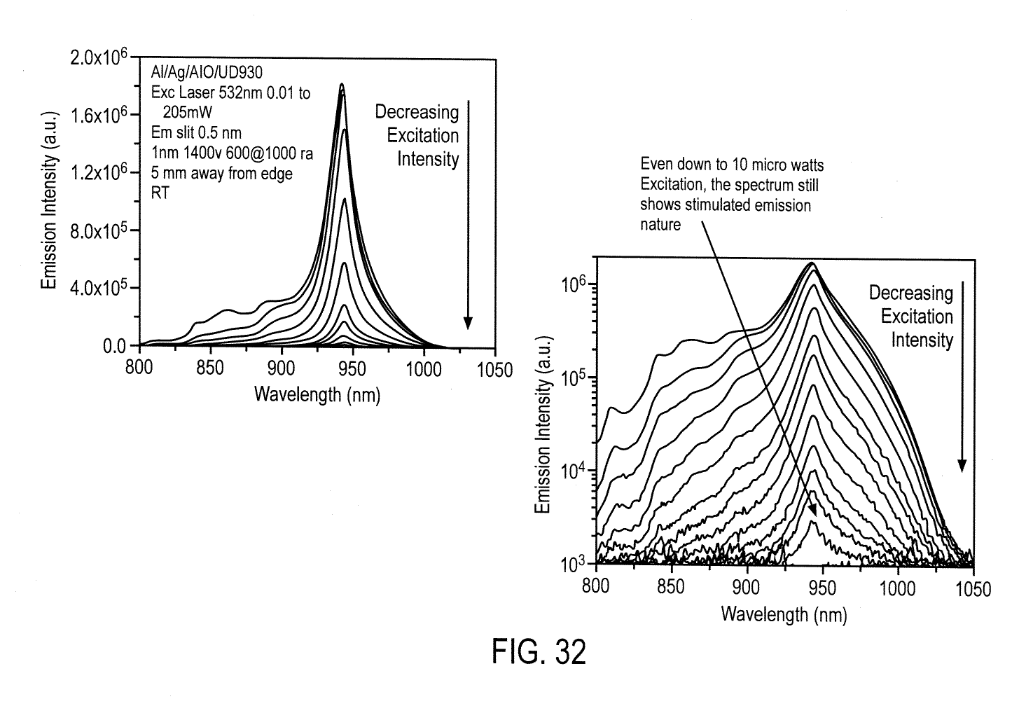

FIG. 32 illustrates superimposed plots of edge emission spectra for one sample as a function of excitation power in the range of about 0.01 mW to about 205 mW. As can be appreciated, the emission spectra are indicative of stimulated emission, which was observed even with an excitation power down to about 0.01 mW and a corresponding excitation intensity down to about 1 mW cm⁻². The low excitation intensities for stimulated emission are indicative of a low lasing threshold associated with a polariton laser.

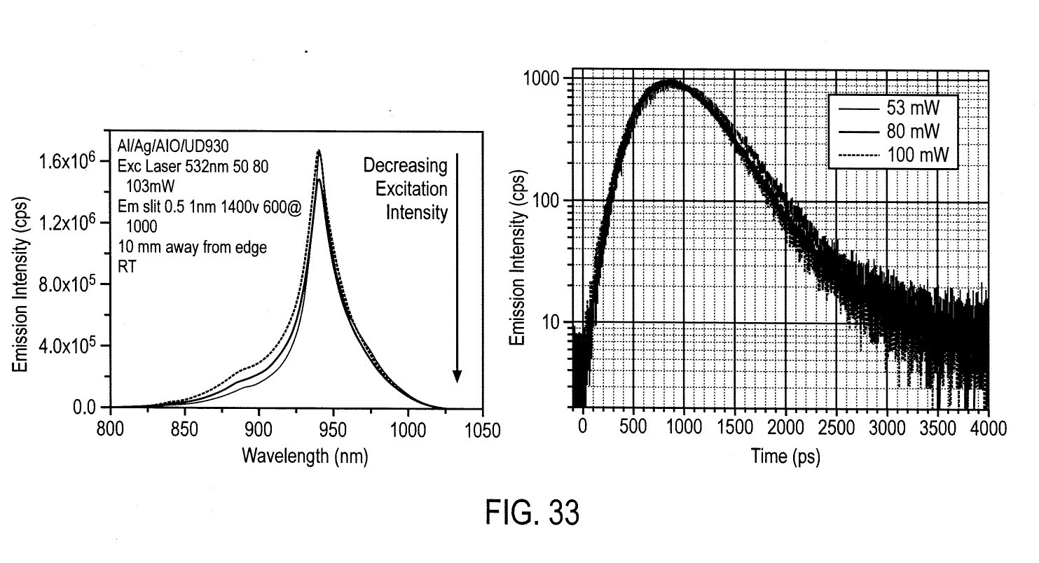

FIG. 33 illustrates superimposed plots of edge emission spectra for excitation powers of about 50 mW, about 80 mW, and about 100 mW. Again, the emission spectra are indicative of stimulated emission and a low lasing threshold associated with a polariton laser. FIG. 33 also illustrates superimposed plots of edge emission intensities as a function of time, with the origin corresponding to a start of excitation. As can be appreciated, a photoluminescence lifetime or a radiative lifetime typically corresponds to a time interval between a peak value in emission intensity to a (1/e) value as the emission intensity decays from its peak value. As illustrated in FIG. 33, radiative lifetimes were observed to be about 100 psec or less. These short radiative lifetimes are again indicative of a polariton laser.

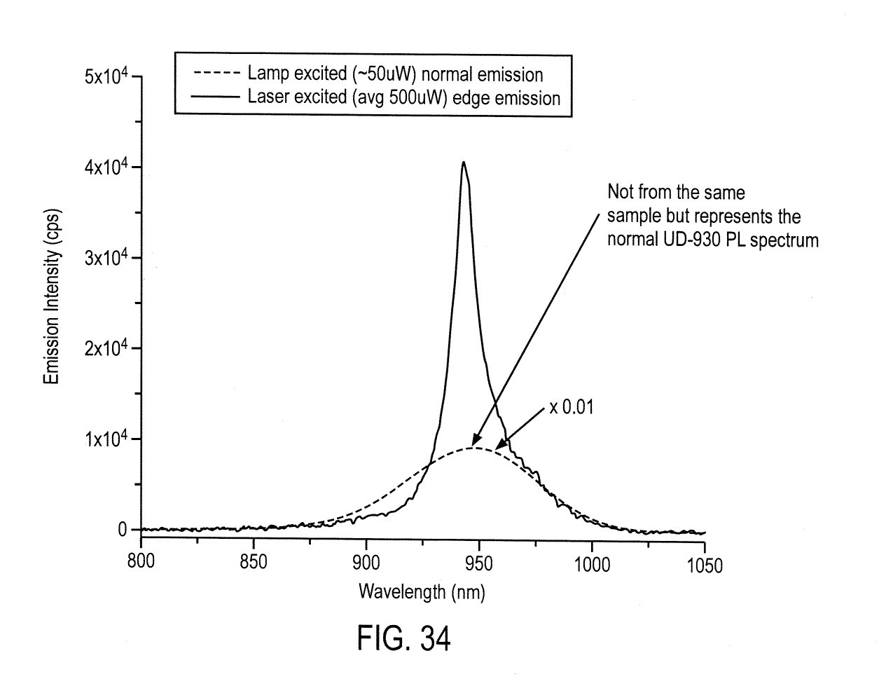

FIG. 34 illustrates superimposed plots of an edge emission spectrum for UD930 when incorporated within an integrated cavity sample and a typical emission spectrum for UD930 in the absence of resonant cavity effects. As can be appreciated, incorporation of UD930 within the integrated cavity sample yields a narrowing of its emission peak, which is again indicative of a polariton laser.

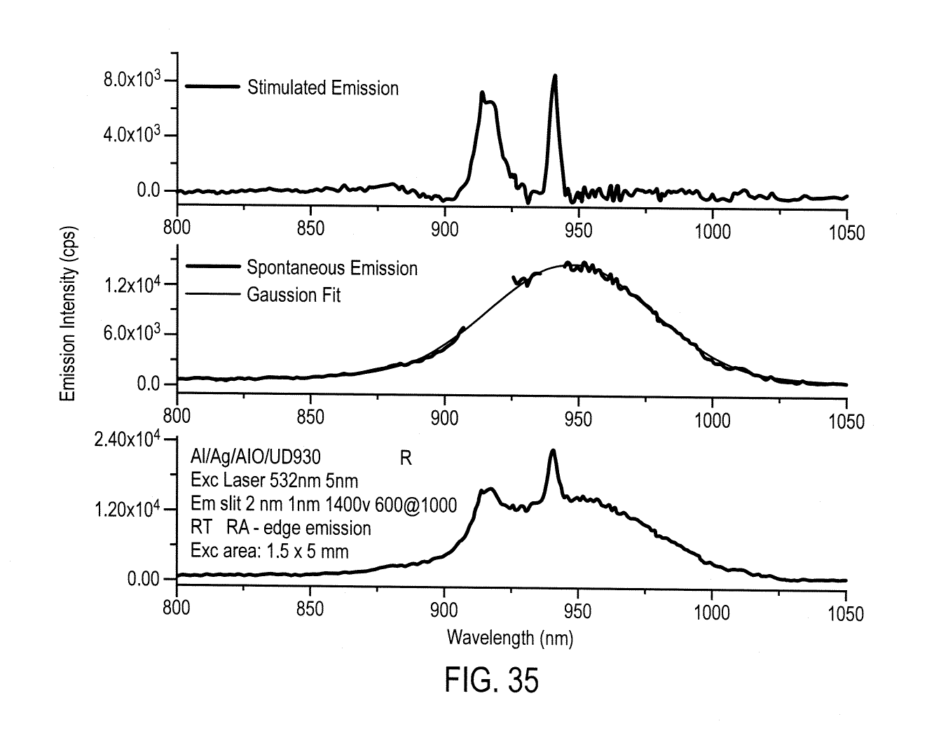

FIG. 35 illustrates an edge emission spectrum for UD930 when incorporated within an integrated cavity sample and when excited with a white light source at an intensity of less than about 50 mW cm⁻² (lower plot). As can be appreciated, the emission spectrum can be represented as a combination of an emission spectrum associated with stimulated emission (upper plot) and an emission spectrum associated with spontaneous emission (middle plot). The emission spectrum associated with stimulated emission exhibits a splitting of peaks that is indicative of Rabi splitting.

### Example 6

### Characterization of Spectral Concentrator—Integrated Cavity Samples with O-type Reflectors

Photoluminescence measurements were performed on integrated cavity samples with O-type reflectors in accordance with an experimental set-up similar to that of Example 3.

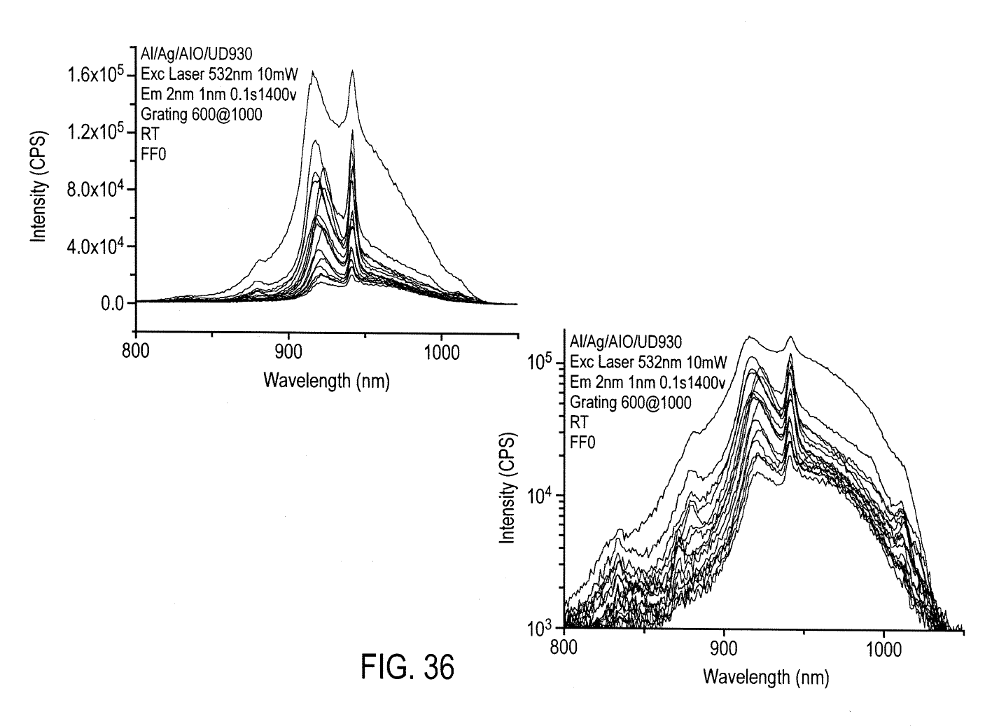

FIG. 36 illustrates superimposed plots of edge emission spectra for one sample. As can be appreciated, the emission spectra are indicative of stimulated emission, and the low excitation intensities for stimulated emission are indicative of a low lasing threshold associated with a polariton laser. As illustrated in FIG. 36, a splitting of peaks in the emission spectra is indicative of Rabi splitting and the presence of exciton-polaritons in a strong coupling regime.

### Example 7

### Characterization of Spectral Concentrator—Integrated Cavity Samples with J-type Reflectors

Photoluminescence measurements were performed on integrated cavity samples with J-type reflectors in accordance with an experimental set-up similar to that of Example 3.

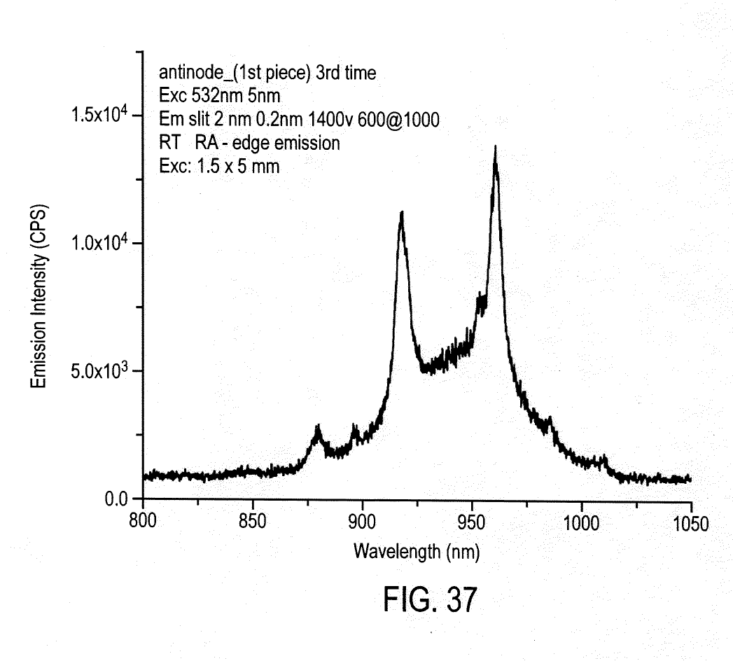

FIG. 37 illustrates an edge emission spectrum for UD930 when incorporated within an integrated cavity sample and when excited with a white light source at an intensity of less than about 50 mW cm⁻². As can be appreciated, the emission spectrum exhibits a splitting of peaks that is indicative of Rabi splitting.

### Example 8

### Characterization of Spectral Concentrator—Resonant Cavity Effects

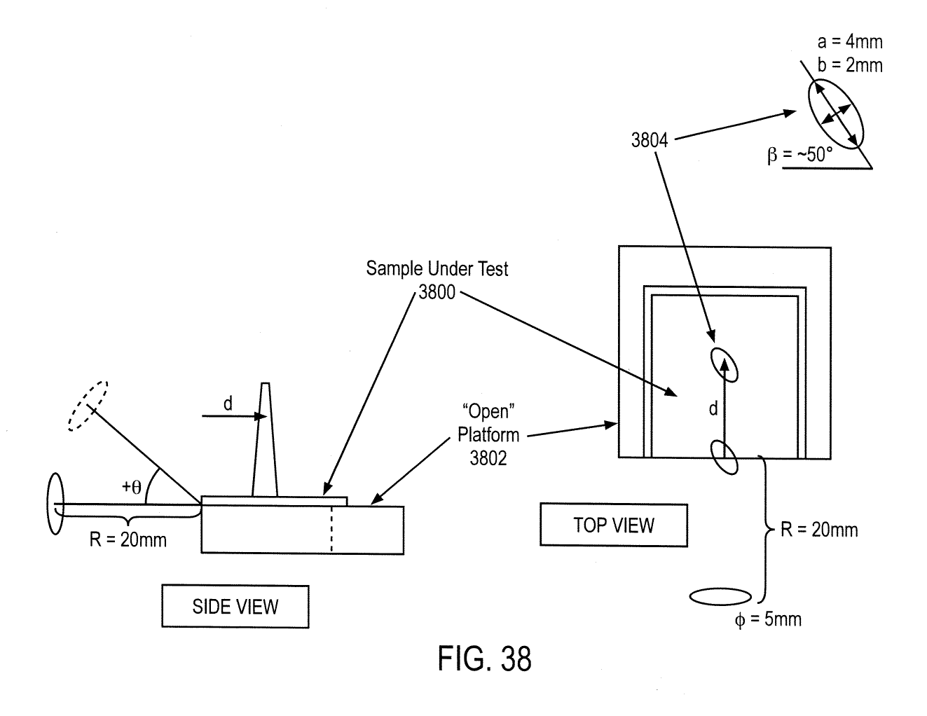

Photoluminescence measurements were performed on samples of spectral concentrators in accordance with an experimental set-up as illustrated in FIG. 38. Each sample 3800 was placed on a platform 3802, and a top surface of the sample 3800 was excited using a laser diode module, which directed an excitation spot 3804 with dimensions of about 4 mm by about 2 mm along a direction substantially normal to the top surface. The excitation spot 3804 was rotated by about 50° to account for an offset in the laser diode module. Edge emissions were measured with respect to a distance d of the excitation spot 3804 from an edge of the sample 3800 and with respect to an angle θ relative to a horizontal plane of the sample 3800. The distance d was varied in the range of about 0 mm to about 10 mm in increments of about 0.25 mm, and was offset based on an amount R in terms of total beam-edge displacement. The angle θ was varied in the range of about −50° to about +70° in increments of about 2.5°, with positive values denoting angles above the horizontal plane, and with negative values denoting angles below the horizontal plane. Edge emissions were measured for each angle θ at an initial distance d, the sample 3800 was repositioned to a subsequent distance d, edge emissions were then measured for each angle θ at that subsequent distance d, and so forth.

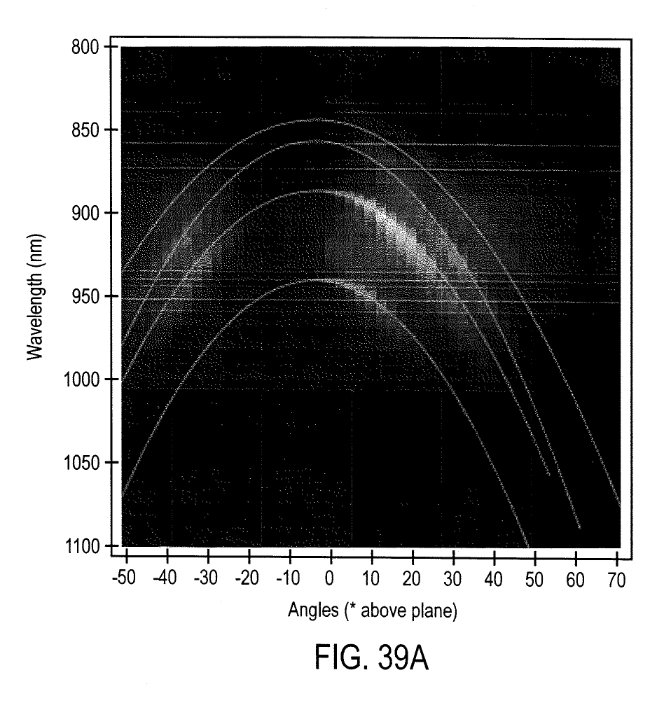

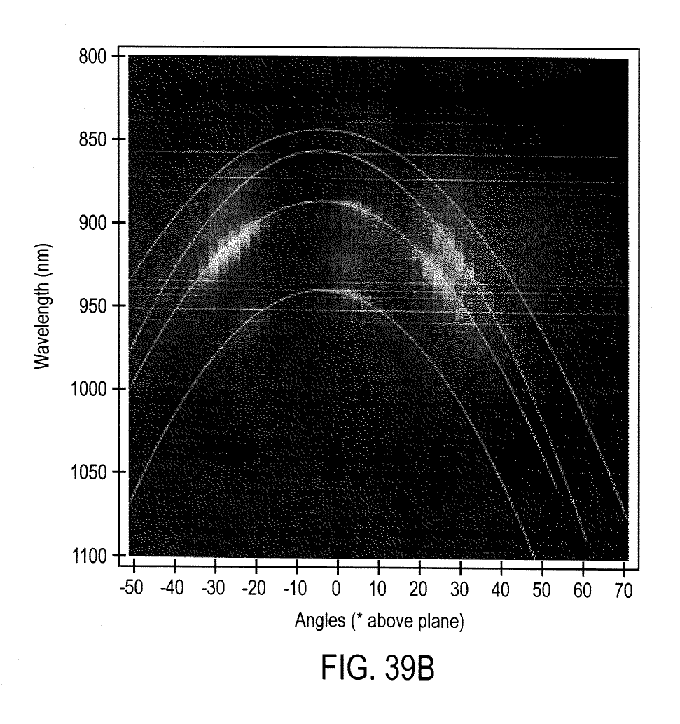

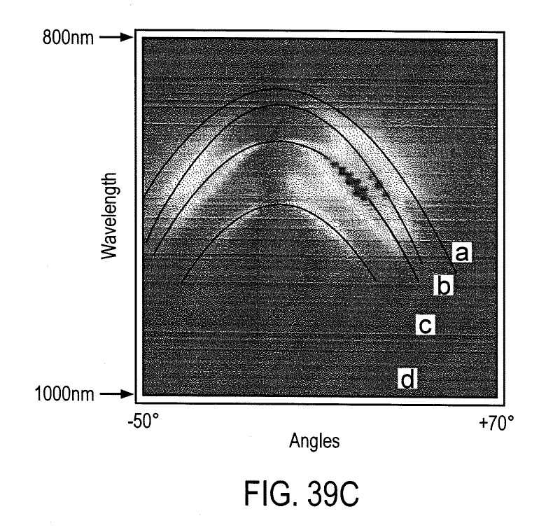

FIG. 39A illustrates a plot of edge emission spectra as a function of the angle θ and at a particular distance d, FIG. 39B illustrates a plot of edge emission spectra as a function of the angle θ and at another distance d, and FIG. 39C illustrates superimposed plots of edge emission spectra as a function of the angle θ and over all distances d. As can be appreciated, photoluminescence was manifested in the form of distinct bands of photoluminescence intensities, each band having an associated peak emission intensity that varies with the angle θ in accordance with a respective dispersion curve. In particular, at least four distinct bands were observed (labeled as “a,” “b,” “c,” and “d”), and curve-fitting was carried out to yield the following parabolic dispersion curves: (1) λₐ(nm)=884+0.04128 θ(°)²; (2) λ_{b}(nm)=857+0.05504 θ(°)²; (3) θ_{c}(nm)=887+0.05160 θ(°)²; and (4) θ_{d}(nm)=941+0.05848 θ(°)². Without wishing to be bound by a particular theory, these bands of photoluminescence intensities and their associated dispersion curves are indicative of distinct optical modes that propagate emitted radiation within a resonant cavity waveguide.

It should be appreciated that the specific embodiments of the invention described above are provided by way of example, and that various other embodiments are contemplated. For example, while certain elements have been described with reference to some embodiments, it is contemplated that these elements may be implemented in other embodiments or may be combined, sub-divided, or re-ordered in a number of other ways.

A practitioner of ordinary skill in the art requires no additional explanation in developing the solar modules described herein but may nevertheless find some helpful guidance regarding the formation and processing of PV cells by examining the following references: U.S. Pat. No. 7,169,669, entitled “Method of Making Thin Silicon Sheets for Solar Cells” and issued on Jan. 30, 2007; and U.S. Patent Application Publication No. 2005/0272225, entitled “Semiconductor Processing” and published on Dec. 8, 2005, the disclosures of which are incorporated herein by reference in their entireties. A practitioner of ordinary skill in the art may also find some helpful guidance regarding spectral concentration by examining the following references: U.S. Pat. No. 4,227,939, entitled “Luminescent Solar Energy Concentrator Devices” and issued on Oct. 14, 1980; and A. H. Zewali, “Photon Trapping and Energy Transfer in Multiple-Dye Plastic Matrices: an Efficient Solar-Energy Concentrator;” Optics Letters, Vol. 1, p. 73 (1977), the disclosures of which are incorporated herein by reference in their entireties. Also, a practitioner of ordinary skill in the art may find some helpful guidance regarding multi-junction solar modules by examining Barnham et al., “Quantum-dot Concentrator and Thermodynamic Model for the Global Redshift,” Applied Physics Letters, Vol. 76, No. 9, pp. 1197-1199 (2000), the disclosure of which is incorporated herein by reference in its entirety. Furthermore, a practitioner of ordinary skill in the art may find some helpful guidance regarding resonant cavity effects and related structures by examining U.S. patent application Ser. No. 12/144,548, entitled “Solar Modules with Enhanced Efficiencies via Use of Spectral Concentrators” and filed on Jun. 23, 2008, the disclosure of which is incorporated herein by reference in its entirety.

While the invention has been described with reference to the specific embodiments thereof, it should be understood by those skilled in the art that various changes may be made and equivalents may be substituted without departing from the true spirit and scope of the invention as defined by the appended claims. In addition, many modifications may be made to adapt a particular situation, material, composition of matter, method, or process to the objective, spirit and scope of the invention. All such modifications are intended to be within the scope of the claims appended hereto. In particular, while the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A solar module comprising:
a photovoltaic cell; and
a resonant cavity waveguide optically coupled to the photovoltaic cell, the resonant cavity waveguide including:
a top reflector;
a bottom reflector; and
an emission layer disposed between the top reflector and the bottom reflector with respect to an anti-node position within the resonant cavity waveguide, the emission layer configured to absorb incident solar radiation and emit radiation that is guided towards the photovoltaic cell, the emitted radiation including an energy band having a spectral width no greater than 80 nm at Full Width at Half Maximum.

2. The solar module of claim 1, wherein the emission layer is disposed between the top reflector and the bottom reflector so as to be substantially centered at the anti-node position.

3. The solar module of claim 1, wherein the emitted radiation is guided towards the photovoltaic cell in accordance with a set of optical modes within the resonant cavity waveguide, and the spectral width is no greater than 50 nm at Full Width at Half Maximum.

4. The solar module of claim 3, wherein the spectral width is in the range of 1 nm to 20 nm at Full Width at Half Maximum.

5. The solar module of claim 3, wherein the emitted radiation includes the energy band having a peak emission wavelength in the near infrared range.

6. The solar module of claim 1, wherein the top reflector includes a dielectric stack having narrowband reflectivity with respect to the emitted radiation.

7. The solar module of claim 6, further comprising a spacer layer disposed between the emission layer and the bottom reflector, wherein the spacer layer has a refractive index no greater than 1.5, and the bottom reflector has broadband reflectivity.

8. The solar module of claim 7, wherein the spacer layer includes at least one of an oxide and a fluoride, and the bottom reflector includes at least one of a metal and a metal alloy.

9. The solar module of claim 6, wherein the bottom reflector is a first bottom reflector, and further comprising a second bottom reflector disposed between the emission layer and the first bottom reflector, wherein one of the first bottom reflector and the second bottom reflector has narrowband reflectivity with respect to the emitted radiation, and another one of the first bottom reflector and the second bottom reflector has broadband reflectivity.

10. The solar module of claim 1, wherein the emission layer is a top emission layer disposed between the top reflector and the bottom reflector with respect to a first anti-node position within the resonant cavity waveguide, and further comprising:
a bottom emission layer disposed between the top emission layer and the bottom reflector with respect to a second anti-node position within the resonant cavity waveguide; and
a spacer layer disposed between the top emission layer and the bottom emission layer.

11. The solar module of claim 10, wherein the spacer layer is configured to guide at least a fraction of the emitted radiation towards the photovoltaic cell via optical mode transfer.

12. The solar module of claim 1, wherein the emission layer includes a luminescent material having the formula:
[AₐB_{b}XₓX′_{x′}X″_{x″}],
A is selected from elements of Group IA;
B is selected from elements of Group IVB;
X, X′, and X″ are independently selected from elements of Group VIIB;
a is in the range of 1 to 9;
b is in the range of 1 to 5; and
a sum of x, x′, and x″ is in the range of 1 to 9.

13. A solar module comprising:
a photovoltaic cell; and
a spectral concentrator optically coupled to the photovoltaic cell and including a luminescent stack, the luminescent stack including:
a first reflector;
a second reflector; and
an emission layer disposed between the first reflector and the second reflector, the emission layer including a luminescent material having the formula:
[AₐB_{b}Xₓ],
A is selected from potassium, rubidium, and cesium;
B is selected from germanium, tin, and lead;
X is selected from chlorine, bromine, and iodine;
a is in the range of 1 to 9;
b is in the range of 1 to 5; and
x is equal to a+2b.

14. The solar module of claim 13, wherein a is 1, and x is equal to 1+2b.

15. The solar module of claim 14, wherein B is tin.

16. The solar module of claim 15, wherein the luminescent material is configured to absorb incident solar radiation and emit radiation that is guided towards the photovoltaic cell, and at least one of the first reflector and the second reflector has narrowband reflectivity with respect to the emitted radiation.

17. The solar module of claim 16, wherein the first reflector has narrowband reflectivity with respect to the emitted radiation, and the second reflector has broadband reflectivity.

18. The solar module of claim 17, further comprising a spacer layer disposed between the emission layer and the second reflector, wherein the spacer layer has a refractive index no greater than 2.

19. A solar module comprising:
a photovoltaic cell; and
a luminescent stack defining a groove and including:
a first reflector;
a second reflector;
a first emission layer disposed between the first reflector and the second reflector;
a second emission layer disposed between the first emission layer and the second reflector; and
a bonding layer disposed between the first emission layer and the second emission layer,
wherein the groove extends through at least a portion of the first emission layer and the second emission layer, and the photovoltaic cell is disposed with respect to the groove so as to be optically coupled to the first emission layer and the second emission layer.

20. The solar module of claim 19, wherein the bonding layer is formed from an adhesive material.

21. The solar module of claim 19, further comprising a waveguide structure disposed within the groove, and wherein the photovoltaic cell is adjacent to the waveguide structure.

22. The solar module of claim 19, wherein the photovoltaic cell is disposed within the groove.
